(19) United States
(12) Patent Application Publication
(10) Pub. No.: US 2024/0368465 A1
(43) Pub. Date: Nov. 7, 2024

(54) ORGANIC ELECTROLUMINESCENT MATERIAL AND DEVICE COMPRISING SAME

(71) Applicant: BEIJING SUMMER SPROUT TECHNOLOGY CO., LTD., Beijing (CN)

(72) Inventors: Hongbo Li, Beijing (CN); Zhen Wang, Beijing (CN); Zheng Wang, Beijing (CN); Wei Cai, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 18/615,493

(22) Filed: Mar. 25, 2024

(30) Foreign Application Priority Data
Mar. 30, 2023 (CN) 202310330188.5

(51) Int. Cl. C09K 11/06; H10K 50/11; H10K 85/30

(52) U.S. Cl. CPC C09K 11/06; H10K 50/11; H10K 85/342; C09K 2211/185

(57) ABSTRACT

Provided are an organic electroluminescent material and a device comprising the same. The organic electroluminescent material is a metal complex having a structure of Formula 1, and the structure of Formula 1 includes a ligand Lₐ having a specific substituent and a ligand L_{b} having a specific substituent. When applied to the electroluminescent devices, these new compounds can provide excellent device performance such as improved device efficiency, an extended device lifetime, and reduced device capacitance, and facilitate the improvement of the overall performance of the devices. Further provided are an organic electroluminescent device including the metal complex and a composition including the metal complex.

### CROSS-REFERENCE TO RELATED APPLICATION(S)

This application claims priority to Chinese Patent Application No. 202310330188.5 filed on Mar. 30, 2023, the disclosure of which is incorporated herein by reference in its entirety.

### TECHNICAL FIELD

The present disclosure relates to compounds for organic electronic devices such as organic light-emitting devices. In particular, the present disclosure relates to a metal complex having a structure of Formula 1, an organic electroluminescent device including the metal complex, and a compound composition including the metal complex.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which includes an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may include multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may include one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

US20210047353A1 discloses a metal complex having a general formula structure of Ir(L¹)ₓ(L²)_{y}(L³)_{z}, wherein the ligand L¹ has the following structure:

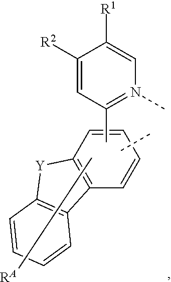

and the ligands L² and L³ identically or differently have the structure:

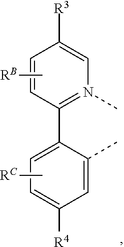

wherein R^{A}, R^{B}, and R^{C} are selected from hydrogen, deuterium, halogen, alkyl, cyano, etc., and R¹ to R⁴ are selected from alkyl, cycloalkyl, etc., and further discloses the following structures:

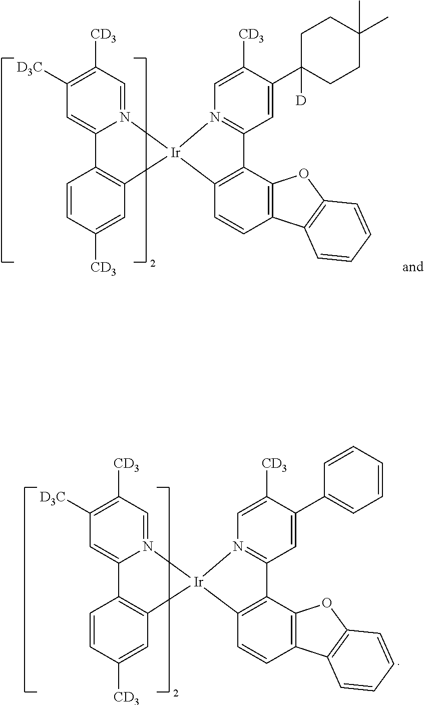

The preceding application does not disclose or teach a metal complex in which the ligand L¹ has a specific R^{A} substituent and L² and L³ also have specific substituents and the effect of such a metal complex on device performance.

### SUMMARY

The present disclosure is intended to provide a series of metal complexes each having a structure of Formula 1 to solve at least part of the above-mentioned problems. The structure of Formula 1 includes a ligand Lₐ having a specific substituent and a ligand L_{b} having a specific substituent. When applied to the electroluminescent devices, these new metal complexes can improve device efficiency, extend a device lifetime, and reduce device capacitance, facilitating the improvement of the overall performance of the devices.

According to an embodiment of the present disclosure, a metal complex is disclosed. The metal complex has a general structure of M(Lₐ)ₘ(L_{b})ₙ which is represented by Formula 1:

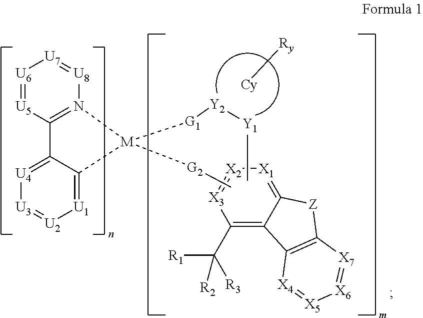

wherein
the metal M is selected from a metal with a relative atomic mass greater than 40;
m is selected from 1 or 2, n is selected from 1 or 2, and m+n equals an oxidation state of the metal M; when m is 2, two Lₐ are the same or different; when n is 2, two L_{b} are the same or different;
G₁ and G₂ are, at each occurrence identically or differently, selected from a single bond, O or S;
Cy is, at each occurrence identically or differently, selected from an aromatic ring including Y₁ and Y₂ and having 6 to 24 ring atoms, a heteroaromatic ring including Y₁ and Y₂ and having 5 to 24 ring atoms, or a combination thereof,
X₁ to X₇ are, at each occurrence identically or differently, selected from C, CRₓ or N; one of X₁ to X₃ is selected from C and joined to Y₁;
when X₁, X₂ or X₃ is selected from N, G₂ is selected from a single bond, and X₁, X₂ or X₃ is joined to the metal through a metal-nitrogen bond; or when X₁, X₂ or X₃ is selected from C, G₂ is selected from a single bond, O or S, and X₁, X₂ or X₃ is joined to the metal M through G₂;
Y₁ and Y₂ are, at each occurrence identically or differently, selected from C or N; when Y₂ is selected from N, G₁ is selected from a single bond, and Y₂ is directly joined to the metal M; or when Y₂ is selected from C, G₁ is selected from a single bond, O or S, Y₂ is joined to the metal M through G₁;
Z is selected from the group consisting of O, S, Se, NR′, CR′R′, SiR′R′, and GeR′R′; when two R′ are present at the same time, the two R′ are the same or different;
R_{y} represents mono-substitution, multiple substitutions or non-substitution; when a plurality of R_{y} are present, the plurality of R_{y} are the same or different;
U₁ to U₈ are, at each occurrence identically or differently, selected from CR, CRᵤ or N, and at least three of U₁ to U₈ are selected from CRᵤ;
R₁ to R₃ are, at each occurrence identically or differently, selected from the group consisting of: hydrogen, deuterium, halogen, a cyano group, an isocyano group, substituted or unsubstituted alkyl having 1 to 20 carbon atoms, substituted or unsubstituted cycloalkyl having 3 to 20 ring carbon atoms, and combinations thereof,
at least one of R₁ to R₃ is selected from hydrogen or deuterium;
R, Rₓ, R_{y}, and R′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
Rᵤ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, at least one of X₁ to X₇ is CRₓ, and Rₓ is a cyano group or fluorine;
adjacent substituents R_{y} can be optionally joined to form a ring;
adjacent substituents R₁ to R₃ can be optionally joined to form a ring;
adjacent substituents R′ and Rₓ can be optionally joined to form a ring;
adjacent substituents Rᵤ and R can be optionally joined to form a ring.

According to another embodiment of the present disclosure, an organic electroluminescent device is further disclosed. The organic electroluminescent device includes an anode, a cathode, and an organic layer disposed between the anode and the cathode, wherein at least one layer of the organic layer includes the metal complex described in the preceding embodiment.

According to another embodiment of the present disclosure, a compound composition is further disclosed. The compound composition includes the metal complex described in the preceding embodiments.

The present disclosure is intended to provide a series of metal complexes each having a structure of Formula 1 to solve at least part of the above-mentioned problems. When applied to the electroluminescent devices, these new metal complexes can improve device efficiency, extend a device lifetime, and reduce device capacitance, facilitating the improvement of the overall performance of the devices. These metal complexes also help to improve the response rate of OLED display devices at low greyscales and increase the refresh frequency of the devices. The compound disclosed by the present disclosure has huge advantages and broad prospects in industrial applications.

### BRIEF DESCRIPTION OF DRAWINGS

FIG. 1 is a schematic diagram of an organic light-emitting apparatus that may include a metal complex and a compound composition including the metal complex disclosed herein.

FIG. 2 is a schematic diagram of another organic light-emitting apparatus that may include a metal complex and a compound composition including the metal complex disclosed herein.

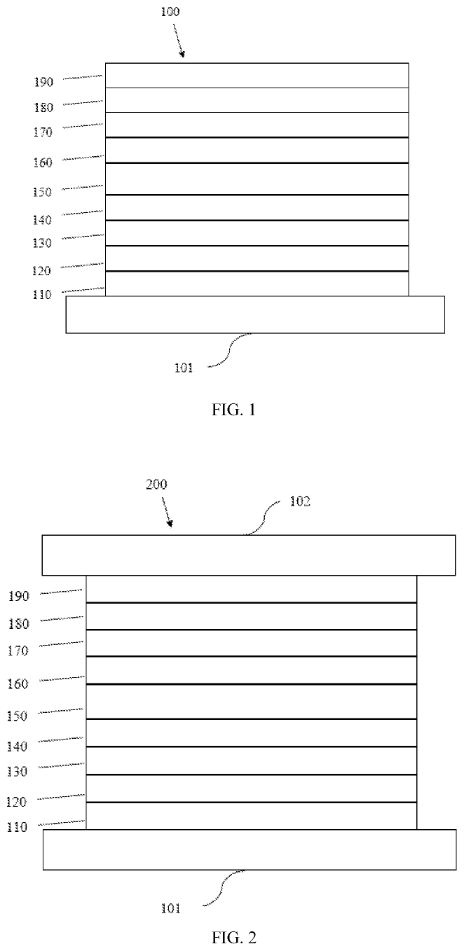

### DETAILED DESCRIPTION

OLEDs can be fabricated on various types of substrates such as glass, plastic, and metal foil. FIG. 2 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 3 schematically shows an organic light emitting device 200 without limitation. FIG. 3 differs from FIG. 2 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

As used herein, “emission area” means the area of an organic electroluminescent device in the direction perpendicular to the emissive surface where the anode is in direct contact with the organic layer and at the same time the organic layer is in direct contact with the cathode. Herein, the emission area in examples and comparative examples is 0.04 cm².

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔES-T). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔES-T. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl having 6 to 20 carbon atoms, unsubstituted alkylgermanyl having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen can also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitution (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

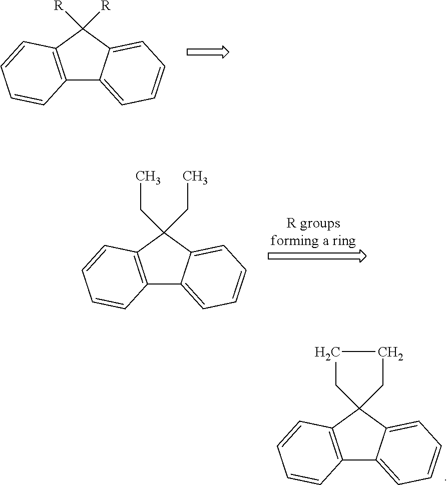

The expression that adjacent substituents can be optionally joined to form a ring is also intended to mean that two substituents bonded to carbon atoms which are directly bonded to each other are joined to each other via a chemical bond to form a ring, which can be exemplified by the following formula:

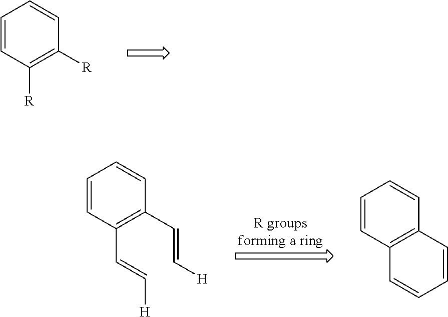

The expression that adjacent substituents can be optionally joined to form a ring is also intended to mean that two substituents bonded to a further distant carbon atom are joined to each other via a chemical bond to form a ring, which can be exemplified by the following formula:

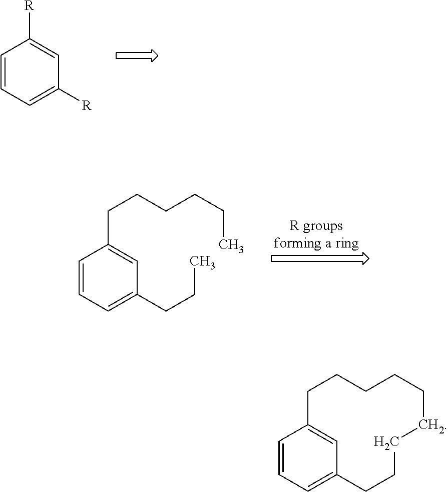

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

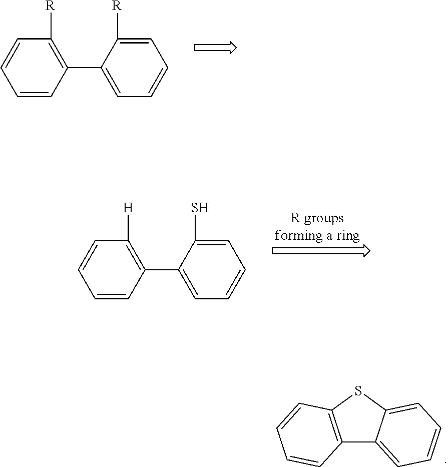

According to an embodiment of the present disclosure, a metal complex is disclosed. The metal complex has a general structure of M(Lₐ)ₘ(L_{b})ₙ which is represented by Formula 1:
wherein,

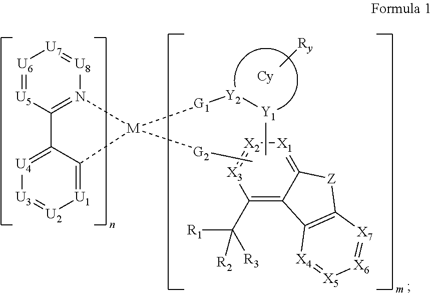

the metal M is selected from a metal with a relative atomic mass greater than 40;
m is selected from 1 or 2, n is selected from 1 or 2, and m+n equals an oxidation state of the metal M; when m is 2, two Lₐ are the same or different; when n is 2, two L_{b} are the same or different;
G₁ and G₂ are, at each occurrence identically or differently, selected from a single bond, O or S;
Cy is, at each occurrence identically or differently, selected from an aromatic ring including Y₁ and Y₂ and having 6 to 24 ring atoms, a heteroaromatic ring including Y₁ and Y₂ and having 5 to 24 ring atoms, or a combination thereof,
X₁ to X₇ are, at each occurrence identically or differently, selected from C, CRₓ or N; one of X₁ to X₃ is selected from C and joined to Y₁;
when X₁, X₂ or X₃ is selected from N, G₂ is selected from a single bond, and X₁, X₂ or X₃ is joined to the metal through a metal-nitrogen bond; or when X₁, X₂ or X₃ is selected from C, G₂ is selected from a single bond, O or S, and X₁, X₂ or X₃ is joined to the metal M through G₂;
Y₁ and Y₂ are, at each occurrence identically or differently, selected from C or N; when Y₂ is selected from N, G₁ is selected from a single bond, and Y₂ is directly joined to the metal M; or when Y₂ is selected from C, G₁ is selected from a single bond, O or S, Y₂ is joined to the metal M through G₁;
Z is selected from the group consisting of O, S, Se, NR′, CR′R′, SiR′R′, and GeR′R′; when two R′ are present at the same time, the two R′ are the same or different;
R_{y} represents mono-substitution, multiple substitutions or non-substitution; when a plurality of R_{y} are present, the plurality of R_{y} are the same or different;
U₁ to U₈ are, at each occurrence identically or differently, selected from CR, CRᵤ or N, and at least three of U₁ to U₈ are selected from CRᵤ;
R₁ to R₃ are, at each occurrence identically or differently, selected from the group consisting of: hydrogen, deuterium, halogen, a cyano group, an isocyano group, substituted or unsubstituted alkyl having 1 to 20 carbon atoms, substituted or unsubstituted cycloalkyl having 3 to 20 ring carbon atoms, and combinations thereof,
at least one of R₁ to R₃ is selected from hydrogen or deuterium;
R, Rₓ, R_{y}, and R′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
Rᵤ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, at least one of X₁ to X₇ is CRₓ, and Rₓ is a cyano group or fluorine;
adjacent substituents R_{y} can be optionally joined to form a ring;
adjacent substituents R₁ to R₃ can be optionally joined to form a ring;
adjacent substituents R′ and Rₓ can be optionally joined to form a ring;
adjacent substituents Rᵤ and R can be optionally joined to form a ring.

Herein, when G₁ is selected from a single bond, it means that Y₂ is directly joined to the metal M; when G₂ is selected from a single bond, it means that X₁, X₂ or X₃ is directly joined to the metal M.

Herein, the expression that “adjacent substituents R_{y} can be optionally joined to form a ring” is intended to mean that when a plurality of R_{y} are present, any two adjacent substituents R_{y} can be joined to form a ring. Obviously, it is possible that none of these substituents are joined to form a ring.

Herein, the expression that “adjacent substituents R′ and Rₓ can be optionally joined to form a ring” is intended to mean that any one or more of groups of adjacent substituents, such as two substituents R′, two substituents Rₓ, and substituents R′ and Rₓ, can be joined to form a ring. Obviously, it is possible that none of these substituents are joined to form a ring.

Herein, the expression that “adjacent substituents Rᵤ and R can be optionally joined to form a ring” is intended to mean that any one or more of groups of adjacent substituents, such as two substituents Rᵤ, two substituents R, and substituents R and Rᵤ, can be joined to form a ring. Obviously, it is possible that none of these substituents are joined to form a ring.

Herein, the expression that “adjacent substituents R₁ to R₃ can be optionally joined to form a ring” is intended to mean that any one or more of groups of adjacent substituents, such as substituents R₁ and R₂, substituents R₁ and R₃, and substituents R₃ and R₂, can be joined to form a ring. Obviously, it is possible that none of these substituents are joined to form a ring.

According to an embodiment of the present disclosure, G₁ and G₂ are, at each occurrence identically or differently, selected from a single bond or O.

According to an embodiment of the present disclosure, G₁ and G₂ are single bonds.

According to an embodiment of the present disclosure, Cy is, at each occurrence identically or differently, selected from any one of the following structures:

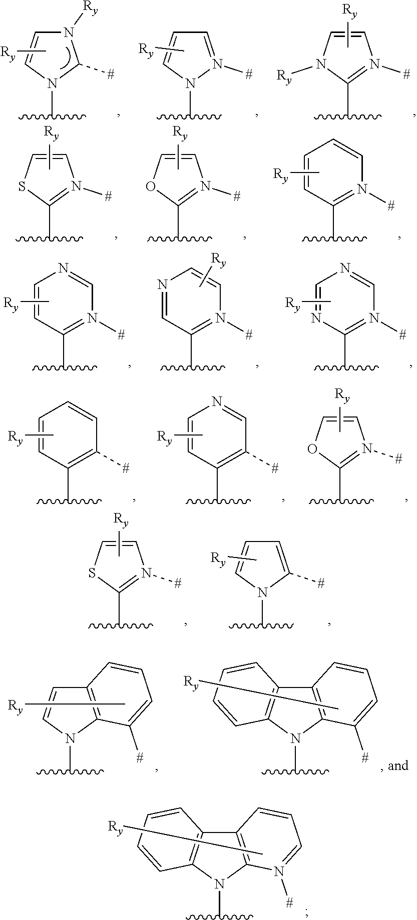

wherein,
R_{y} represents, at each occurrence identically or differently, mono-substitution, multiple substitutions or non-substitution; when a plurality of R_{y} are present in any structure, the plurality of R_{y} are the same or different;
R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
adjacent substituents R_{y} can be optionally joined to form a ring;
“#” represents the position of attachment to G₁ or the metal M, and “ [symbol] ” represents the position of attachment to X₁, X₂ or X₃.

According to an embodiment of the present disclosure, the metal M is, at each occurrence identically or differently, selected from the group consisting of Cu, Ag, Au, Ru, Rh, Pd, Os, Ir, and Pt.

According to an embodiment of the present disclosure, the metal M is, at each occurrence identically or differently, selected from Pt or Ir.

According to an embodiment of the present disclosure, the metal complex has a general formula structure of Ir(Lₐ)ₘ(L_{b})₃₋ₘ which is represented by Formula 2:

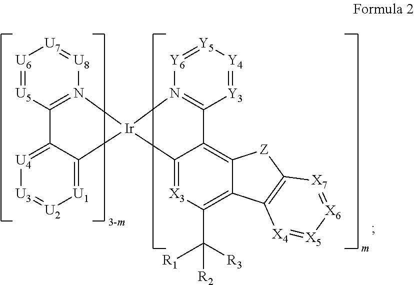

wherein,
m is selected from 1 or 2; when m is selected from 1, two L_{b} are the same or different; when m is selected from 2, two Lₐ are the same or different;
Z is selected from the group consisting of O, S, and Se;
X₃ to X₇ are, at each occurrence identically or differently, selected from CRₓ or N;
Y₃ to Y₆ are, at each occurrence identically or differently, selected from CR_{y} or N;
U₁ to U₈ are, at each occurrence identically or differently, selected from CR, CRᵤ or N, and at least three of U₁ to U₈ are selected from CRᵤ;
R₁ to R₃ are, at each occurrence identically or differently, selected from the group consisting of: hydrogen, deuterium, halogen, a cyano group, an isocyano group, substituted or unsubstituted alkyl having 1 to 20 carbon atoms, substituted or unsubstituted cycloalkyl having 3 to 20 ring carbon atoms, and combinations thereof,
at least one of R₁ to R₃ is selected from hydrogen or deuterium;
R, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
Rᵤ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
at least one of X₃ to X₇ is CRₓ, and Rₓ is a cyano group or fluorine;
adjacent substituents R_{y} can be optionally joined to form a ring;
adjacent substituents R₁ to R₃ can be optionally joined to form a ring;
adjacent substituents Rₓ can be optionally joined to form a ring;
adjacent substituents Rᵤ and R can be optionally joined to form a ring.

According to an embodiment of the present disclosure, m is selected from 1 or 2.

According to an embodiment of the present disclosure, m is selected from 1.

According to an embodiment of the present disclosure, Z is selected from O or S.

According to an embodiment of the present disclosure, Z is selected from O.

According to an embodiment of the present disclosure, Rᵤ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted alkylsilyl having 3 to 20 carbon atoms, substituted or unsubstituted alkylgermanyl having 3 to 20 carbon atoms, and combinations thereof.

According to an embodiment of the present disclosure, Rᵤ is, at each occurrence identically or differently, selected from the group consisting of: substituted or unsubstituted alkyl having 1 to 20 carbon atoms, substituted or unsubstituted cycloalkyl having 3 to 20 ring carbon atoms, and combinations thereof.

According to an embodiment of the present disclosure, Rᵤ is, at each occurrence identically or differently, selected from the group consisting of: substituted or unsubstituted alkyl having 1 to 6 carbon atoms, substituted or unsubstituted cycloalkyl having 3 to 6 ring carbon atoms, and combinations thereof.

According to an embodiment of the present disclosure, at least one of Rᵤ is selected from substituted or unsubstituted alkyl having 3 to 20 carbon atoms, substituted or unsubstituted cycloalkyl having 3 to 20 ring carbon atoms, or a combination thereof.

According to an embodiment of the present disclosure, at least one of Rᵤ is selected from the group consisting of: isopropyl, deuterated isopropyl, isobutyl, deuterated isobutyl, tert-butyl, neopentyl, deuterated neopentyl, cyclopentyl, deuterated cyclopentyl, cyclohexyl, deuterated cyclohexyl, and combinations thereof.

According to an embodiment of the present disclosure, at least two of U₁ to U₄ are selected from CRᵤ, and at least one of U₅ to U₈ is selected from CRᵤ.

According to an embodiment of the present disclosure, at least one of U₁ to U₄ is selected from CRᵤ, and at least two of U₅ to U₈ are selected from CRᵤ.

According to an embodiment of the present disclosure, at least two of U₁ to U₄ are selected from CRᵤ, and at least two of U₅ to U₈ are selected from CRᵤ.

According to an embodiment of the present disclosure, three of U₂, U₃, U₆, and U₇ are selected from CRᵤ.

According to an embodiment of the present disclosure, three of U₃, U₆, and U₇ are selected from CRᵤ.

According to an embodiment of the present disclosure, three of U₂, U₆, and U₇ are selected from CRᵤ.

According to an embodiment of the present disclosure, U₂, U₃, U₆, and U₇ are all selected from CRᵤ.

According to an embodiment of the present disclosure, when R₁ is selected from alkyl or cycloalkyl, the linking atom of R₁ is primary carbon, secondary carbon or tertiary carbon. For example, when R₁ is ethyl, the group including R₁ to R₃ in Formula 1 is as follows:

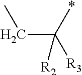

(wherein “*” represents the position of attachment in Formula 1), wherein “C” in the shown letter “CH₂” is the linking atom of R₁.

According to an embodiment of the present disclosure, R₁ to R₃ are, at each occurrence identically or differently, selected from hydrogen, deuterium or fluorine.

According to an embodiment of the present disclosure, X₁ to X₇ are, at each occurrence identically or differently, selected from CRₓ.

According to an embodiment of the present disclosure, X₁ to X₇ are, at each occurrence identically or differently, selected from CRₓ or N, and at least one of X₁ to X₇ is selected from N, for example, one of X₁ to X₇ is selected from N or two of X₁ to X₇ are selected from N.

According to an embodiment of the present disclosure, X₄ to X₇ are, at each occurrence identically or differently, selected from CRₓ.

According to an embodiment of the present disclosure, X₄ to X₇ are, at each occurrence identically or differently, selected from CRₓ or N, and at least one of X₄ to X₇ is selected from N, for example, one of X₄ to X₇ is selected from N or two of X₄ to X₇ are selected from N.

According to an embodiment of the present disclosure, R and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, a cyano group, and combinations thereof.

According to an embodiment of the present disclosure, R and Rₓ are, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, a cyano group, and combinations thereof.

According to an embodiment of the present disclosure, R and Rₓ are, at each occurrence identically or differently, selected from the group consisting of: hydrogen, deuterium, fluorine, substituted or unsubstituted alkyl having 1 to 6 carbon atoms, substituted or unsubstituted aryl having 6 to 12 carbon atoms, substituted or unsubstituted heteroaryl having 3 to 12 carbon atoms, a cyano group, and combinations thereof.

According to an embodiment of the present disclosure, at least two of X₄ to X₇ are selected from CRₓ, one of the Rₓ is a cyano group or fluorine, and at least one of the other Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, a cyano group, and combinations thereof.

According to an embodiment of the present disclosure, at least two of X₄ to X₇ are selected from CRₓ, one of the Rₓ is a cyano group or fluorine, and at least one of the other Rₓ is, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, a cyano group, and combinations thereof.

According to an embodiment of the present disclosure, Y₃ to Y₆ are, at each occurrence identically or differently, selected from CR_{y}.

According to an embodiment of the present disclosure, Y₃ to Y₆ are, at each occurrence identically or differently, selected from CR_{y} or N, and at least one of Y₃ to Y₆ is selected from N, for example, one of Y₃ to Y₆ is selected from N or two of Y₃ to Y₆ are selected from N.

According to an embodiment of the present disclosure, R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, a cyano group, and combinations thereof.

According to an embodiment of the present disclosure, R_{y} is, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, a cyano group, and combinations thereof.

According to an embodiment of the present disclosure, Y₃ to Y₆ are, at each occurrence identically or differently, CR_{y} or N, at least one of Y₃ to Y₆ is selected from CR_{y}, and the R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, Y₃ to Y₆ are, at each occurrence identically or differently, CR_{y} or N, at least one of Y₃ to Y₆ is selected from CR_{y}, and the R_{y} is selected from the group consisting of: deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, and combinations thereof.

According to an embodiment of the present disclosure, the metal complex has a structure represented by any one of Formula 2-1 to Formula 2-5:

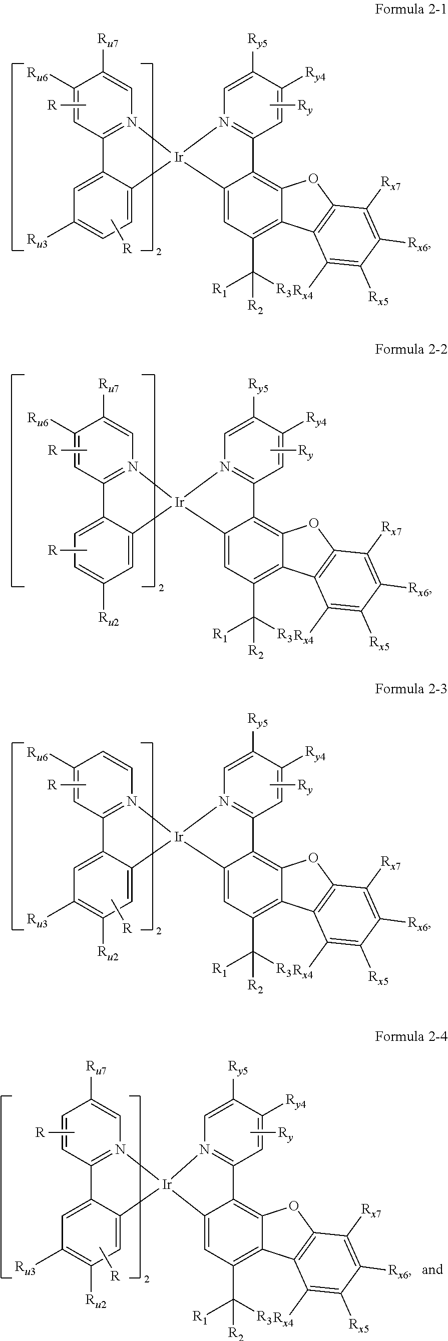

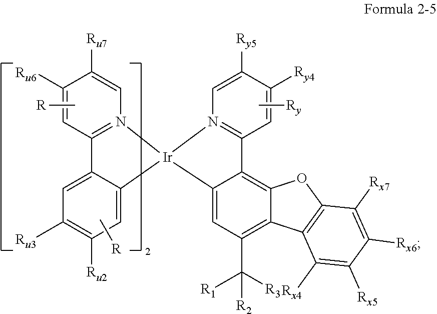

wherein,
R and R_{y} represent mono-substitution, multiple substitutions or non-substitution; when a plurality of R_{y} are present, the plurality of R_{y} are the same or different; when a plurality of R are present, the plurality of R are the same or different;
R and R_{y} are, at each occurrence identically or differently, selected from the group consisting of: hydrogen and deuterium;
Rₓ₄ to Rₓ₇, R_{y4}, and R_{y5} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, a cyano group, and combinations thereof,
at least one of Rₓ₄ to Rₓ₇ is selected from a cyano group or fluorine;
R₁ to R₃ are, at each occurrence identically or differently, selected from the group consisting of: hydrogen, deuterium, halogen, a cyano group, an isocyano group, substituted or unsubstituted alkyl having 1 to 20 carbon atoms, substituted or unsubstituted cycloalkyl having 3 to 20 ring carbon atoms, and combinations thereof,
at least one of R₁ to R₃ is selected from hydrogen or deuterium;
Rᵤ₂, Rᵤ₃, Rᵤ₆, and Rᵤ₇ are, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted alkylsilyl having 3 to 20 carbon atoms, substituted or unsubstituted alkylgermanyl having 3 to 20 carbon atoms, and combinations thereof,
adjacent substituents R₁ to R₃ can be optionally joined to form a ring;
adjacent substituents R_{y4} and R_{y5} can be optionally joined to form a ring;
adjacent substituents Rₓ₄, Rₓ₅, Rₓ₆, and Rₓ₇ can be optionally joined to form a ring;
adjacent substituents Rᵤ₂ and Rᵤ₃ can be optionally joined to form a ring;
adjacent substituents Rᵤ₆ and Rᵤ₇ can be optionally joined to form a ring.

Herein, the expression that “adjacent substituents Rₓ₄, Rₓ₅, Rₓ₆, and Rₓ₇ can be optionally joined to form a ring” is intended to mean that any one or more of groups of adjacent substituents, such as substituents Rₓ₄ and Rₓ₅, substituents Rₓ₅ and Rₓ₆, and substituents Rₓ₆ and Rₓ₇, can be joined to form a ring. Obviously, it is possible that none of these substituents are joined to form a ring.

According to an embodiment of the present disclosure, Lₐ is, at each occurrence identically or differently, selected from the group consisting of: Lₐ₋₁₋₁ to Lₐ₋₁₋₈₂₃, Lₐ₋₂₋₁ to Lₐ₋₂₋₈₂₃, Lₐ₋₃₋₁ to Lₐ₋₃₋₈₂₃, Lₐ₋₄₋₁ to Lₐ₋₄₋₈₂₃, Lₐ₋₅₋₁ to Lₐ₋₅₋₈₂₃, and Lₐ₋₆₋₁ to Lₐ₋₆₋₈₂₃. For the specific structures of Lₐ₋₁₋₁ to Lₐ₋₁₋₈₂₃, Lₐ₋₂₋₁ to Lₐ₋₂₋₈₂₃, Lₐ₋₃₋₁ to Lₐ₋₃₋₈₂₃, Lₐ₋₄₋₁ to Lₐ₋₄₋₈₂₃, Lₐ₋₅₋₁ to Lₐ₋₅₋₈₂₃, and Lₐ₋₆₋₁ to Lₐ₋₆₋₈₂₃, reference is made to claim 14.

According to an embodiment of the present disclosure, hydrogens in Lₐ₋₁₋₁ to Lₐ₋₁₋₈₂₃, Lₐ₋₂₋₁ to Lₐ₋₂₋₈₂₃, Lₐ₋₃₋₁ to Lₐ₋₃₋₈₂₃, Lₐ₋₄₋₁ to Lₐ₋₄₋₈₂₃, Lₐ₋₅₋₁ to Lₐ₋₅₋₈₂₃, and Lₐ₋₆₋₁ to Lₐ₋₆₋₈₂₃ can be optionally partially or completely substituted with deuterium.

According to an embodiment of the present disclosure, L_{b} is, at each occurrence identically or differently, selected from the group consisting of L_{b1} to L_{b751}, and for the specific structures of L_{b1} to L_{b751}, reference is made to claim 15.

According to an embodiment of the present disclosure, hydrogens in L_{b1} to L_{b751} can be optionally partially or completely substituted with deuterium.

According to an embodiment of the present disclosure, the metal complex is selected from the group consisting of metal complex 1-1 to metal complex 1938-1, metal complex 1-2 to metal complex 1938-2, metal complex 1-3 to metal complex 1938-3, metal complex 1-4 to metal complex 1938-4, metal complex 1-5 to metal complex 1938-5, metal complex 1-6 to metal complex 1938-6, and metal complex 1-7 to metal complex 40-7; for the specific structures of metal complex 1-1 to metal complex 1938-1, metal complex 1-2 to metal complex 1938-2, metal complex 1-3 to metal complex 1938-3, metal complex 1-4 to metal complex 1938-4, metal complex 1-5 to metal complex 1938-5, metal complex 1-6 to metal complex 1938-6, and metal complex 1-7 to metal complex 40-7, reference is made to claim 16.

According to an embodiment of the present disclosure, hydrogens in metal complex 1-1 to metal complex 1938-1, metal complex 1-2 to metal complex 1938-2, metal complex 1-3 to metal complex 1938-3, metal complex 1-4 to metal complex 1938-4, metal complex 1-5 to metal complex 1938-5, metal complex 1-6 to metal complex 1938-6, and metal complex 1-7 to metal complex 40-7 can be optionally partially or completely substituted with deuterium.

According to an embodiment of the present disclosure, an organic electroluminescent device is further disclosed. The organic electroluminescent device includes an anode, a cathode, and an organic layer disposed between the anode and the cathode, wherein at least one layer of the organic layer includes the metal complex described in any one of the preceding embodiments.

According to an embodiment of the present disclosure, the organic layer including the metal complex is an emissive layer.

According to an embodiment of the present disclosure, the emissive layer further includes a first host compound.

According to an embodiment of the present disclosure, the emissive layer further includes a first host compound and a second host compound.

According to an embodiment of the present disclosure, the first host compound and/or the second host compound include at least one chemical group selected from the group consisting of: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

According to an embodiment of the present disclosure, the first host compound has a structure represented by Formula X-1 or Formula X-2:

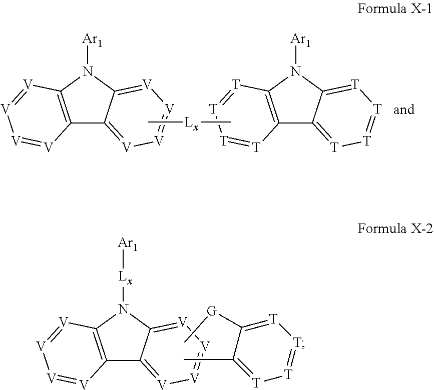

wherein,
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof,
G is, at each occurrence identically or differently, selected from C(R_{g})₂, NR_{g}, O or S;
V is, at each occurrence identically or differently, selected from C, CRₜ, or N;
in Formula X-1, T is, at each occurrence identically or differently, selected from C, CRₜ or N;
in Formula X-2, T is, at each occurrence identically or differently, selected from CRₜ or N;
R_{g}, Rᵥ, and Rₜ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
Ar₁ is, at each occurrence identically or differently, selected from substituted or unsubstituted aryl having 6 to 30 carbon atoms, substituted or unsubstituted heteroaryl having 3 to 30 carbon atoms, or a combination thereof,
adjacent substituents R_{g}, Rᵥ, and Rₜ can be optionally joined to form a ring.

In this embodiment, the expression that “adjacent substituents R_{g}, Rᵥ, and Rₜ can be optionally joined to form a ring” is intended to mean that any one or more of groups of adjacent substituents, such as two substituents Rᵥ, two substituents Rₜ, two substituents R_{g}, substituents Rᵥ and Rₜ, substituents Rᵥ and R_{g}, and substituents R_{g} and Rₜ, can be joined to form a ring. Obviously, it is possible that none of these substituents are joined to form a ring.

According to an embodiment of the present disclosure, the first host compound has a structure represented by one of Formula X-a to Formula X-p:

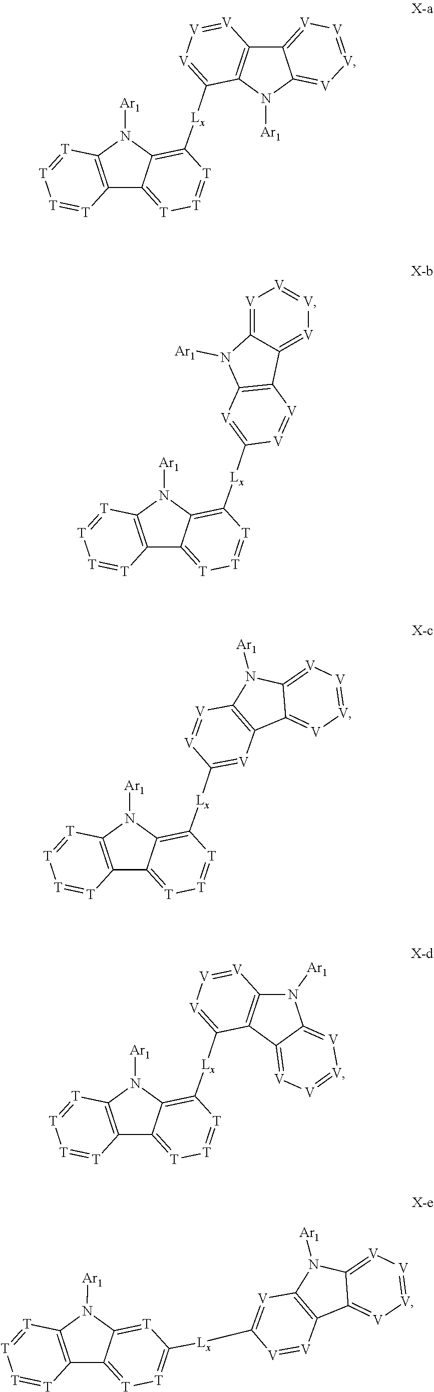

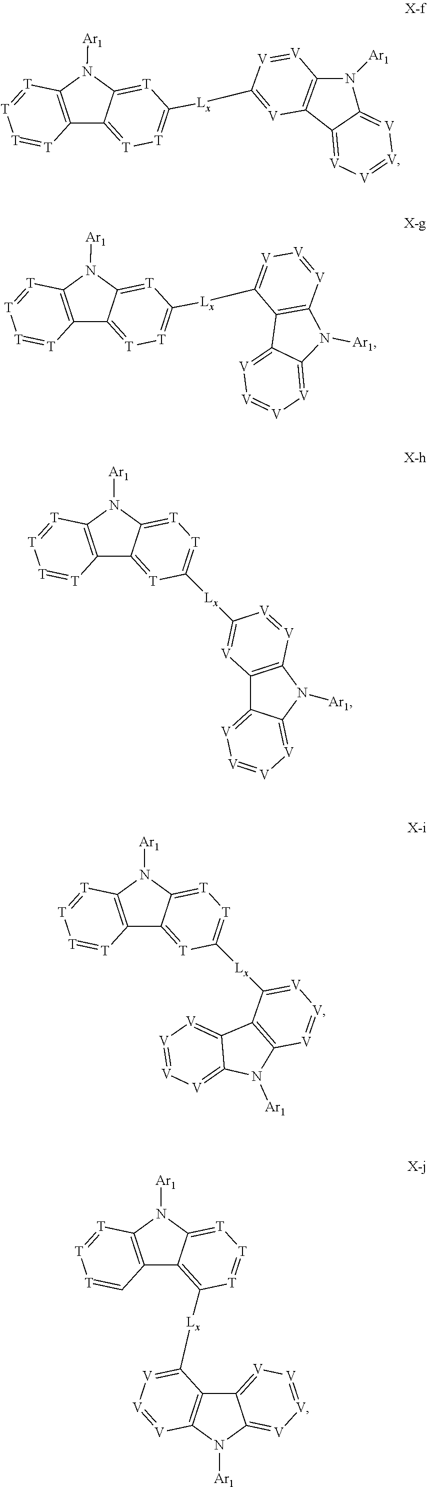

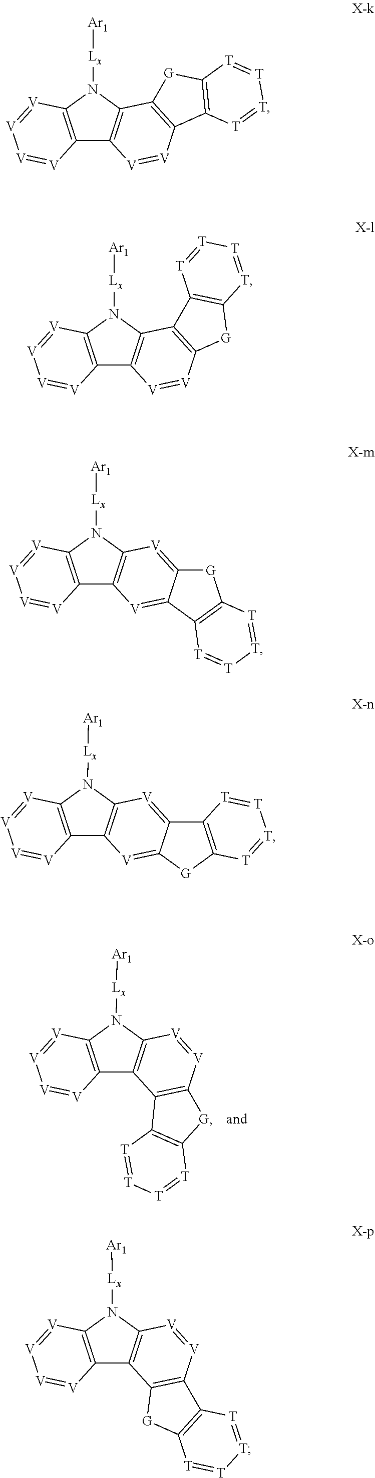

wherein,
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof,
G is, at each occurrence identically or differently, selected from C(R_{g})₂, NR_{g}, O or S;
V is, at each occurrence identically or differently, selected from CRᵥ, or N;
T is, at each occurrence identically or differently, selected from CRₜ or N;
R_{g}, Rᵥ, and Rₜ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
Ar₁ is, at each occurrence identically or differently, selected from substituted or unsubstituted aryl having 6 to 30 carbon atoms, substituted or unsubstituted heteroaryl having 3 to 30 carbon atoms, or a combination thereof,
adjacent substituents R_{g}, Rᵥ, and Rₜ can be optionally joined to form a ring.

According to an embodiment of the present disclosure, the first host compound is selected from the group consisting of the following compounds:

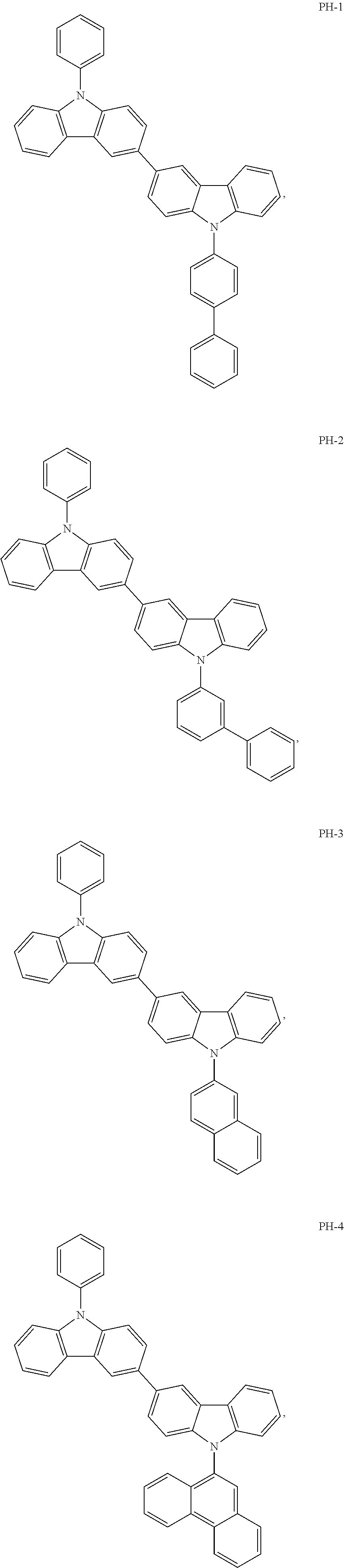 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cccc(-n3c4ccccc4c4cc(-c5ccc6c(c5)c5ccccc5n6-c5ccccc5)ccc43)c2)cc1 ; c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cc5ccccc5c5ccccc45)ccc32)cc1]

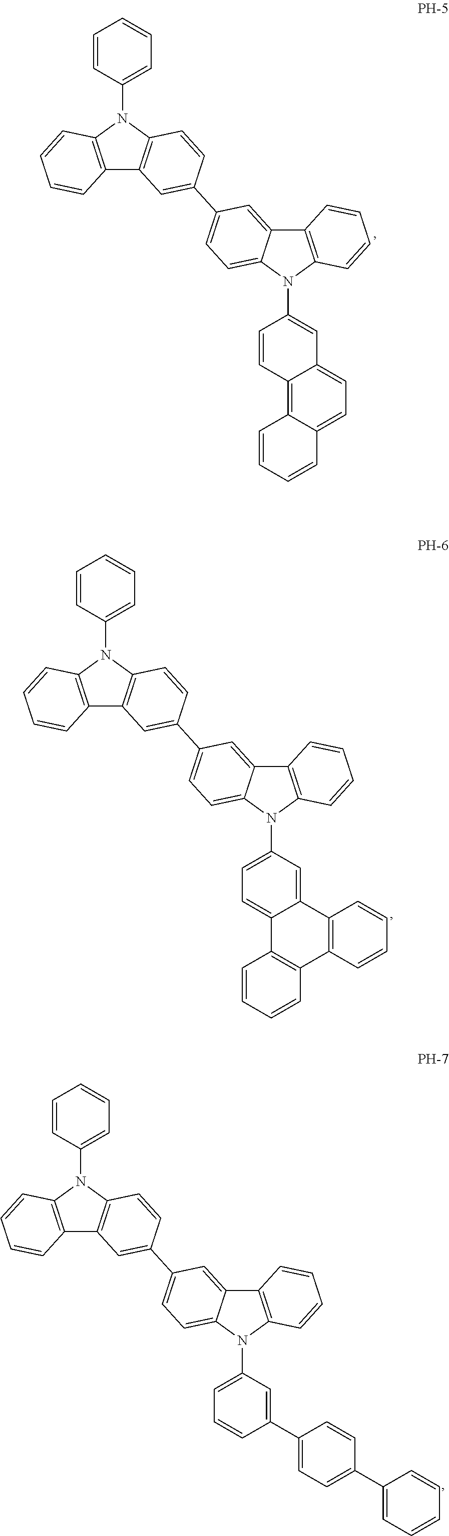 [SMILES: c1ccc(-n2c3ccccc3c3cc(-c4ccc5c(c4)c4ccccc4n5-c4ccc5c(ccc6ccccc65)c4)ccc32)cc1 ; c1ccc(-n2c3ccccc3c3cc(-c4ccc5c(c4)c4ccccc4n5-c4ccc5c6ccccc6c6ccccc6c5c4)ccc32)cc1 ; c1ccc(-c2ccc(-c3cccc(-n4c5ccccc5c5cc(-c6ccc7c(c6)c6ccccc6n7-c6ccccc6)ccc54)c3)cc2)cc1]

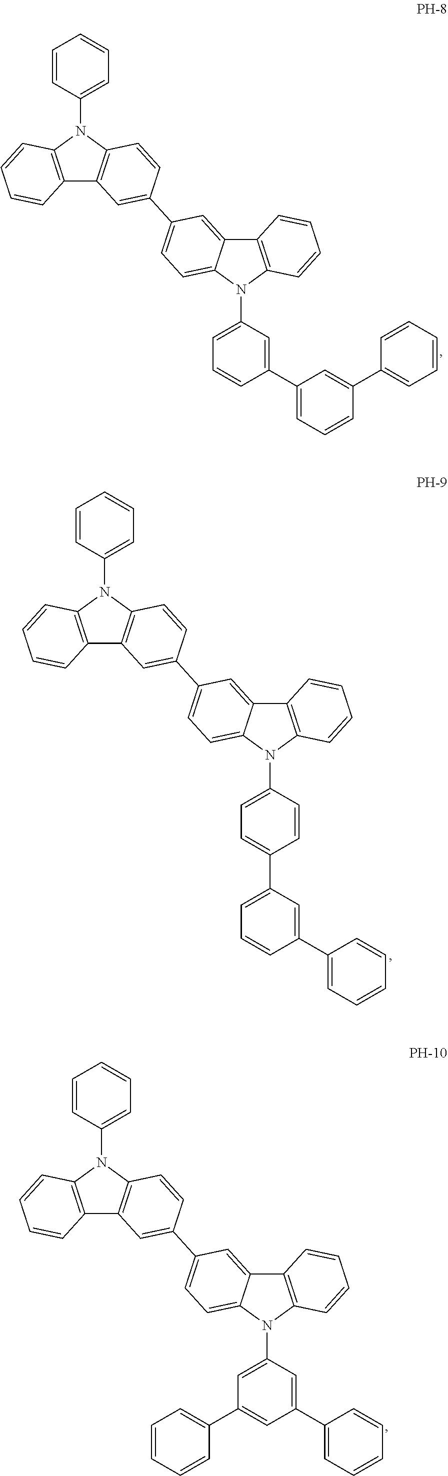 [SMILES: c1ccc(-c2cccc(-c3cccc(-n4c5ccccc5c5cc(-c6ccc7c(c6)c6ccccc6n7-c6ccccc6)ccc54)c3)c2)cc1 ; c1ccc(-c2cccc(-c3ccc(-n4c5ccccc5c5cc(-c6ccc7c(c6)c6ccccc6n7-c6ccccc6)ccc54)cc3)c2)cc1 ; c1ccc(-c2cc(-c3ccccc3)cc(-n3c4ccccc4c4cc(-c5ccc6c(c5)c5ccccc5n6-c5ccccc5)ccc43)c2)cc1]

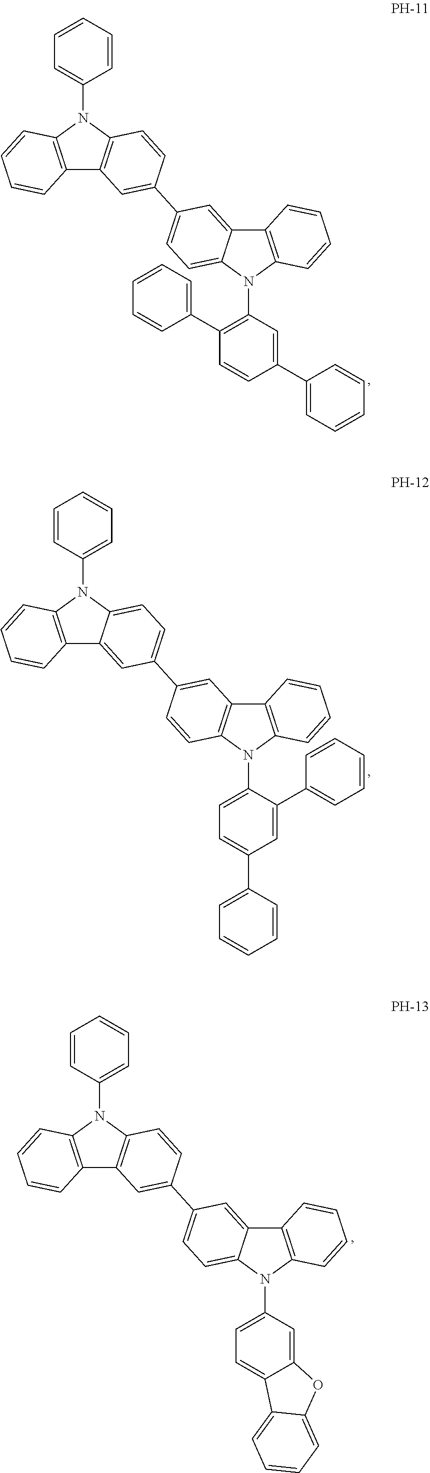 [SMILES: c1ccc(-c2ccc(-c3ccccc3)c(-n3c4ccccc4c4cc(-c5ccc6c(c5)c5ccccc5n6-c5ccccc5)ccc43)c2)cc1 ; c1ccc(-c2ccc(-n3c4ccccc4c4cc(-c5ccc6c(c5)c5ccccc5n6-c5ccccc5)ccc43)c(-c3ccccc3)c2)cc1 ; c1ccc(-n2c3ccccc3c3cc(-c4ccc5c(c4)c4ccccc4n5-c4ccc5c(c4)oc4ccccc45)ccc32)cc1]

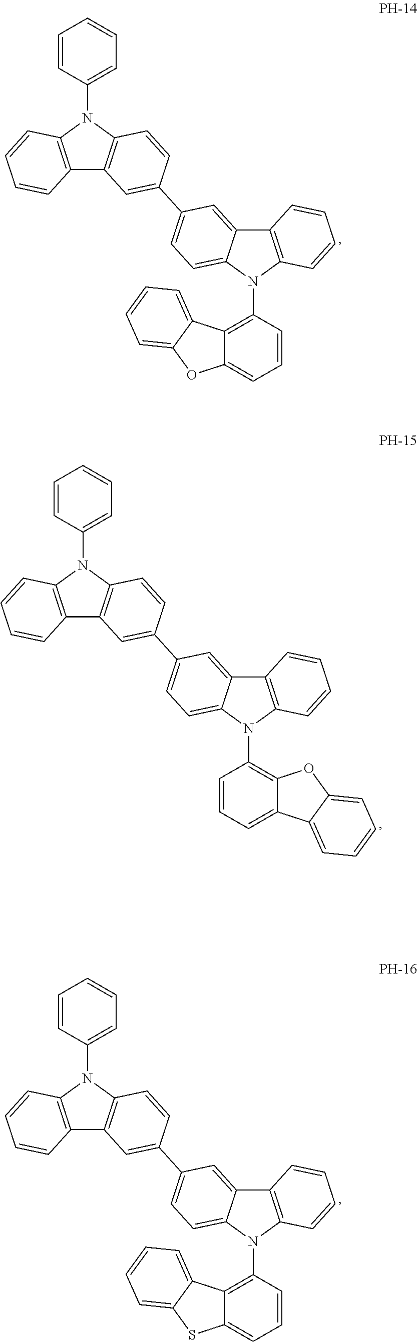 [SMILES: c1ccc(-n2c3ccccc3c3cc(-c4ccc5c(c4)c4ccccc4n5-c4cccc5oc6ccccc6c45)ccc32)cc1 ; c1ccc(-n2c3ccccc3c3cc(-c4ccc5c(c4)c4ccccc4n5-c4cccc5c4oc4ccccc45)ccc32)cc1 ; c1ccc(-n2c3ccccc3c3cc(-c4ccc5c(c4)c4ccccc4n5-c4cccc5sc6ccccc6c45)ccc32)cc1]

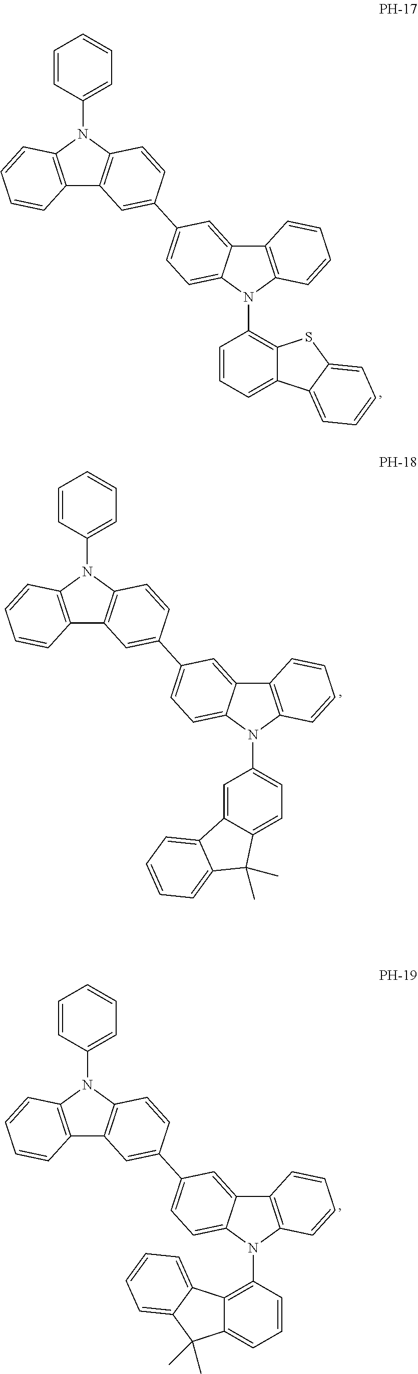 [SMILES: c1ccc(-n2c3ccccc3c3cc(-c4ccc5c(c4)c4ccccc4n5-c4cccc5c4sc4ccccc45)ccc32)cc1 ; CC1(C)c2ccccc2-c2cc(-n3c4ccccc4c4cc(-c5ccc6c(c5)c5ccccc5n6-c5ccccc5)ccc43)ccc21 ; CC1(C)c2ccccc2-c2c(-n3c4ccccc4c4cc(-c5ccc6c(c5)c5ccccc5n6-c5ccccc5)ccc43)cccc21]

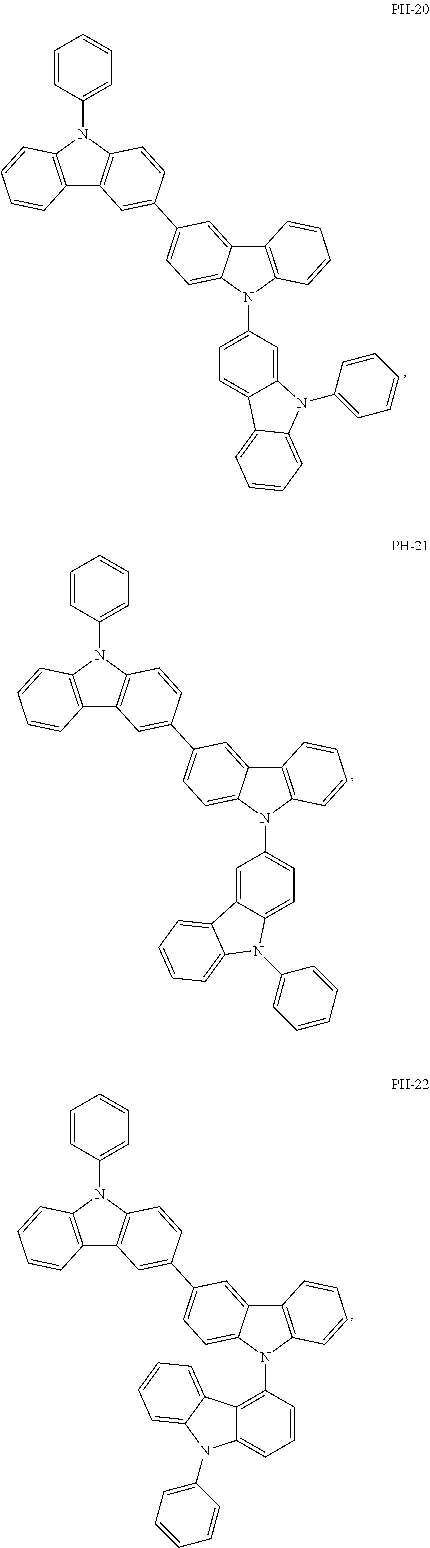 [SMILES: c1ccc(-n2c3ccccc3c3cc(-c4ccc5c(c4)c4ccccc4n5-c4ccc5c6ccccc6n(-c6ccccc6)c5c4)ccc32)cc1 ; c1ccc(-n2c3ccccc3c3cc(-c4ccc5c(c4)c4ccccc4n5-c4ccc5c(c4)c4ccccc4n5-c4ccccc4)ccc32)cc1 ; c1ccc(-n2c3ccccc3c3cc(-c4ccc5c(c4)c4ccccc4n5-c4cccc5c4c4ccccc4n5-c4ccccc4)ccc32)cc1]

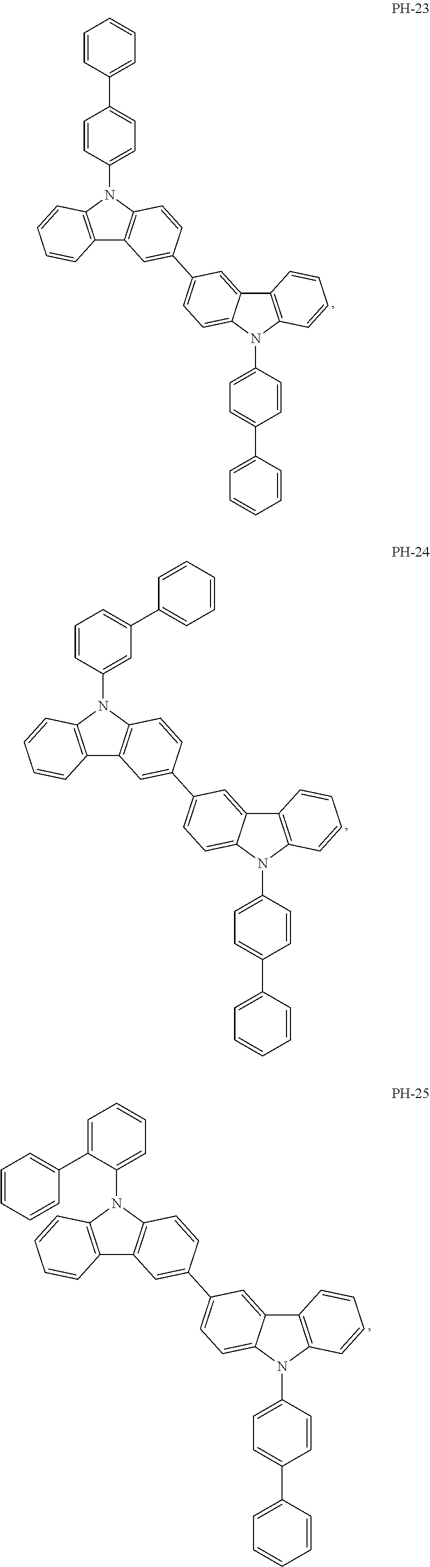 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5-c5ccccc5)ccc43)cc2)cc1]

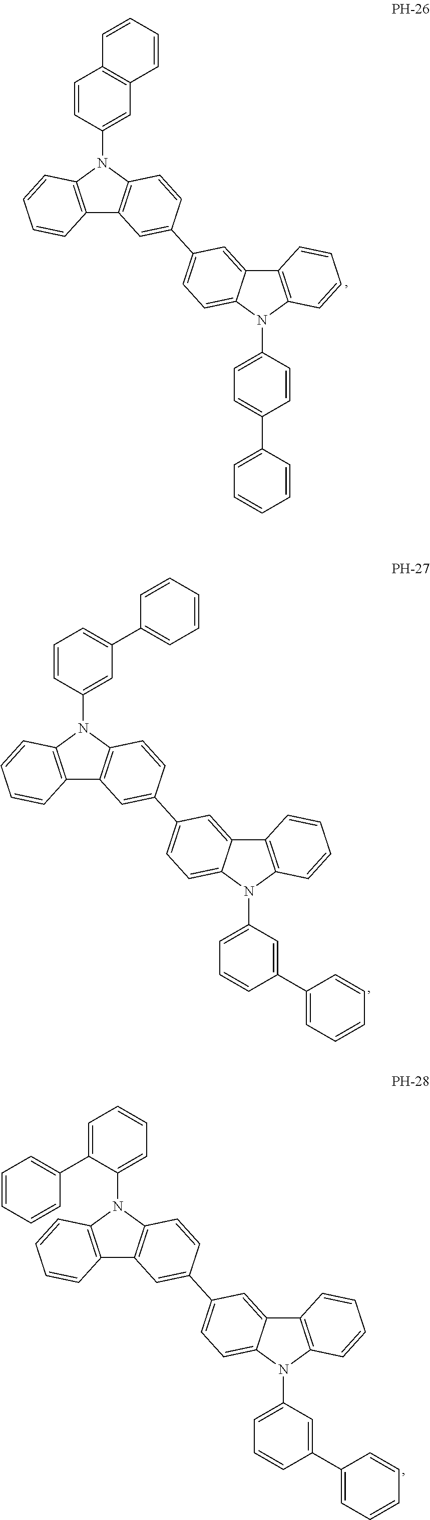 [SMILES: c1ccc(-c2ccc(-n3c4ccccc4c4cc(-c5ccc6c(c5)c5ccccc5n6-c5ccc6ccccc6c5)ccc43)cc2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5-c5ccccc5)ccc43)c2)cc1]

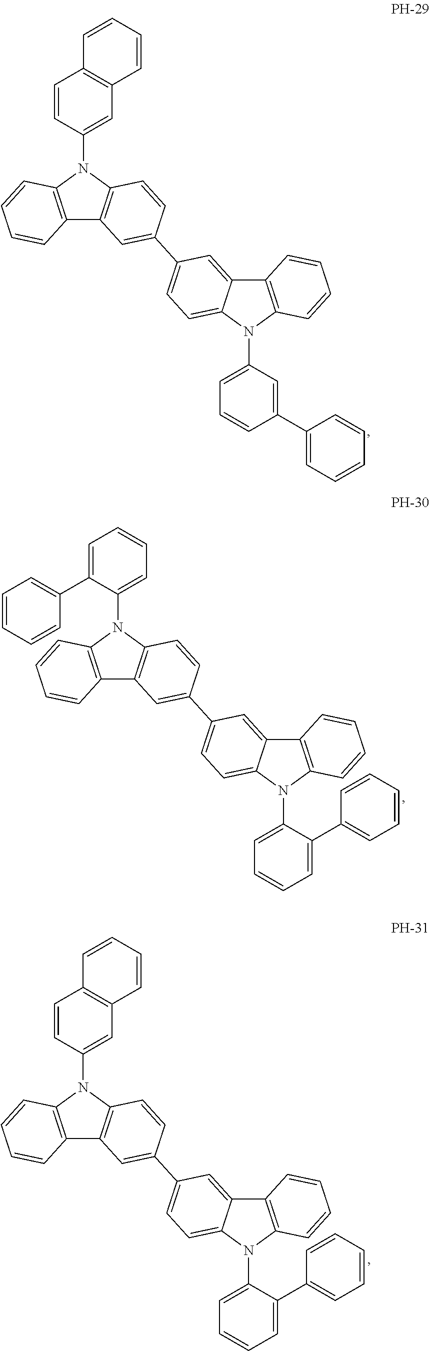 [SMILES: c1ccc(-c2cccc(-n3c4ccccc4c4cc(-c5ccc6c(c5)c5ccccc5n6-c5ccc6ccccc6c5)ccc43)c2)cc1 ; c1ccc(-c2ccccc2-n2c3ccccc3c3cc(-c4ccc5c(c4)c4ccccc4n5-c4ccccc4-c4ccccc4)ccc32)cc1 ; c1ccc(-c2ccccc2-n2c3ccccc3c3cc(-c4ccc5c(c4)c4ccccc4n5-c4ccc5ccccc5c4)ccc32)cc1]

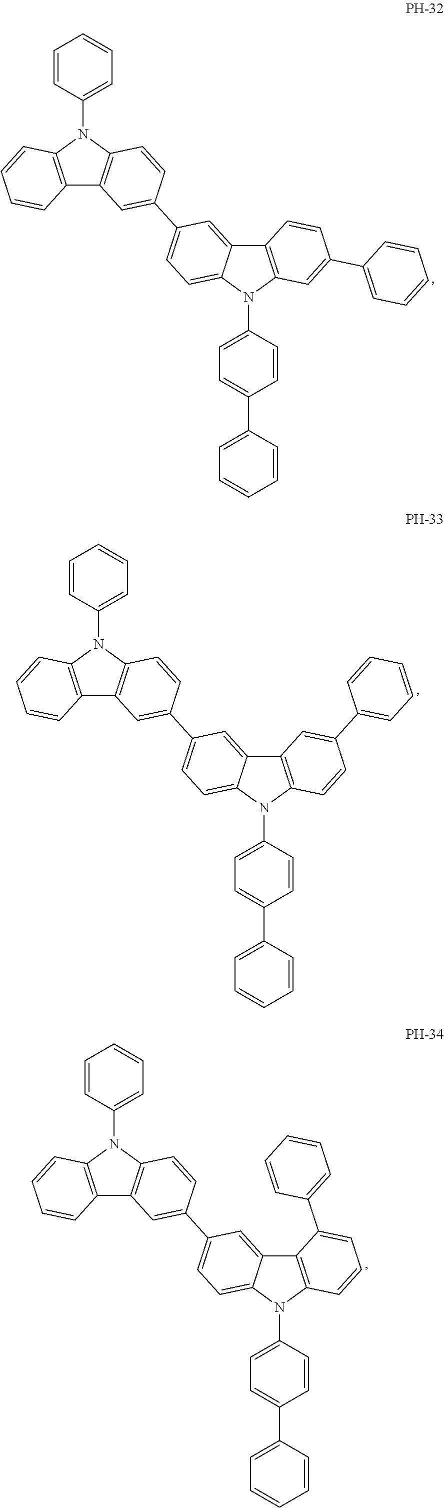 [SMILES: c1ccc(-c2ccc(-n3c4ccc(-c5ccc6c(c5)c5ccccc5n6-c5ccccc5)cc4c4ccc(-c5ccccc5)cc43)cc2)cc1 ; c1ccc(-c2ccc(-n3c4ccc(-c5ccccc5)cc4c4cc(-c5ccc6c(c5)c5ccccc5n6-c5ccccc5)ccc43)cc2)cc1 ; c1ccc(-c2ccc(-n3c4ccc(-c5ccc6c(c5)c5ccccc5n6-c5ccccc5)cc4c4c(-c5ccccc5)cccc43)cc2)cc1]

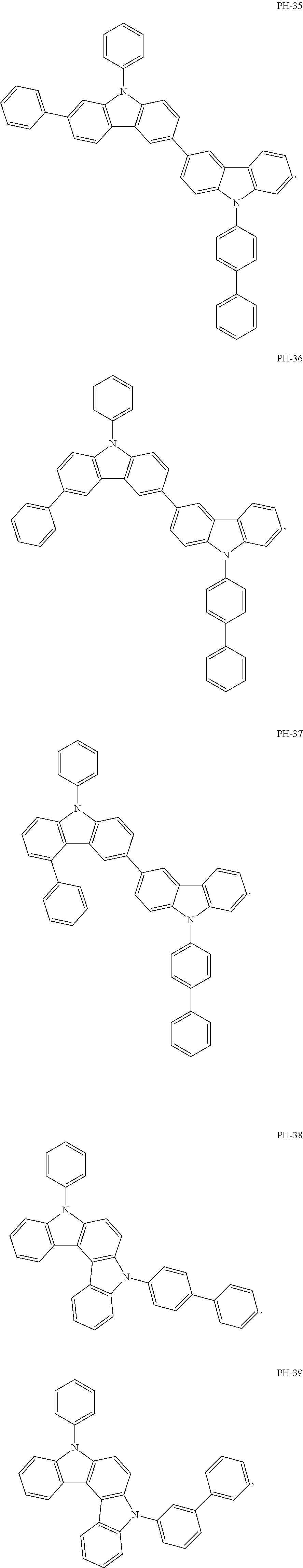 [SMILES: c1ccc(-c2ccc(-n3c4ccccc4c4cc(-c5ccc6c(c5)c5ccc(-c7ccccc7)cc5n6-c5ccccc5)ccc43)cc2)cc1 ; c1ccc(-c2ccc(-n3c4ccccc4c4cc(-c5ccc6c(c5)c5cc(-c7ccccc7)ccc5n6-c5ccccc5)ccc43)cc2)cc1 ; c1ccc(-c2ccc(-n3c4ccccc4c4cc(-c5ccc6c(c5)c5c(-c7ccccc7)cccc5n6-c5ccccc5)ccc43)cc2)cc1 ; c1ccc(-c2ccc(-n3c4ccccc4c4c5c6ccccc6n(-c6ccccc6)c5ccc43)cc2)cc1 ; c1ccc(-c2cccc(-n3c4ccccc4c4c5c6ccccc6n(-c6ccccc6)c5ccc43)c2)cc1]

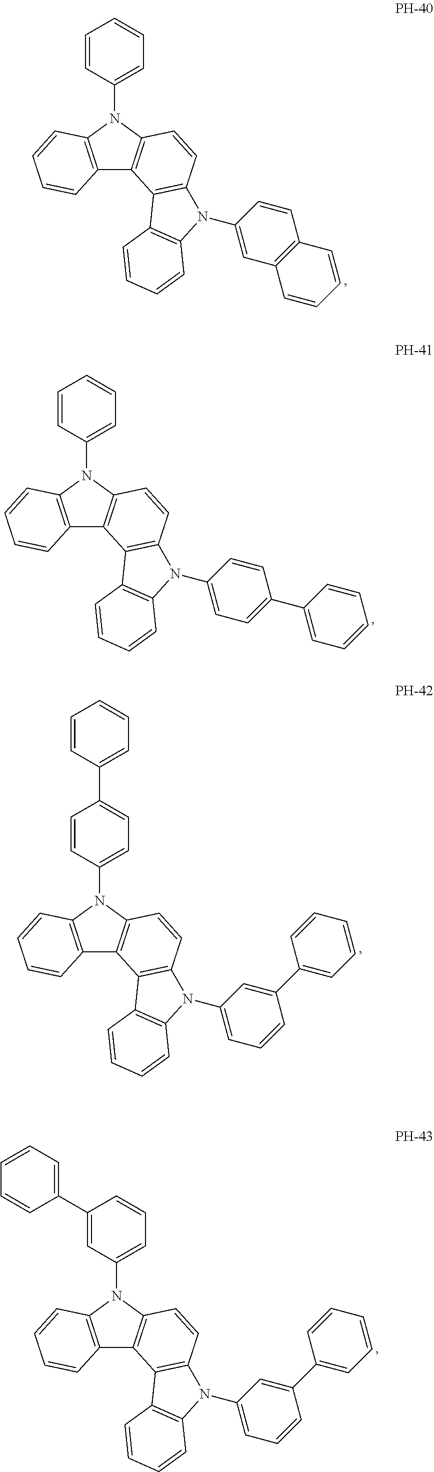 [SMILES: c1ccc(-n2c3ccccc3c3c4c5ccccc5n(-c5ccc6ccccc6c5)c4ccc32)cc1 ; c1ccc(-c2ccc(-n3c4ccccc4c4c5c6ccccc6n(-c6ccccc6)c5ccc43)cc2)cc1 ; c1ccc(-c2ccc(-n3c4ccccc4c4c5c6ccccc6n(-c6cccc(-c7ccccc7)c6)c5ccc43)cc2)cc1 ; c1ccc(-c2cccc(-n3c4ccccc4c4c5c6ccccc6n(-c6cccc(-c7ccccc7)c6)c5ccc43)c2)cc1]

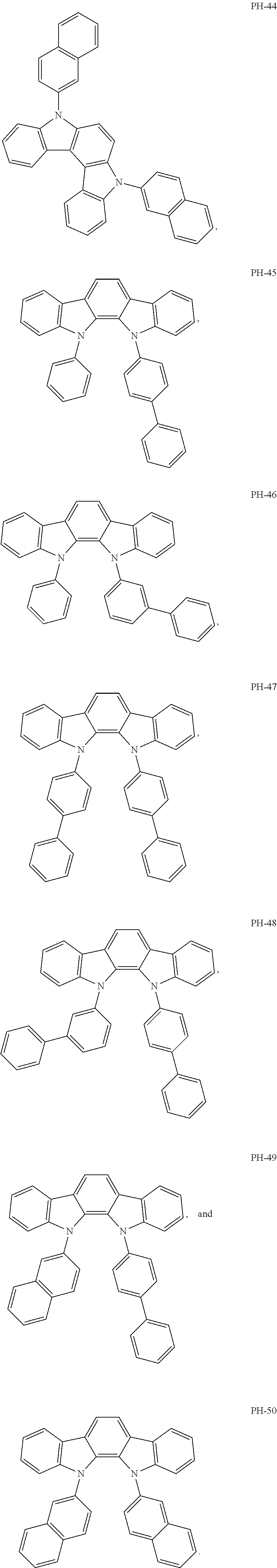

According to an embodiment of the present disclosure, the second host compound has a structure represented by Formula 5:

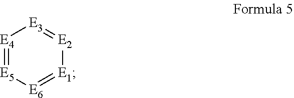

wherein,
E₁ to E₆ are, at each occurrence identically or differently, selected from C, CRₑ or N, at least two of E₁ to E₆ are N, and at least one of E₁ to E₆ is C and joined to Formula A;

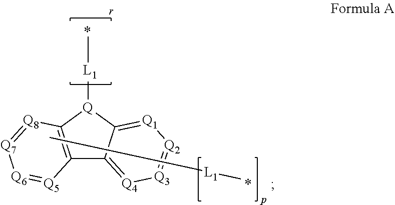

wherein,
Q is, at each occurrence identically or differently, selected from the group consisting of O, S, Se, N, NR_{Q}, CR_{Q}R_{Q}, SiR_{Q}R_{Q}, GeR_{Q}R_{Q}, and R_{Q}C═CR_{Q}; when two R_{Q} are present at the same time, the two R_{Q} may be the same or different;
p is 0 or 1, and r is 0 or 1;
when Q is selected from N, p is 0, and r is 1;
when Q is selected from the group consisting of O, S, Se, NR_{Q}, CR_{Q}R_{Q}, SiR_{Q}R_{Q}, GeR_{Q}R_{Q}, and R_{Q}C═CR_{Q}, p is 1 and r is 0;
L₁ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof,
Q₁ to Q₈ are, at each occurrence identically or differently, selected from C, CR_{q} or N;
Rₑ, R_{Q}, and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
“*” represents the position of attachment of Formula A to Formula 5;
adjacent substituents Rₑ, R_{Q}, and R_{q} can be optionally joined to form a ring.

Herein, the expression that “adjacent substituents Rₑ, R_{Q}, and R_{q} can be optionally joined to form a ring” is intended to mean that any one or more of groups of adjacent substituents, such as two substituents Rₑ, two substituents R_{Q}, two substituents R_{q}, and two substituents R_{Q} and R_{q}, can be joined to form a ring. Obviously, it is possible that none of these substituents are joined to form a ring.

According to an embodiment of the present disclosure, the second host compound is selected from the group consisting of the following compounds:

[chemical structure]

[chemical structure]

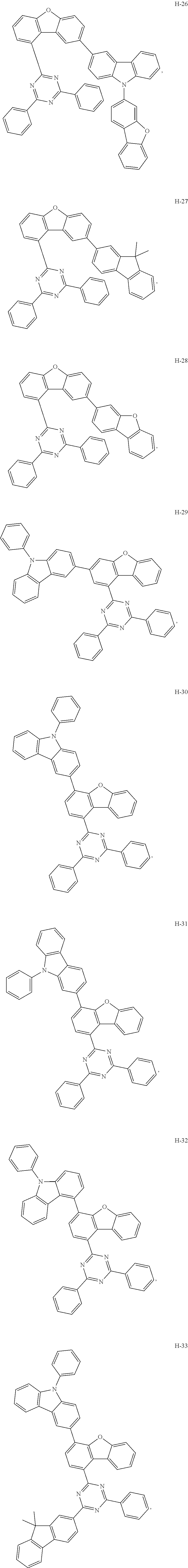

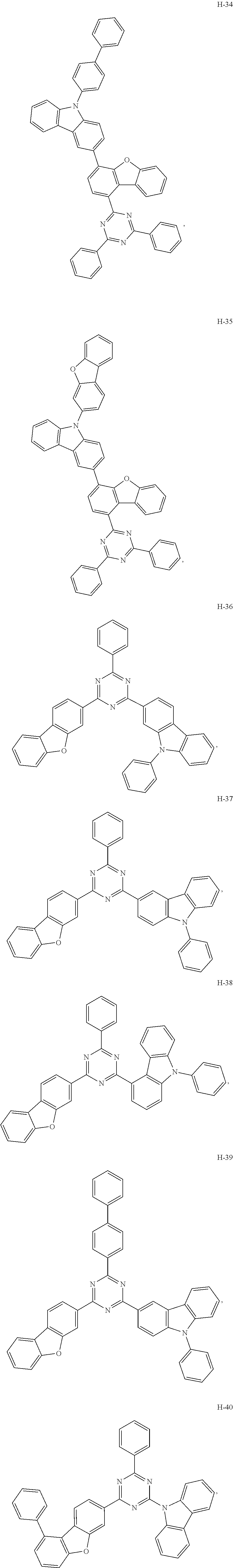

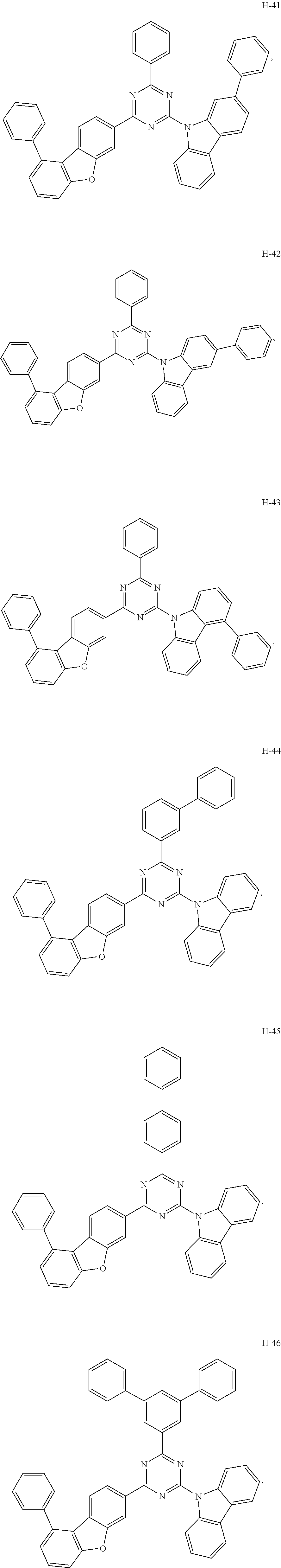

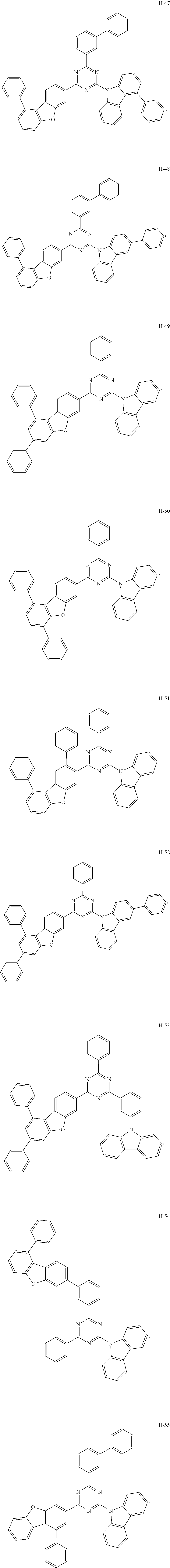

[chemical structure]

[chemical structure]

[chemical structure]

According to an embodiment of the present disclosure, the metal complex is doped in the first host compound and the second host compound, and the weight of the mental complex accounts for 1% to 30% of the total weight of the emissive layer.

According to an embodiment of the present disclosure, the metal complex is doped in the first host compound and the second host compound, and the weight of the metal complex accounts for 3% to 13% of the total weight of the emissive layer.

According to an embodiment of the present disclosure, the organic electroluminescent device further includes a hole injection layer. The hole injection layer may be a functional layer containing a single material or a functional layer containing a variety of materials, wherein the most commonly used ones among the variety of materials contained are hole transport materials doped with a certain proportion of p-type conductive doped material. Common p-type doped materials are as follows:

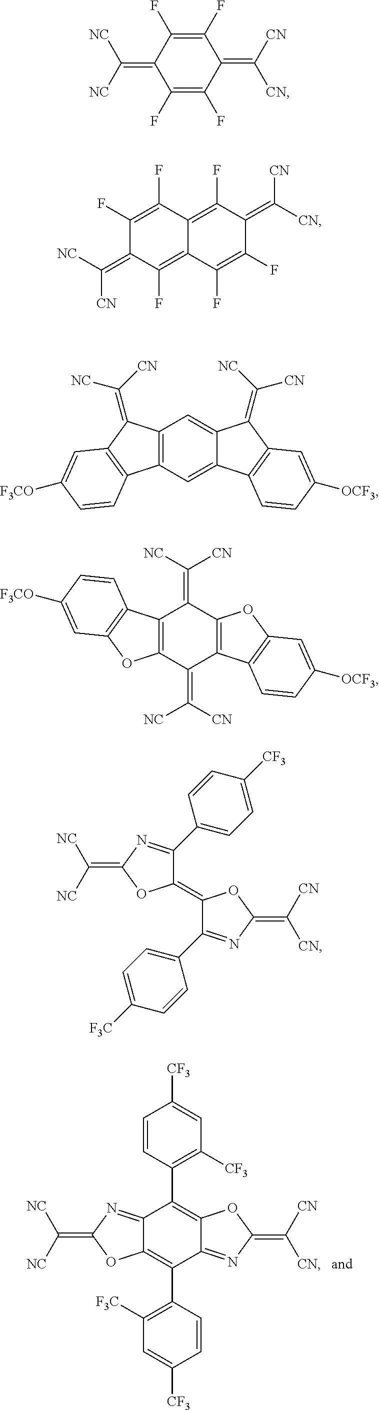

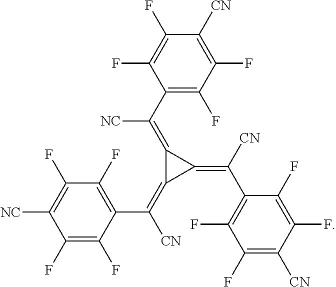 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

According to an embodiment of the present disclosure, a compound composition is further disclosed. The compound composition includes the metal complex described in any one of the preceding embodiments.

Combination with Other Materials

The materials described in the present disclosure for a particular layer in an organic light-emitting device can be used in combination with various other materials present in the device. The combinations of these materials are described in more detail in U.S. Pat. App. Pub. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light-emitting device may be used in combination with a variety of other materials present in the device. For example, dopants disclosed herein may be used in combination with a wide variety of hosts, transport layers, blocking layers, injection layers, electrodes and other layers that may be present. The combination of these materials is described in detail in paragraphs 0080-0101 of U.S. Pat. App. Pub. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FATAR, life testing system produced by SUZHOU FATAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

### MATERIAL SYNTHESIS EXAMPLE

### Synthesis Example 1: Synthesis of Metal Complex 225-2

### Step 1:

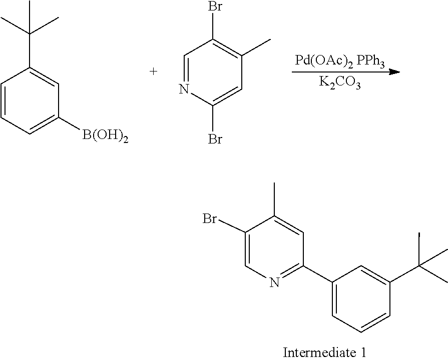

3-tert-butylbenzeneboronic acid (17.8 g, 100.0 mmol), 2,5-dibromo-4-methylpyridine (30.1 g, 120.0 mmol), palladium acetate (Pd(OAc)₂, 0.8 g, 3.5 mmol), triphenylphosphine (PPh₃, 1.8 g, 7.0 mmol), potassium carbonate (K₂CO₃, 27.6 g, 200.0 mmol), acetonitrile (180 mL), and water (60 mL) were sequentially added to a 500 mL dry round-bottom flask and purged with N₂ three times, and the reaction was heated at 55° C. with stirring for 24 h under N₂ protection. After the reaction was completed, the reaction mixture was extracted with ethyl acetate, washed three times with saturated brine, dried with anhydrous magnesium sulfate, and concentrated under reduced pressure. The crude product was purified by column chromatography to give 22 g of the product Intermediate 1 as a colorless liquid (with a yield of 99.0%).

### Step 2:

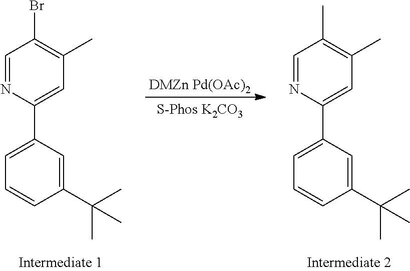

Intermediate 1 (31.0 g, 101.7 mmol), palladium acetate (Pd(OAc)₂, 0.9 g, 4.0 mmol), S-phos (3.2 g, 8.0 mmol), potassium carbonate (K₂CO₃, 28.2 g, 204.0 mmol), and anhydrous tetrahydrofuran (300 mL) were sequentially added to a 1000 mL dry round-bottom flask, purged with nitrogen three times, and cooled in an ice bath (0° C.) with stirring for 5 min under nitrogen protection, dimethylzinc (DMZn, 81.5 mL, 1 M) was slowly added in batches, and after the addition was completed, the reaction was stirred at room temperature for 12 h. After the reaction was completed, the reaction mixture was quenched with saturated ammonium chloride aqueous solution, extracted with ethyl acetate, washed three times with saturated brine, dried with anhydrous magnesium sulfate, and concentrated under reduced pressure. The crude product was purified by column chromatography to give 16.4 g of the product Intermediate 2 as a colorless liquid (with a yield of 67.4%).

### Step 3:

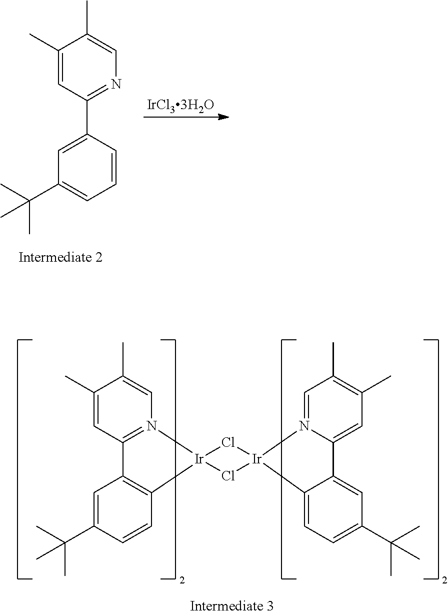

Intermediate 2 (16.4 g, 52.9 mmol), iridium trichloride trihydrate (IrCl₃·3H₂O, 7.1 g, 20.0 mmol), 300 mL of 2-ethoxyethanol, and 100 mL of water were sequentially added to a 500 mL dry round-bottom flask, purged with nitrogen three times, and heated at 130° C. with stirring for 24 h under nitrogen protection. After the reaction was completed, the reaction mixture was filtered, washed three times with methanol and n-hexane, respectively, and suction-filtered to dryness to give 13.0 g of Intermediate 3 (with a yield of 92.3%).

### Step 4:

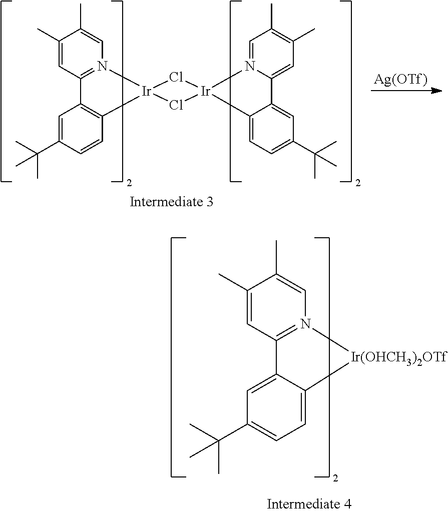

Intermediate 3 (13.0 g, 7.7 mmol), 350 mL of anhydrous dichloromethane, 15 mL of methanol, and silver trifluoromethanesulfonate (Ag(OTf), 5.0 g, 19.4 mmol) were sequentially added to a 500 mL dry round-bottom flask and purged with nitrogen three times, and the reaction was stirred at room temperature for 24 h under nitrogen protection. After the reaction was completed, the reaction mixture was filtered through Celite and washed twice with dichloromethane. The organic phases below were collected and concentrated under reduced pressure to give 17.5 g of Intermediate 4 as a yellow solid (with a yield of 95%).

### Step 5:

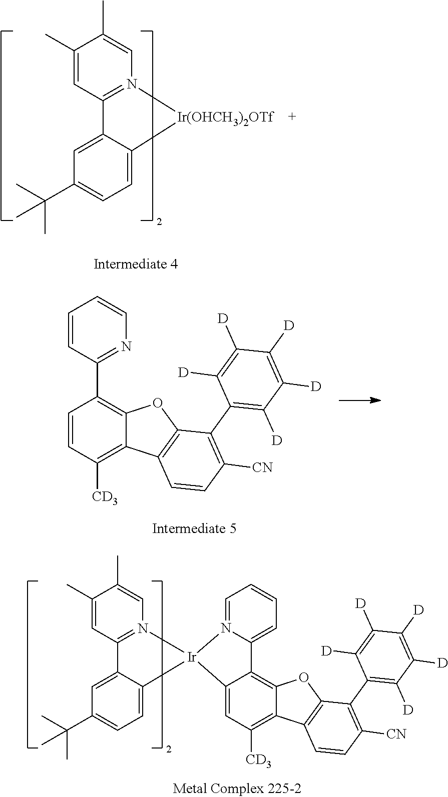

Intermediate 4 (3.1 g, 3.5 mmol), Intermediate 5 (1.8 g, 4.9 mmol), 2-ethoxyethanol (40 mL), and DMF (40 mL) were sequentially added to a 250 mL dry round-bottom flask and purged with nitrogen three times, and the reaction was heated at 100° C. for 5 days under nitrogen protection. After the reaction was completed, the reaction mixture was concentrated under reduced pressure and purified by column chromatography to give Metal Complex 225-2 as a yellow solid (1.6 g, 1.5 mmol, with a yield of 44%). The product was confirmed as the target product with a molecular weight of 1036.5.

### Synthesis Example 2: Synthesis of Metal Complex 238-2

### Step 1:

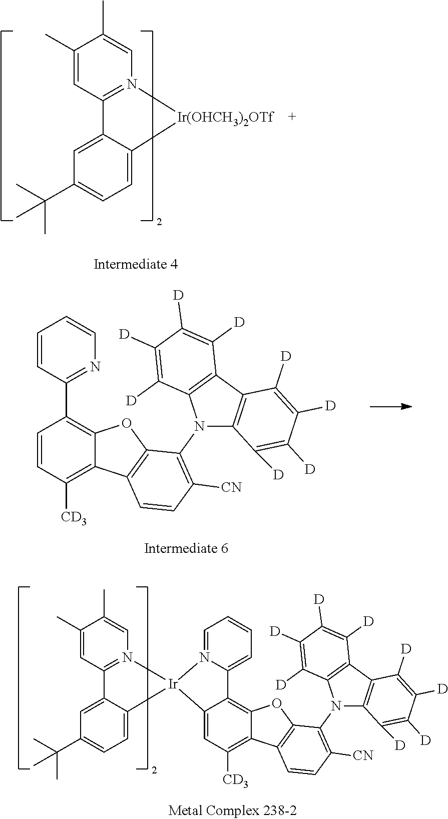

Intermediate 4 (2.0 g, 2.2 mmol), Intermediate 6 (1.4 g, 3.0 mmol), 2-ethoxyethanol (40 mL), and DMF (40 mL) were sequentially added to a 250 mL dry round-bottom flask and purged with nitrogen three times, and the reaction was heated at 100° C. for 5 days under nitrogen protection. After the reaction was completed, the reaction mixture was concentrated under reduced pressure and purified by column chromatography to give Metal Complex 238-2 as a yellow solid (1.2 g, with a yield of 48.3%). The product was confirmed as the target product with a molecular weight of 1128.5.

The persons skilled in the art will appreciate that the above preparation methods are merely exemplary. The persons skilled in the art can obtain other compound structures of the present disclosure via modifications of the preparation methods.

### DEVICE EXAMPLE

### Device Example 1

First, a glass substrate having an indium tin oxide (ITO) anode (whose sheet resistance was 14 to 20 Ω/sq and emission area was 0.04 cm²) with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. Organic layers specified below were sequentially deposited through vacuum thermal evaporation on the ITO anode at a rate of 0.2 to 2 Angstroms per second at a vacuum degree of about 10⁻⁸ torr. Compound HI was deposited as a hole injection layer (HIL). Compound HT was deposited as a hole transport layer (HTL). Compound PH-23 was deposited as an electron blocking layer (EBL). Metal Complex 225-2 of the present disclosure was doped in Compound PH-23 and Compound H-40, and the resulting mixture was co-deposited as an emissive layer (EML). On the EML, Compound HB was deposited as a hole blocking layer (HBL). On the HBL, Compound ET and 8-hydroxyquinolinolato-lithium (Liq) were co-deposited as an electron transport layer (ETL). Finally, 8-hydroxyquinolinolato-lithium (Liq) with a thickness of 1 nm was deposited as an electron injection layer, and A1 with a thickness of 120 nm was deposited as a cathode. The device was transferred back to the glovebox and encapsulated with a glass lid and a moisture absorbent to complete the device.

### Device Comparative Example 1

The implementation in Device Comparative Example 1 was the same as the implementation in Device Example 1 except that in the emissive layer (EML), Metal Complex 225-2 of the present disclosure was replaced with Compound GD1.

### Device Comparative Example 2

The implementation in Device Comparative Example 2 was the same as the implementation in Device Example 1 except that in the emissive layer (EML), Metal Complex 225-2 of the present disclosure was replaced with Compound GD2.

Detailed structures and thicknesses of layers of the devices are shown in the following table. The layers using more than one material were obtained by doping different compounds at their mass ratios as recorded.

TABLE 1
Device structures in Example 1 and Comparative Examples 1 to 2

| Device ID | HIL | HTL | EBL | EML | HBL | ETL |
|---|---|---|---|---|---|---|
| Example 1 | Compound | Compound | Compound | Compound PH-23:Compound H-40:Metal | Compound | Compound ET:Liq |
| | HI (100 Å) | HT (350 Å) | PH-23 (50 Å) | Complex 225-2 (56:38:6) (400 Å) | HB (50 Å) | (40:60) (350 Å) |
| Comparative | Compound | Compound | Compound | Compound PH-23:Compound H-40:Compound | Compound | Compound ET:Liq |
| Example 1 | HI (100 Å) | HT (350 Å) | PH-23 (50 Å) | GD1 (56:38:6) (400 Å) | HB (50 Å) | (40:60) (350 Å) |
| Comparative | Compound | Compound | Compound | Compound PH-23:Compound H-40:Compound | Compound | Compound ET:Liq |
| Example 2 | HI (100 Å) | HT (350 Å) | PH-23 (50 Å) | GD2 (56:38:6) (400 Å) | HB (50 Å) | (40:60) (350 Å) |

The structures of the materials used in the devices are as follows:

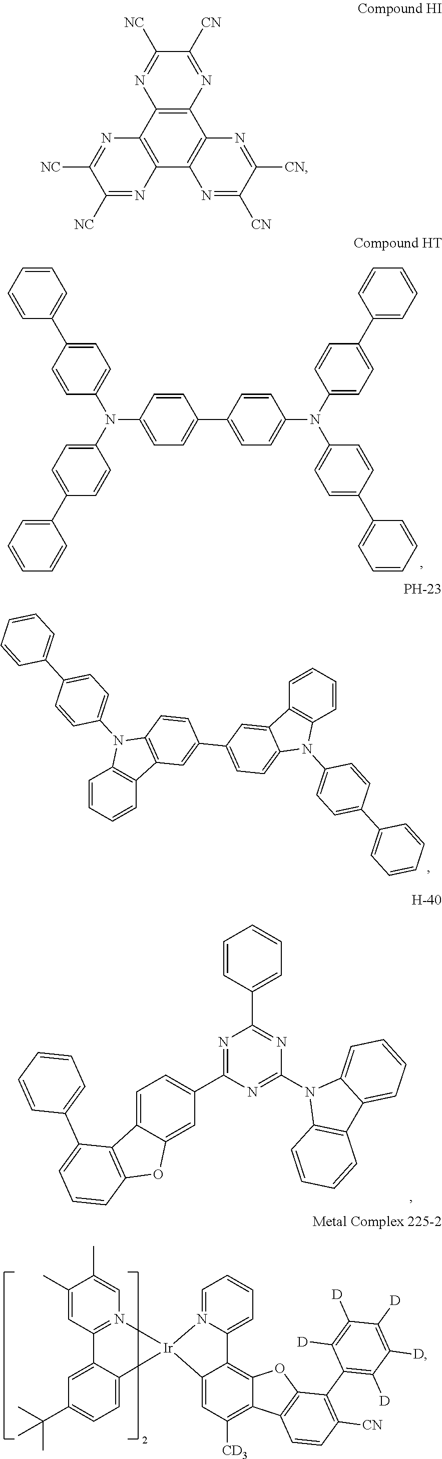

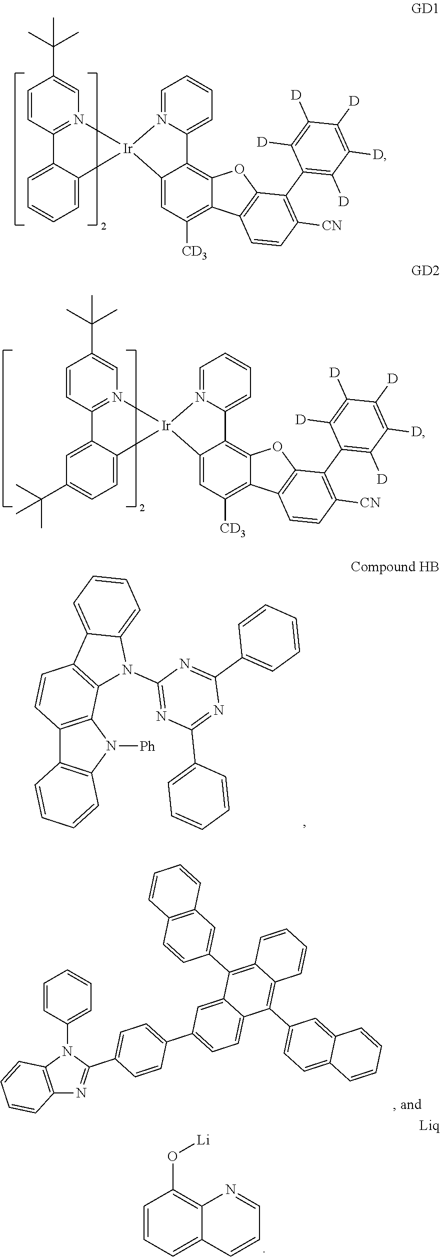

The IVL properties of the devices were measured. The CIE data, maximum emission wavelength (λₘₐₓ), current efficiency (CE), external quantum efficiency (EQE), and lifetime (LT97) of each device were measured at 15 mA/cm². The capacitance of each device was tested using an impedance analyzer (Keysight E4990A): a direct current bias voltage of −4 V to 5 V was applied to the electrodes at both ends of the device, a sinusoidal alternating current voltage signal of 100 mV was superimposed, and the capacitance was separately tested at an alternating current voltage with a frequency of 500 Hz. The C-V curve of each device was measured, the maximum capacitance (Cₘₐₓ) of each device was obtained, and these data are recorded and shown in Table 2.

TABLE 2
Device data in Example 1 and Comparative Examples 1 to 2

| | CIE | λmax | CE | EQE | LT97 | |
|---|---|---|---|---|---|---|
| Device ID | (x, y) | (nm) | (cd/m²) | (%) | (h) | Cₘₐₓ/nF |
| Example 1 | (0.330, | 527 | 93.66 | 24.14 | 718 | 2.10 |
| | 0.640) | | | | | |
| Comparative | (0.294, | 521 | 88.43 | 23.12 | 547 | 3.61 |
| Example 1 | 0.660) | | | | | |
| Comparative | (0.317, | 524 | 91.55 | 23.61 | 476 | 3.28 |
| Example 2 | 0.648) | | | | | |

### Discussion

With the comparison between Example 1 and both Comparative Example 1 and Comparative Example 2, the emissive materials used in Example 1, Comparative Example 1, and Comparative Example 2 had the same ligand Lₐ, but different ligands L_{b}. As can be seen from data in Table 2, at 15 mA/cm², with the comparison between Example 1 and both Comparative Example 1 and Comparative Example 2, the current efficiency (CE) in Example 1 was 5.9% and 2.3% higher than that in Comparative Example 1 and Comparative Example 2, respectively, and the external quantum efficiency (EQE) in Example 1 was 4.4% and 2.2% higher than that in Comparative Example 1 and Comparative Example 2, respectively; at 15 mA/cm², the lifetime (LT97) in Example 1 was 31.3% and 50.8% longer than that in Comparative Example 1 and Comparative Example 2, respectively. Moreover, the maximum capacitance in Example 1 was significantly reduced compared with that in Comparative Example 1 and Comparative Example 2, by 1.51 nF and 1.18 nF, respectively. Therefore, the metal complex provided by the present disclosure can provide the device with better performance.

### Device Example 2

The implementation in Device Example 2 was the same as the implementation in Device Example 1 except that in the emissive layer (EML), Metal Complex 225-2 of the present disclosure was replaced with Metal Complex 238-2 of the present disclosure and the ratio of Compound PH-23, Compound H-40 and Metal Complex 238-2 in the emissive layer was 47:47:6.

### Device Comparative Example 3

The implementation in Device Comparative Example 3 was the same as the implementation in Device Example 2 except that in the emissive layer (EML), Metal Complex 238-2 of the present disclosure was replaced with Compound GD3.

### Device Comparative Example 4

The implementation in Device Comparative Example 4 was the same as that in Device Example 2 except that in the emissive layer (EML), Metal Complex 238-2 of the present disclosure was replaced with Compound GD4.

Detailed structures and thicknesses of layers of the devices are shown in the following table. The layers using more than one material were obtained by doping different compounds at their, mass ratios as recorded.

TABLE 3
Device structures in Example 2 and Comparative Examples 3 to 4

| Device ID | HIL | HTL | EBL | EML | HBL | ETL |
|---|---|---|---|---|---|---|
| Example 2 | Compound | Compound | Compound | Compound PH-23:Compound H-40:Metal | Compound | Compound ET:Liq |
| | HI (100 Å) | HT (350 Å) | PH-23 (50 Å) | Complex 238-2 (47:47:6) (400 Å) | HB (50 Å) | (40:60) (350 Å) |
| Comparative | Compound | Compound | Compound | Compound PH-23:Compound H-40:Compound | Compound | Compound ET:Liq |
| Example 3 | HI (100 Å) | HT (350 Å) | PH-23 (50 Å) | GD3 (47:47:6) (400 Å) | HB (50 Å) | (40:60) (350 Å) |
| Comparative | Compound | Compound | Compound | Compound PH-23:Compound H-40:Compound | Compound | Compound ET:Liq |
| Example 4 | HI (100 Å) | HT (350 Å) | PH-23 (50 Å) | GD4 (47:47:6) (400 Å) | HB (50 Å) | (40:60) (350 Å) |

The structures of the new materials used in the devices are as followed:

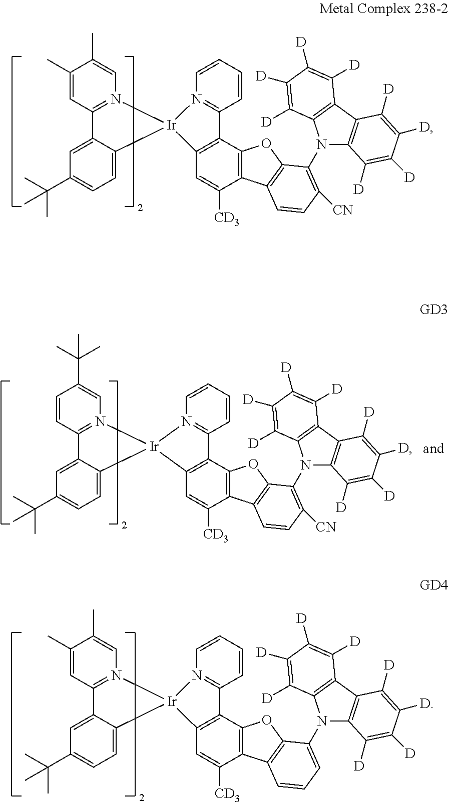

The IVL properties of the devices were measured. The CIE data, maximum emission wavelength (λₘₐₓ), current efficiency (CE), external quantum efficiency (EQE), and lifetime (LT97) of each device were measured at 15 mA/cm². The capacitance of each device was tested using an impedance analyzer (Keysight E4990A): a direct current bias voltage of −4 V to 5 V was applied to the electrodes at both ends of the device, a sinusoidal alternating current voltage signal of 100 mV was superimposed, and the capacitance was separately tested at an alternating current voltage with a frequency of 500 Hz. The C-V curve of each device was measured, the maximum capacitance (Cₘₐₓ) of each device was obtained, and these data are recorded and shown in Table 4.

TABLE 4
Device data in Example 2 and Comparative Examples 3 to 4

| | CIE | λmax | CE | EQE | LT97 | |
|---|---|---|---|---|---|---|
| Device ID | (x, y) | (nm) | (cd/m²) | (%) | (h) | Cₘₐₓ/nF |
| Example 2 | (0.333, | 528 | 94.4 | 24.32 | 335 | 2.25 |
| | 0.639) | | | | | |
| Comparative | (0.319, | 525 | 91.9 | 23.73 | 302 | 3.30 |
| Example 3 | 0.647) | | | | | |
| Comparative | (0.334, | 524 | 81.8 | 21.96 | 148 | 2.19 |
| Example 4 | 0.630) | | | | | |

### Discussion

With the comparison between Example 2 and Comparative Example 3, the emissive materials used in Example 2 and Comparative Example 3 had the same ligand Lₐ, but different ligands L_{b}. As can be seen from data in Table 4, the current efficiency (CE) in Example 2 was 2.7% higher than that in Comparative Example 3, the external quantum efficiency (EQE) in Example 2 was 2.5% higher than that in Comparative Example 3, and the lifetime (LT97) in Example 2 was 10.9% longer than that in Comparative Example 3. Moreover, the maximum capacitance in Example 2 was significantly reduced compared with that in Comparative Example 3, by 1.05 nF. Therefore, the metal complex provided by the present disclosure can provide the device with better performance.

With the comparison between Example 2 and Comparative Example 4, the emissive materials used in Example 2 and Comparative Example 4 had the same ligand L_{b}, but the difference between them is whether the ligand Lₐ had a specific substituent. As can be seen from data in Table 4, although the capacitance in Example 2 was substantially equivalent to that in Comparative Example 4, the current efficiency (CE) in Example 2 was 15.4% higher than that in Comparative Example 4, the external quantum efficiency (EQE) was 10.7% higher than that in Comparative Example 4, and the lifetime (LT97) was improved by 1.26 times. Therefore, the metal complex provided by the present disclosure can provide the device with better performance.

As can be seen from the preceding results, the metal complex provided by the present disclosure including specific ligands Lₐ and L_{b} can provide the devices with better performance and has an excellent effect on reducing the capacitor performance of the devices, thereby helping to improve the response rate of OLED display devices at low greyscales and increase the refresh frequency of the devices. The compound disclosed by the present disclosure has huge advantages and broad prospects in industrial applications.

It should be understood that various embodiments described herein are merely examples and not intended to limit the scope of the present disclosure. Therefore, it is apparent to the persons skilled in the art that the present disclosure as claimed may include variations from specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. A metal complex of claim 1, having a general structure of M(Lₐ)ₘ(L_{b})ₙ which is represented by Formula 1: 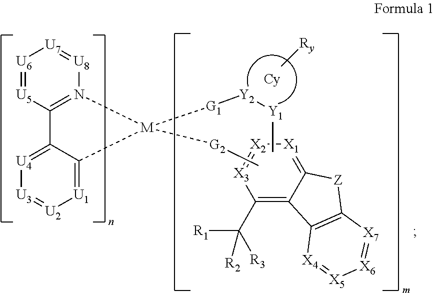
wherein
the metal M is selected from a metal with a relative atomic mass greater than 40;
m is selected from 1 or 2, n is selected from 1 or 2, and m+n equals an oxidation state of the metal M; when m is 2, two Lₐ are the same or different; when n is 2, two L_{b} are the same or different;
G₁ and G₂ are, at each occurrence identically or differently, selected from a single bond, O or S;
Cy is, at each occurrence identically or differently, selected from an aromatic ring comprising Y₁ and Y₂ and having 6 to 24 ring atoms, a heteroaromatic ring comprising Y₁ and Y₂ and having 5 to 24 ring atoms, or a combination thereof,
X₁ to X₇ are, at each occurrence identically or differently, selected from C, CRₓ or N; one of X₁ to X₃ is selected from C and joined to Y₁;
when X₁, X₂ or X₃ is selected from N, G₂ is selected from a single bond, and X₁, X₂ or X₃ is joined to the metal through a metal-nitrogen bond; or when X₁, X₂ or X₃ is selected from C, G₂ is selected from a single bond, O or S, and X₁, X₂ or X₃ is joined to the metal through G₂;
Y₁ and Y₂ are, at each occurrence identically or differently, selected from C or N; when Y₂ is selected from N, G₁ is selected from a single bond, and Y₂ is directly joined to the metal M; or when Y₂ is selected from C, G₁ is selected from a single bond, O or S, Y₂ is joined to the metal through G₁;
Z is selected from the group consisting of O, S, Se, NR′, CR′R′, SiR′R′, and GeR′R′; when two R′ are present at the same time, the two R′ are the same or different;
R_{y} represents mono-substitution, multiple substitutions or non-substitution; when a plurality of R_{y} are present, the plurality of R_{y} are the same or different;
U₁ to U₈ are, at each occurrence identically or differently, selected from CR, CRᵤ or N, and at least three of U₁ to U₈ are selected from CRᵤ;
R₁ to R₃ are, at each occurrence identically or differently, selected from the group consisting of: hydrogen, deuterium, halogen, a cyano group, an isocyano group, substituted or unsubstituted alkyl having 1 to 20 carbon atoms, substituted or unsubstituted cycloalkyl having 3 to 20 ring carbon atoms, and combinations thereof,
at least one of R₁ to R₃ is selected from hydrogen or deuterium;
R, Rₓ, R_{y}, and R′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Rᵤ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
at least one of X₁ to X₇ is CRₓ, and Rₓ is a cyano group or fluorine;
adjacent substituents R_{y} can be optionally joined to form a ring;
adjacent substituents R₁ to R₃ can be optionally joined to form a ring;
adjacent substituents R′ and Rₓ can be optionally joined to form a ring;
adjacent substituents Rᵤ and R can be optionally joined to form a ring.

2. The metal complex of claim 1, wherein G₁ and G₂ are, at each occurrence identically or differently, selected from a single bond or O; preferably, G₁ and G₂ are single bonds.

3. The metal complex of claim 1, wherein Cy is, at each occurrence identically or differently, selected from any one of the following structures: 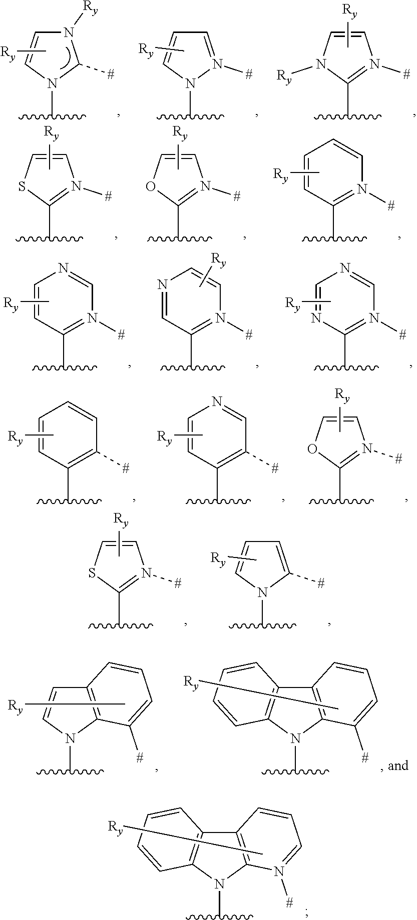
wherein,
R_{y} represents, at each occurrence identically or differently, mono-substitution, multiple substitutions or non-substitution; when a plurality of R_{y} are present in any structure, the plurality of R_{y} are the same or different;
R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
adjacent substituents R_{y} can be optionally joined to form a ring;
“#” represents the position of attachment to G₁ or the metal M, 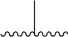
and represents the position of attachment to X₁, X₂ or X₃.

4. The metal complex of claim 1, wherein the metal M is, at each occurrence identically or differently, selected from the group consisting of Cu, Ag, Au, Ru, Rh, Pd, Os, Ir, and Pt;
preferably, the metal M is, at each occurrence identically or differently, selected from Pt or Ir.

5. The metal complex of claim 1, wherein the metal complex has a general formula structure of Ir(Lₐ)ₘ(L_{b})₃₋ₘ which is represented by Formula 2: 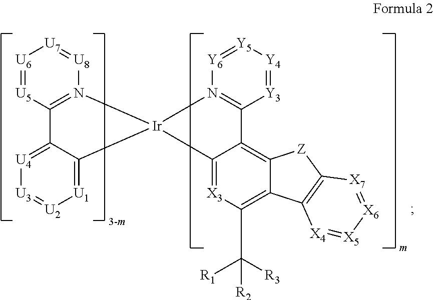
wherein,
m is selected from 1 or 2; when m is selected from 1, two L_{b} are the same or different; when m is selected from 2, two Lₐ are the same or different;
Z is selected from the group consisting of O, S, and Se;
X₃ to X₇ are, at each occurrence identically or differently, selected from CRₓ or N;
Y₃ to Y₆ are, at each occurrence identically or differently, selected from CR_{y} or N;
U₁ to U₈ are, at each occurrence identically or differently, selected from CR, CRᵤ or N, and at least three of U₁ to U₈ are selected CRᵤ;
R₁ to R₃ are, at each occurrence identically or differently, selected from the group consisting of: hydrogen, deuterium, halogen, a cyano group, an isocyano group, substituted or unsubstituted alkyl having 1 to 20 carbon atoms, substituted or unsubstituted cycloalkyl having 3 to 20 ring carbon atoms, and combinations thereof;
at least one of R₁ to R₃ is selected from hydrogen or deuterium;
R, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Rᵤ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
at least one of X₃ to X₇ is CRₓ, and Rₓ is a cyano group or fluorine;
adjacent substituents R_{y} can be optionally joined to form a ring;
adjacent substituents R₁ to R₃ can be optionally joined to form a ring;
adjacent substituents Rₓ can be optionally joined to form a ring;
adjacent substituents Rᵤ and R can be optionally joined to form a ring.

6. The metal complex of claim 1, wherein Rᵤ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted alkylsilyl having 3 to 20 carbon atoms, substituted or unsubstituted alkylgermanyl having 3 to 20 carbon atoms, and combinations thereof,
preferably, Rᵤ is, at each occurrence identically or differently, selected from the group consisting of: substituted or unsubstituted alkyl having 1 to 20 carbon atoms, substituted or unsubstituted cycloalkyl having 3 to 20 ring carbon atoms, and combinations thereof,
more preferably, Rᵤ is, at each occurrence identically or differently, selected from the group consisting of: substituted or unsubstituted alkyl having 1 to 6 carbon atoms, substituted or unsubstituted cycloalkyl having 3 to 6 ring carbon atoms, and combinations thereof.

7. The metal complex of claim 1, wherein at least one of Rᵤ is selected from substituted or unsubstituted alkyl having 3 to 20 carbon atoms, substituted or unsubstituted cycloalkyl having 3 to 20 ring carbon atoms, or a combination thereof,
preferably, at least one of Rᵤ is selected from the group consisting of the following groups: isopropyl, deuterated isopropyl, isobutyl, deuterated isobutyl, tert-butyl, neopentyl, deuterated neopentyl, cyclopentyl, deuterated cyclopentyl, cyclohexyl, deuterated cyclohexyl, and combinations thereof.

8. The metal complex of claim 1, wherein at least two of U₁ to U₄ are selected from CRᵤ, and at least one of U₅ to U₈ is selected from CRᵤ; or at least one of U₁ to U₄ is selected from CRᵤ, and at least two of U₅ to U₈ are selected from CRᵤ;
preferably, at least three of U₂, U₃, U₆, and U₇ are selected from CRᵤ.

9. The metal complex of claim 1, wherein R₁ to R₃ are, at each occurrence identically or differently, selected from hydrogen, deuterium or fluorine.

10. The metal complex of claim 1, wherein R and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, a cyano group, and combinations thereof,
preferably, R and Rₓ are, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, a cyano group, and combinations thereof.

11. The metal complex of claim 1, wherein at least two of X₄ to X₇ are selected from CRₓ, one of Rₓ is a cyano group or fluorine, and at least one of the other Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, a cyano group, and combinations thereof,
preferably, at least two of X₄ to X₇ are selected from CRₓ, one of Rₓ is a cyano group or fluorine, and at least one of the other Rₓ is, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, a cyano group, and combinations thereof.

12. The metal complex of claim 5, wherein R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, a cyano group, and combinations thereof,
preferably, R_{y} is, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, a cyano group, and combinations thereof.

13. The metal complex of claim 5, wherein Y₃ to Y₆ are, at each occurrence identically or differently, CR_{y} or N, at least one of Y₃ to Y₆ is selected from CR_{y}, and the R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof,
preferably, Y₃ to Y₆ are, at each occurrence identically or differently, CR_{y} or N, at least one of Y₃ to Y₆ is selected from CR_{y}, and the R_{y} is selected from the group consisting of: deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, and combinations thereof.

14. The metal complex of claim 1, wherein Lₐ is, at each occurrence identically or differently, selected from the group consisting of: Lₐ₋₁₋₁ to Lₐ₋₁₋₈₂₃, Lₐ₋₂₋₁ to Lₐ₋₂₋₈₂₃, Lₐ₋₃₋₁ to Lₐ₋₃₋₈₂₃, Lₐ₋₄₋₁ to Lₐ₋₄₋₈₂₃, Lₐ₋₅₋₁ to Lₐ₋₅₋₈₂₃, and Lₐ₋₆₋₁ to Lₐ₋₆₋₈₂₃; wherein Lₐ₋₁₋₁ to Lₐ₋₁₋₈₂₃ have a structure represented by Formula Lₐ₋₁₋ₖ: 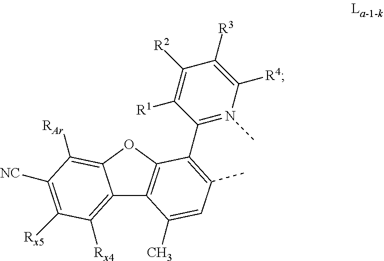
Lₐ₋₂₋₁ to Lₐ₋₂₋₈₂₃ have a structure represented by Formula Lₐ₋₂₋ₖ: 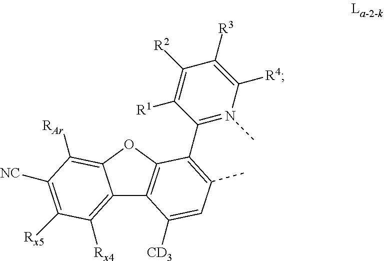
Lₐ₋₃₋₁ to Lₐ₋₃₋₈₂₃ have a structure represented by Formula Lₐ₋₃₋ₖ: 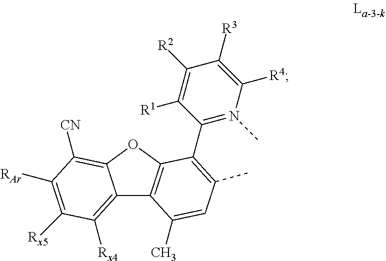
Lₐ₋₄₋₁ to Lₐ₋₄₋₈₂₃ have a structure represented by Formula Lₐ₋₄₋ₖ: 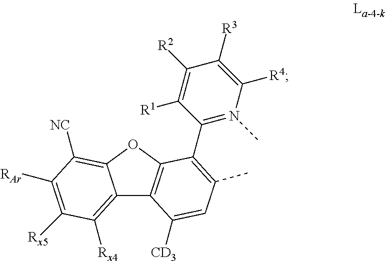
Lₐ₋₅₋₁ to Lₐ₋₅₋₈₂₃ have a structure represented by Formula Lₐ₋₅₋ₖ: 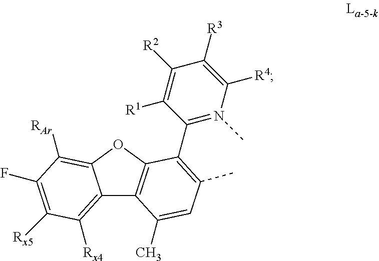
Lₐ₋₆₋₁ to Lₐ₋₆₋₈₂₃ have a structure represented by Formula Lₐ₋₆₋ₖ: 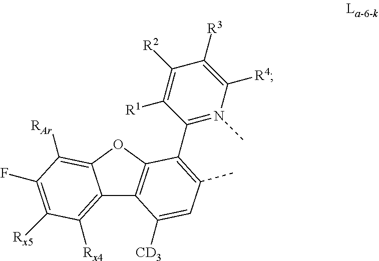
wherein k, Rₓ₄, Rₓ₅, R_{Ar}, and R¹ to R⁴ are specifically as follows:

| k | Rx₄ | Rx₅ | R_{Ar} | R¹ | R² | R³ | R⁴ |
|---|---|---|---|---|---|---|---|
| 1 | H | H | H | H | H | H | H |
| 2 | H | H | H | H | P1 | H | H |
| 3 | H | H | H | H | P2 | H | H |
| 4 | H | H | H | H | P3 | H | H |
| 5 | H | H | H | H | P4 | H | H |
| 6 | H | H | H | H | P5 | H | H |
| 7 | H | H | H | H | P6 | H | H |
| 8 | H | H | H | H | P7 | H | H |
| 9 | H | H | H | H | P8 | H | H |
| 10 | H | H | H | H | P9 | H | H |
| 11 | H | H | H | H | P10 | H | H |
| 12 | H | H | H | H | P11 | H | H |
| 13 | H | H | H | H | P12 | H | H |
| 14 | H | H | H | H | P13 | H | H |
| 15 | H | H | H | H | P14 | H | H |
| 16 | H | H | H | H | P15 | H | H |
| 17 | H | H | H | H | P16 | H | H |
| 18 | H | H | H | H | P17 | H | H |
| 19 | H | H | H | H | P18 | H | H |
| 20 | H | H | H | H | P19 | H | H |
| 21 | H | H | H | H | P20 | H | H |
| 22 | H | H | H | H | P21 | H | H |
| 23 | H | H | H | H | P1 | F | H |
| 24 | H | H | H | H | P2 | F | H |
| 25 | H | H | H | H | P3 | F | H |
| 26 | H | H | H | H | P4 | F | H |
| 27 | H | H | H | H | P5 | F | H |
| 28 | H | H | H | H | P6 | F | H |
| 29 | H | H | H | H | P7 | F | H |
| 30 | H | H | H | H | P8 | F | H |
| 31 | H | H | H | H | P9 | F | H |
| 32 | H | H | H | H | P10 | F | H |
| 33 | H | H | H | H | P11 | F | H |
| 34 | H | H | H | H | P12 | F | H |
| 35 | H | H | H | H | P13 | F | H |
| 36 | H | H | H | H | P14 | F | H |
| 37 | H | H | H | H | P15 | F | H |
| 38 | H | H | H | H | P16 | F | H |
| 39 | H | H | H | H | P17 | F | H |
| 40 | H | H | H | H | P18 | F | H |
| 41 | H | H | H | H | P19 | F | H |
| 42 | H | H | H | H | P20 | F | H |
| 43 | H | H | H | H | P21 | F | H |
| 44 | H | H | H | H | H | P1 | H |
| 45 | H | H | H | H | H | P2 | H |
| 46 | H | H | H | H | H | P3 | H |
| 47 | H | H | H | H | H | P4 | H |
| 48 | H | H | H | H | H | P5 | H |
| 49 | H | H | H | H | H | P6 | H |
| 50 | H | H | H | H | H | P7 | H |
| 51 | H | H | H | H | H | P8 | H |
| 52 | H | H | H | H | H | P9 | H |
| 53 | H | H | H | H | H | P10 | H |
| 54 | H | H | H | H | H | P11 | H |
| 55 | H | H | H | H | H | P12 | H |
| 56 | H | H | H | H | H | P13 | H |
| 57 | H | H | H | H | H | P14 | H |
| 58 | H | H | H | H | H | P15 | H |
| 59 | H | H | H | H | H | P16 | H |
| 60 | H | H | H | H | H | P17 | H |
| 61 | H | H | H | H | H | P18 | H |
| 62 | H | H | H | H | H | P19 | H |
| 63 | H | H | H | H | H | P20 | H |
| 64 | H | H | H | H | H | P21 | H |
| 65 | H | H | H | H | F | P1 | H |
| 66 | H | H | H | H | F | P2 | H |
| 67 | H | H | H | H | F | P3 | H |
| 68 | H | H | H | H | F | P4 | H |
| 69 | H | H | H | H | F | P5 | H |
| 70 | H | H | H | H | F | P6 | H |
| 71 | H | H | H | H | F | P7 | H |
| 72 | H | H | H | H | F | P8 | H |
| 73 | H | H | H | H | F | P9 | H |
| 74 | H | H | H | H | F | P10 | H |
| 75 | H | H | H | H | F | P11 | H |
| 76 | H | H | H | H | F | P12 | H |
| 77 | H | H | H | H | F | P13 | H |
| 78 | H | H | H | H | F | P14 | H |
| 79 | H | H | H | H | F | P15 | H |
| 80 | H | H | H | H | F | P16 | H |
| 81 | H | H | H | H | F | P17 | H |
| 82 | H | H | H | H | F | P18 | H |
| 83 | H | H | H | H | F | P19 | H |
| 84 | H | H | H | H | F | P20 | H |
| 85 | H | H | H | H | F | P21 | H |
| 86 | H | H | H | H | P1 | P1 | H |
| 87 | H | H | H | H | P1 | P3 | H |
| 88 | H | H | H | H | P1 | P8 | H |
| 89 | H | H | H | H | P1 | P10 | H |
| 90 | H | H | H | H | P1 | P20 | H |
| 91 | H | H | H | H | P1 | P21 | H |
| 92 | H | H | H | H | P2 | P2 | H |
| 93 | H | H | H | H | P2 | P4 | H |
| 94 | H | H | H | H | P2 | P5 | H |
| 95 | H | H | H | H | P2 | P9 | H |
| 96 | H | H | H | H | P2 | P11 | H |
| 97 | H | H | H | H | P2 | P20 | H |
| 98 | H | H | H | H | P2 | P21 | H |
| 99 | H | H | H | D | D | D | D |
| 100 | H | H | H | D | F | D | D |
| 101 | H | H | H | D | D | F | D |
| 102 | H | H | H | D | P2 | D | D |
| 103 | H | H | H | D | D | P2 | D |
| 104 | H | H | H | D | P2 | P2 | D |
| 105 | H | H | D | H | H | H | H |
| 106 | H | H | D | H | P6 | H | H |
| 107 | H | H | D | H | P2 | H | H |
| 108 | H | H | D | H | P5 | H | H |
| 109 | H | H | D | H | P10 | H | H |
| 110 | H | H | D | H | P11 | H | H |
| 111 | H | H | D | H | H | P6 | H |
| 112 | H | H | D | H | H | P2 | H |
| 113 | H | H | D | H | H | P4 | H |
| 114 | H | H | D | H | H | P5 | H |
| 115 | H | H | D | H | H | P10 | H |
| 116 | H | H | D | H | H | P11 | H |
| 117 | H | H | D | H | P1 | F | H |
| 118 | H | H | D | H | P2 | F | H |
| 119 | H | H | D | H | P11 | F | H |
| 120 | H | H | D | H | F | P1 | H |
| 121 | H | H | D | H | F | P2 | H |
| 122 | H | H | D | H | F | P3 | H |
| 123 | H | H | D | H | F | P4 | H |
| 124 | H | H | D | H | F | P5 | H |
| 125 | H | H | D | H | F | P8 | H |
| 126 | H | H | D | H | F | P11 | H |
| 127 | H | H | D | H | P1 | P1 | H |
| 128 | H | H | D | H | P2 | P2 | H |
| 129 | H | H | D | H | P2 | P2 | D |
| 130 | H | H | P20 | H | H | H | H |
| 131 | H | H | P20 | H | P1 | H | H |
| 132 | H | H | P20 | H | P2 | H | H |
| 133 | H | H | P20 | H | P3 | H | H |
| 134 | H | H | P20 | H | P4 | H | H |
| 135 | H | H | P20 | H | P5 | H | H |
| 136 | H | H | P20 | H | P6 | H | H |
| 137 | H | H | P20 | H | P7 | H | H |
| 138 | H | H | P20 | H | P8 | H | H |
| 139 | H | H | P20 | H | P9 | H | H |
| 140 | H | H | P20 | H | P10 | H | H |
| 141 | H | H | P20 | H | P11 | H | H |
| 142 | H | H | P20 | H | P12 | H | H |
| 143 | H | H | P20 | H | P13 | H | H |
| 144 | H | H | P20 | H | P14 | H | H |
| 145 | H | H | P20 | H | P15 | H | H |
| 146 | H | H | P20 | H | P16 | H | H |
| 147 | H | H | P20 | H | P17 | H | H |
| 148 | H | H | P20 | H | P18 | H | H |
| 149 | H | H | P20 | H | P19 | H | H |
| 150 | H | H | P20 | H | P20 | H | H |
| 151 | H | H | P20 | H | P21 | H | H |
| 152 | H | H | P20 | H | H | P1 | H |
| 153 | H | H | P20 | H | H | P2 | H |
| 154 | H | H | P20 | H | H | P3 | H |
| 155 | H | H | P20 | H | H | P4 | H |
| 156 | H | H | P20 | H | H | P5 | H |
| 157 | H | H | P20 | H | H | P6 | H |
| 158 | H | H | P20 | H | H | P7 | H |
| 159 | H | H | P20 | H | H | P8 | H |
| 160 | H | H | P20 | H | H | P9 | H |
| 161 | H | H | P20 | H | H | P10 | H |
| 162 | H | H | P20 | H | H | P11 | H |
| 163 | H | H | P20 | H | H | P12 | H |
| 164 | H | H | P20 | H | H | P15 | H |
| 165 | H | H | P20 | H | H | P17 | H |
| 166 | H | H | P20 | H | H | P18 | H |
| 167 | H | H | P20 | H | H | P19 | H |
| 168 | H | H | P20 | H | H | P20 | H |
| 169 | H | H | P20 | H | H | P21 | H |
| 170 | H | H | P20 | H | F | H | H |
| 171 | H | H | P20 | H | F | P1 | H |
| 172 | H | H | P20 | H | F | P2 | H |
| 173 | H | H | P20 | H | F | P3 | H |
| 174 | H | H | P20 | H | F | P4 | H |
| 175 | H | H | P20 | H | F | P5 | H |
| 176 | H | H | P20 | H | F | P6 | H |
| 177 | H | H | P20 | H | F | P7 | H |
| 178 | H | H | P20 | H | F | P8 | H |
| 179 | H | H | P20 | H | F | P9 | H |
| 180 | H | H | P20 | H | F | P10 | H |
| 181 | H | H | P20 | H | F | P11 | H |
| 182 | H | H | P20 | H | P1 | F | H |
| 183 | H | H | P20 | H | P2 | F | H |
| 184 | H | H | P20 | H | P3 | F | H |
| 185 | H | H | P20 | H | P4 | F | H |
| 186 | H | H | P20 | H | P5 | F | H |
| 187 | H | H | P20 | H | P6 | F | H |
| 188 | H | H | P20 | H | P7 | F | H |
| 189 | H | H | P20 | H | P8 | F | H |
| 190 | H | H | P20 | H | P9 | F | H |
| 191 | H | H | P20 | H | P10 | F | H |
| 192 | H | H | P20 | H | P11 | F | H |
| 193 | H | H | P20 | H | P1 | P1 | H |
| 194 | H | H | P20 | H | P2 | P2 | H |
| 195 | H | H | P20 | D | D | D | D |
| 196 | H | H | P20 | D | P2 | P2 | D |
| 197 | H | H | P20 | D | F | P4 | D |
| 198 | H | H | P20 | D | F | P5 | D |
| 199 | H | H | P20 | D | F | P9 | D |
| 200 | H | H | P20 | D | F | P11 | D |
| 201 | H | H | P21 | H | H | H | H |
| 202 | H | H | P21 | H | P1 | H | H |
| 203 | H | H | P21 | H | P2 | H | H |
| 204 | H | H | P21 | H | P3 | H | H |
| 205 | H | H | P21 | H | P4 | H | H |
| 206 | H | H | P21 | H | P5 | H | H |
| 207 | H | H | P21 | H | P6 | H | H |
| 208 | H | H | P21 | H | P7 | H | H |
| 209 | H | H | P21 | H | P8 | H | H |
| 210 | H | H | P21 | H | P9 | H | H |
| 211 | H | H | P21 | H | P10 | H | H |
| 212 | H | H | P21 | H | P11 | H | H |
| 213 | H | H | P21 | H | P12 | H | H |
| 214 | H | H | P21 | H | P13 | H | H |
| 215 | H | H | P21 | H | P14 | H | H |
| 216 | H | H | P21 | H | P15 | H | H |
| 217 | H | H | P21 | H | P16 | H | H |
| 218 | H | H | P21 | H | P17 | H | H |
| 219 | H | H | P21 | H | P18 | H | H |
| 220 | H | H | P21 | H | P19 | H | H |
| 221 | H | H | P21 | H | P20 | H | H |
| 222 | H | H | P21 | H | P21 | H | H |
| 223 | H | H | P21 | H | H | P1 | H |
| 224 | H | H | P21 | H | H | P2 | H |
| 225 | H | H | P21 | H | H | P3 | H |
| 226 | H | H | P21 | H | H | P4 | H |
| 227 | H | H | P21 | H | H | P5 | H |
| 228 | H | H | P21 | H | H | P6 | H |
| 229 | H | H | P21 | H | H | P7 | H |
| 230 | H | H | P21 | H | H | P8 | H |
| 231 | H | H | P21 | H | H | P9 | H |
| 232 | H | H | P21 | H | H | P10 | H |
| 233 | H | H | P21 | H | H | P11 | H |
| 234 | H | H | P21 | H | H | P12 | H |
| 235 | H | H | P21 | H | H | P15 | H |
| 236 | H | H | P21 | H | H | P17 | H |
| 237 | H | H | P21 | H | H | P18 | H |
| 238 | H | H | P21 | H | H | P19 | H |
| 239 | H | H | P21 | H | H | P20 | H |
| 240 | H | H | P21 | H | H | P21 | H |
| 241 | H | H | P21 | H | F | H | H |
| 242 | H | H | P21 | H | F | P1 | H |
| 243 | H | H | P21 | H | F | P2 | H |
| 244 | H | H | P21 | H | F | P3 | H |
| 245 | H | H | P21 | H | F | P4 | H |
| 246 | H | H | P21 | H | F | P5 | H |
| 247 | H | H | P21 | H | F | P6 | H |
| 248 | H | H | P21 | H | F | P7 | H |
| 249 | H | H | P21 | H | F | P8 | H |
| 250 | H | H | P21 | H | F | P9 | H |
| 251 | H | H | P21 | H | F | P10 | H |
| 252 | H | H | P21 | H | F | P11 | H |
| 253 | H | H | P21 | H | P1 | F | H |
| 254 | H | H | P21 | H | P2 | F | H |
| 255 | H | H | P21 | H | P3 | F | H |
| 256 | H | H | P21 | H | P4 | F | H |
| 257 | H | H | P21 | H | P5 | F | H |
| 258 | H | H | P21 | H | P6 | F | H |
| 259 | H | H | P21 | H | P7 | F | H |
| 260 | H | H | P21 | H | P8 | F | H |
| 261 | H | H | P21 | H | P9 | F | H |
| 262 | H | H | P21 | H | P10 | F | H |
| 263 | H | H | P21 | H | P11 | F | H |
| 264 | H | H | P21 | H | P1 | P1 | H |
| 265 | H | H | P21 | H | P2 | P2 | H |
| 266 | H | H | P21 | D | D | D | D |
| 267 | H | H | P21 | D | P2 | P2 | D |
| 268 | H | H | P21 | D | F | P4 | D |
| 269 | H | H | P21 | D | F | P5 | D |
| 270 | H | H | P21 | D | F | P9 | D |
| 271 | H | H | P21 | D | F | P11 | D |
| 272 | H | H | P54 | H | H | H | H |
| 273 | H | H | P54 | H | P1 | H | H |
| 274 | H | H | P54 | H | P2 | H | H |
| 275 | H | H | P54 | H | P3 | H | H |
| 276 | H | H | P54 | H | P4 | H | H |
| 277 | H | H | P54 | H | P5 | H | H |
| 278 | H | H | P54 | H | P6 | H | H |
| 279 | H | H | P54 | H | P7 | H | H |
| 280 | H | H | P54 | H | P8 | H | H |
| 281 | H | H | P54 | H | P9 | H | H |
| 282 | H | H | P54 | H | P10 | H | H |
| 283 | H | H | P54 | H | P11 | H | H |
| 284 | H | H | P54 | H | P12 | H | H |
| 285 | H | H | P54 | H | P13 | H | H |
| 286 | H | H | P54 | H | P14 | H | H |
| 287 | H | H | P54 | H | P15 | H | H |
| 288 | H | H | P54 | H | P16 | H | H |
| 289 | H | H | P54 | H | P17 | H | H |
| 290 | H | H | P54 | H | P18 | H | H |
| 291 | H | H | P54 | H | P19 | H | H |
| 292 | H | H | P54 | H | P20 | H | H |
| 293 | H | H | P54 | H | P21 | H | H |
| 294 | H | H | P54 | H | H | P1 | H |
| 295 | H | H | P54 | H | H | P2 | H |
| 296 | H | H | P54 | H | H | P3 | H |
| 297 | H | H | P54 | H | H | P4 | H |
| 298 | H | H | P54 | H | H | P5 | H |
| 299 | H | H | P54 | H | H | P6 | H |
| 300 | H | H | P54 | H | H | P7 | H |
| 301 | H | H | P54 | H | H | P8 | H |
| 302 | H | H | P54 | H | H | P9 | H |
| 303 | H | H | P54 | H | H | P10 | H |
| 304 | H | H | P54 | H | H | P11 | H |
| 305 | H | H | P54 | H | H | P12 | H |
| 306 | H | H | P54 | H | H | P15 | H |
| 307 | H | H | P54 | H | H | P17 | H |
| 308 | H | H | P54 | H | H | P18 | H |
| 309 | H | H | P54 | H | H | P19 | H |
| 310 | H | H | P54 | H | H | P20 | H |
| 311 | H | H | P54 | H | H | P21 | H |
| 312 | H | H | P54 | H | F | H | H |
| 313 | H | H | P54 | H | F | P1 | H |
| 314 | H | H | P54 | H | F | P2 | H |
| 315 | H | H | P54 | H | F | P3 | H |
| 316 | H | H | P54 | H | F | P4 | H |
| 317 | H | H | P54 | H | F | P5 | H |
| 318 | H | H | P54 | H | F | P6 | H |
| 319 | H | H | P54 | H | F | P7 | H |
| 320 | H | H | P54 | H | F | P8 | H |
| 321 | H | H | P54 | H | F | P9 | H |
| 322 | H | H | P54 | H | F | P10 | H |
| 323 | H | H | P54 | H | F | P11 | H |
| 324 | H | H | P54 | H | P1 | F | H |
| 325 | H | H | P54 | H | P2 | F | H |
| 326 | H | H | P54 | H | P3 | F | H |
| 327 | H | H | P54 | H | P4 | F | H |
| 328 | H | H | P54 | H | P5 | F | H |
| 329 | H | H | P54 | H | P6 | F | H |
| 330 | H | H | P54 | H | P7 | F | H |
| 331 | H | H | P54 | H | P8 | F | H |
| 332 | H | H | P54 | H | P9 | F | H |
| 333 | H | H | P54 | H | P10 | F | H |
| 334 | H | H | P54 | H | P11 | F | H |
| 335 | H | H | P54 | H | P1 | P1 | H |
| 336 | H | H | P54 | H | P2 | P2 | H |
| 337 | H | H | P54 | D | D | D | D |
| 338 | H | H | P54 | D | P2 | P2 | D |
| 339 | H | H | P54 | D | F | P4 | D |
| 340 | H | H | P54 | D | F | P5 | D |
| 341 | H | H | P54 | D | F | P9 | D |
| 342 | H | H | P54 | D | F | P11 | D |
| 343 | H | H | P96 | H | H | H | H |
| 344 | H | H | P96 | H | P1 | H | H |
| 345 | H | H | P96 | H | P2 | H | H |
| 346 | H | H | P96 | H | P3 | H | H |
| 347 | H | H | P96 | H | P4 | H | H |
| 348 | H | H | P96 | H | P5 | H | H |
| 349 | H | H | P96 | H | P6 | H | H |
| 350 | H | H | P96 | H | P7 | H | H |
| 351 | H | H | P96 | H | P8 | H | H |
| 352 | H | H | P96 | H | P9 | H | H |
| 353 | H | H | P96 | H | P10 | H | H |
| 354 | H | H | P96 | H | P11 | H | H |
| 355 | H | H | P96 | H | P12 | H | H |
| 356 | H | H | P96 | H | P13 | H | H |
| 357 | H | H | P96 | H | P14 | H | H |
| 358 | H | H | P96 | H | P15 | H | H |
| 359 | H | H | P96 | H | P16 | H | H |
| 360 | H | H | P96 | H | P17 | H | H |
| 361 | H | H | P96 | H | P18 | H | H |
| 362 | H | H | P96 | H | P19 | H | H |
| 363 | H | H | P96 | H | P20 | H | H |
| 364 | H | H | P96 | H | P21 | H | H |
| 365 | H | H | P96 | H | H | P1 | H |
| 366 | H | H | P96 | H | H | P2 | H |
| 367 | H | H | P96 | H | H | P3 | H |
| 368 | H | H | P96 | H | H | P4 | H |
| 369 | H | H | P96 | H | H | P5 | H |
| 370 | H | H | P96 | H | H | P6 | H |
| 371 | H | H | P96 | H | H | P7 | H |
| 372 | H | H | P96 | H | H | P8 | H |
| 373 | H | H | P96 | H | H | P9 | H |
| 374 | H | H | P96 | H | H | P10 | H |
| 375 | H | H | P96 | H | H | P11 | H |
| 376 | H | H | P96 | H | H | P12 | H |
| 377 | H | H | P96 | H | H | P15 | H |
| 378 | H | H | P96 | H | H | P17 | H |
| 379 | H | H | P96 | H | H | P18 | H |
| 380 | H | H | P96 | H | H | P19 | H |
| 381 | H | H | P96 | H | H | P20 | H |
| 382 | H | H | P96 | H | H | P21 | H |
| 383 | H | H | P96 | H | F | H | H |
| 384 | H | H | P96 | H | F | P1 | H |
| 385 | H | H | P96 | H | F | P2 | H |
| 386 | H | H | P96 | H | F | P3 | H |
| 387 | H | H | P96 | H | F | P4 | H |
| 388 | H | H | P96 | H | F | P5 | H |
| 389 | H | H | P96 | H | F | P6 | H |
| 390 | H | H | P96 | H | F | P7 | H |
| 391 | H | H | P96 | H | F | P8 | H |
| 392 | H | H | P96 | H | F | P9 | H |
| 393 | H | H | P96 | H | F | P10 | H |
| 394 | H | H | P96 | H | F | P11 | H |
| 395 | H | H | P96 | H | P1 | F | H |
| 396 | H | H | P96 | H | P2 | F | H |
| 397 | H | H | P96 | H | P3 | F | H |
| 398 | H | H | P96 | H | P4 | F | H |
| 399 | H | H | P96 | H | P5 | F | H |
| 400 | H | H | P96 | H | P6 | F | H |
| 401 | H | H | P96 | H | P7 | F | H |
| 402 | H | H | P96 | H | P8 | F | H |
| 403 | H | H | P96 | H | P9 | F | H |
| 404 | H | H | P96 | H | P10 | F | H |
| 405 | H | H | P96 | H | P11 | F | H |
| 406 | H | H | P96 | H | P1 | P1 | H |
| 407 | H | H | P96 | H | P2 | P2 | H |
| 408 | H | H | P96 | D | D | D | D |
| 409 | H | H | P96 | D | P2 | P2 | D |
| 410 | H | H | P96 | D | F | P4 | D |
| 411 | H | H | P96 | D | F | P5 | D |
| 412 | H | H | P96 | D | F | P9 | D |
| 413 | H | H | P96 | D | F | P11 | D |
| 414 | H | H | P97 | H | H | H | H |
| 415 | H | H | P97 | H | P1 | H | H |
| 416 | H | H | P97 | H | P2 | H | H |
| 417 | H | H | P97 | H | P3 | H | H |
| 418 | H | H | P97 | H | P4 | H | H |
| 419 | H | H | P97 | H | P5 | H | H |
| 420 | H | H | P97 | H | P6 | H | H |
| 421 | H | H | P97 | H | P7 | H | H |
| 422 | H | H | P97 | H | P8 | H | H |
| 423 | H | H | P97 | H | P9 | H | H |
| 424 | H | H | P97 | H | P10 | H | H |
| 425 | H | H | P97 | H | P11 | H | H |
| 426 | H | H | P97 | H | P12 | H | H |
| 427 | H | H | P97 | H | P13 | H | H |
| 428 | H | H | P97 | H | P14 | H | H |
| 429 | H | H | P97 | H | P15 | H | H |
| 430 | H | H | P97 | H | P16 | H | H |
| 431 | H | H | P97 | H | P17 | H | H |
| 432 | H | H | P97 | H | P18 | H | H |
| 433 | H | H | P97 | H | P19 | H | H |
| 434 | H | H | P97 | H | P20 | H | H |
| 435 | H | H | P97 | H | P21 | H | H |
| 436 | H | H | P97 | H | H | P1 | H |
| 437 | H | H | P97 | H | H | P2 | H |
| 438 | H | H | P97 | H | H | P3 | H |
| 439 | H | H | P97 | H | H | P4 | H |
| 440 | H | H | P97 | H | H | P5 | H |
| 441 | H | H | P97 | H | H | P6 | H |
| 442 | H | H | P97 | H | H | P7 | H |
| 443 | H | H | P97 | H | H | P8 | H |
| 444 | H | H | P97 | H | H | P9 | H |
| 445 | H | H | P97 | H | H | P10 | H |
| 446 | H | H | P97 | H | H | P11 | H |
| 447 | H | H | P97 | H | H | P12 | H |
| 448 | H | H | P97 | H | H | P15 | H |
| 449 | H | H | P97 | H | H | P17 | H |
| 450 | H | H | P97 | H | H | P18 | H |
| 451 | H | H | P97 | H | H | P19 | H |
| 452 | H | H | P97 | H | H | P20 | H |
| 453 | H | H | P97 | H | H | P21 | H |
| 454 | H | H | P97 | H | F | H | H |
| 455 | H | H | P97 | H | F | P1 | H |
| 456 | H | H | P97 | H | F | P2 | H |
| 457 | H | H | P97 | H | F | P3 | H |
| 458 | H | H | P97 | H | F | P4 | H |
| 459 | H | H | P97 | H | F | P5 | H |
| 460 | H | H | P97 | H | F | P6 | H |
| 461 | H | H | P97 | H | F | P7 | H |
| 462 | H | H | P97 | H | F | P8 | H |
| 463 | H | H | P97 | H | F | P9 | H |
| 464 | H | H | P97 | H | F | P10 | H |
| 465 | H | H | P97 | H | F | P11 | H |
| 466 | H | H | P97 | H | P1 | F | H |
| 467 | H | H | P97 | H | P2 | F | H |
| 468 | H | H | P97 | H | P3 | F | H |
| 469 | H | H | P97 | H | P4 | F | H |
| 470 | H | H | P97 | H | P5 | F | H |
| 471 | H | H | P97 | H | P6 | F | H |
| 472 | H | H | P97 | H | P7 | F | H |
| 473 | H | H | P97 | H | P8 | F | H |
| 474 | H | H | P97 | H | P9 | F | H |
| 475 | H | H | P97 | H | P10 | F | H |
| 476 | H | H | P97 | H | P11 | F | H |
| 477 | H | H | P97 | H | P1 | P1 | H |
| 478 | H | H | P97 | H | P2 | P2 | H |
| 479 | H | H | P97 | D | D | D | D |
| 480 | H | H | P97 | D | P2 | P2 | D |
| 481 | H | H | P97 | D | F | P4 | D |
| 482 | H | H | P97 | D | F | P5 | D |
| 483 | H | H | P97 | D | F | P9 | D |
| 484 | H | H | P97 | D | F | P11 | D |
| 485 | H | H | P102 | H | P1 | H | H |
| 486 | H | H | P102 | H | P2 | H | H |
| 487 | H | H | P102 | H | P3 | H | H |
| 488 | H | H | P102 | H | P4 | H | H |
| 489 | H | H | P102 | H | P5 | H | H |
| 490 | H | H | P102 | H | P6 | H | H |
| 491 | H | H | P102 | H | P7 | H | H |
| 492 | H | H | P102 | H | P8 | H | H |
| 493 | H | H | P102 | H | P9 | H | H |
| 494 | H | H | P102 | H | P10 | H | H |
| 495 | H | H | P102 | H | P11 | H | H |
| 496 | H | H | P102 | H | P12 | H | H |
| 497 | H | H | P102 | H | P13 | H | H |
| 498 | H | H | P102 | H | P14 | H | H |
| 499 | H | H | P102 | H | P15 | H | H |
| 500 | H | H | P102 | H | P16 | H | H |
| 501 | H | H | P102 | H | P17 | H | H |
| 502 | H | H | P102 | H | P18 | H | H |
| 503 | H | H | P102 | H | P19 | H | H |
| 504 | H | H | P102 | H | P20 | H | H |
| 505 | H | H | P102 | H | P21 | H | H |
| 506 | H | H | P102 | H | H | P1 | H |
| 507 | H | H | P102 | H | H | P2 | H |
| 508 | H | H | P102 | H | H | P3 | H |
| 509 | H | H | P102 | H | H | P4 | H |
| 510 | H | H | P102 | H | H | P5 | H |
| 511 | H | H | P102 | H | H | P6 | H |
| 512 | H | H | P102 | H | H | P7 | H |
| 513 | H | H | P102 | H | H | P8 | H |
| 514 | H | H | P102 | H | H | P9 | H |
| 515 | H | H | P102 | H | H | P10 | H |
| 516 | H | H | P102 | H | H | P11 | H |
| 517 | H | H | P102 | H | H | P12 | H |
| 518 | H | H | P102 | H | H | P15 | H |
| 519 | H | H | P102 | H | H | P17 | H |
| 520 | H | H | P102 | H | H | P18 | H |
| 521 | H | H | P102 | H | H | P19 | H |
| 522 | H | H | P102 | H | H | P20 | H |
| 523 | H | H | P102 | H | H | P21 | H |
| 524 | H | H | P102 | H | F | H | H |
| 525 | H | H | P102 | H | F | P1 | H |
| 526 | H | H | P102 | H | F | P2 | H |
| 527 | H | H | P102 | H | F | P3 | H |
| 528 | H | H | P102 | H | F | P4 | H |
| 529 | H | H | P102 | H | F | P5 | H |
| 530 | H | H | P102 | H | F | P6 | H |
| 531 | H | H | P102 | H | F | P7 | H |
| 532 | H | H | P102 | H | F | P8 | H |
| 533 | H | H | P102 | H | F | P9 | H |
| 534 | H | H | P102 | H | F | P10 | H |
| 535 | H | H | P102 | H | F | P11 | H |
| 536 | H | H | P102 | H | P1 | F | H |
| 537 | H | H | P102 | H | P2 | F | H |
| 538 | H | H | P102 | H | P3 | F | H |
| 539 | H | H | P102 | H | P4 | F | H |
| 540 | H | H | P102 | H | P5 | F | H |
| 541 | H | H | P102 | H | P6 | F | H |
| 542 | H | H | P102 | H | P7 | F | H |
| 543 | H | H | P102 | H | P8 | F | H |
| 544 | H | H | P102 | H | P9 | F | H |
| 545 | H | H | P102 | H | P10 | F | H |
| 546 | H | H | P102 | H | P11 | F | H |
| 547 | H | H | P102 | H | P1 | P1 | H |
| 548 | H | H | P102 | H | P2 | P2 | H |
| 549 | H | H | P102 | D | D | D | D |
| 550 | H | H | P102 | D | P2 | P2 | D |
| 551 | H | H | P102 | D | F | P4 | D |
| 552 | H | H | P102 | D | F | P5 | D |
| 553 | H | H | P102 | D | F | P9 | D |
| 554 | H | H | P102 | D | F | P11 | D |
| 555 | H | H | P103 | H | P1 | H | H |
| 556 | H | H | P103 | H | P2 | H | H |
| 557 | H | H | P103 | H | P3 | H | H |
| 558 | H | H | P103 | H | P4 | H | H |
| 559 | H | H | P103 | H | P5 | H | H |
| 560 | H | H | P103 | H | P6 | H | H |
| 561 | H | H | P103 | H | P7 | H | H |
| 562 | H | H | P103 | H | P8 | H | H |
| 563 | H | H | P103 | H | P9 | H | H |
| 564 | H | H | P103 | H | P10 | H | H |
| 565 | H | H | P103 | H | P11 | H | H |
| 566 | H | H | P103 | H | P12 | H | H |
| 567 | H | H | P103 | H | P13 | H | H |
| 568 | H | H | P103 | H | P14 | H | H |
| 569 | H | H | P103 | H | P15 | H | H |
| 570 | H | H | P103 | H | P16 | H | H |
| 571 | H | H | P103 | H | P17 | H | H |
| 572 | H | H | P103 | H | P18 | H | H |
| 573 | H | H | P103 | H | P19 | H | H |
| 574 | H | H | P103 | H | P20 | H | H |
| 575 | H | H | P103 | H | P21 | H | H |
| 576 | H | H | P103 | H | H | P1 | H |
| 577 | H | H | P103 | H | H | P2 | H |
| 578 | H | H | P103 | H | H | P3 | H |
| 579 | H | H | P103 | H | H | P4 | H |
| 580 | H | H | P103 | H | H | P5 | H |
| 581 | H | H | P103 | H | H | P6 | H |
| 582 | H | H | P103 | H | H | P7 | H |
| 583 | H | H | P103 | H | H | P8 | H |
| 584 | H | H | P103 | H | H | P9 | H |
| 585 | H | H | P103 | H | H | P10 | H |
| 586 | H | H | P103 | H | H | P11 | H |
| 587 | H | H | P103 | H | H | P12 | H |
| 588 | H | H | P103 | H | H | P15 | H |
| 589 | H | H | P103 | H | H | P17 | H |
| 590 | H | H | P103 | H | H | P18 | H |
| 591 | H | H | P103 | H | H | P19 | H |
| 592 | H | H | P103 | H | H | P20 | H |
| 593 | H | H | P103 | H | H | P21 | H |
| 594 | H | H | P103 | H | F | H | H |
| 595 | H | H | P103 | H | F | P1 | H |
| 596 | H | H | P103 | H | F | P2 | H |
| 597 | H | H | P103 | H | F | P3 | H |
| 598 | H | H | P103 | H | F | P4 | H |
| 599 | H | H | P103 | H | F | P5 | H |
| 600 | H | H | P103 | H | F | P6 | H |
| 601 | H | H | P103 | H | F | P7 | H |
| 602 | H | H | P103 | H | F | P8 | H |
| 603 | H | H | P103 | H | F | P9 | H |
| 604 | H | H | P103 | H | F | P10 | H |
| 605 | H | H | P103 | H | F | P11 | H |
| 606 | H | H | P103 | H | P1 | F | H |
| 607 | H | H | P103 | H | P2 | F | H |
| 608 | H | H | P103 | H | P3 | F | H |
| 609 | H | H | P103 | H | P4 | F | H |
| 610 | H | H | P103 | H | P5 | F | H |
| 611 | H | H | P103 | H | P6 | F | H |
| 612 | H | H | P103 | H | P7 | F | H |
| 613 | H | H | P103 | H | P8 | F | H |
| 614 | H | H | P103 | H | P9 | F | H |
| 615 | H | H | P103 | H | P10 | F | H |
| 616 | H | H | P103 | H | P11 | F | H |
| 617 | H | H | P103 | H | P1 | P1 | H |
| 618 | H | H | P103 | H | P2 | P2 | H |
| 619 | H | H | P103 | D | D | D | D |
| 620 | H | H | P103 | D | P2 | P2 | D |
| 621 | H | H | P103 | D | F | P4 | D |
| 622 | H | H | P103 | D | F | P5 | D |
| 623 | H | H | P103 | D | F | P9 | D |
| 624 | H | H | P103 | D | F | P11 | D |
| 625 | H | H | H | H | P20 | P1 | H |
| 626 | H | H | H | H | P21 | P2 | H |
| 627 | H | H | H | H | P29 | H | H |
| 628 | H | H | H | H | P29 | P1 | H |
| 629 | H | H | H | H | P54 | H | H |
| 630 | H | H | H | H | P96 | H | H |
| 631 | H | H | H | H | P97 | H | H |
| 632 | H | H | H | H | P96 | P1 | H |
| 633 | H | H | H | H | P97 | P1 | H |
| 634 | H | H | H | H | P102 | H | H |
| 635 | H | H | H | H | P103 | H | H |
| 636 | H | H | D | H | P20 | P1 | H |
| 637 | H | H | D | H | P21 | P2 | H |
| 638 | H | H | D | H | P29 | H | H |
| 639 | H | H | D | H | P29 | P1 | H |
| 640 | H | H | D | H | P54 | H | H |
| 641 | H | H | D | H | P96 | H | H |
| 642 | H | H | D | H | P97 | H | H |
| 643 | H | H | D | H | P96 | P1 | H |
| 644 | H | H | D | H | P97 | P1 | H |
| 645 | H | H | D | H | P102 | H | H |
| 646 | H | H | D | H | P103 | H | H |
| 647 | H | H | P20 | H | P20 | P1 | H |
| 648 | H | H | P20 | H | P21 | P2 | H |
| 649 | H | H | P20 | H | P29 | H | H |
| 650 | H | H | P20 | H | P29 | P1 | H |
| 651 | H | H | P20 | H | P54 | H | H |
| 652 | H | H | P20 | H | P96 | H | H |
| 653 | H | H | P20 | H | P97 | H | H |
| 654 | H | H | P20 | H | P96 | P1 | H |
| 655 | H | H | P20 | H | P97 | P1 | H |
| 656 | H | H | P20 | H | P102 | H | H |
| 657 | H | H | P20 | H | P103 | H | H |
| 658 | H | H | P21 | H | P20 | P1 | H |
| 659 | H | H | P21 | H | P21 | P2 | H |
| 660 | H | H | P21 | H | P29 | H | H |
| 661 | H | H | P21 | H | P29 | P1 | H |
| 662 | H | H | P21 | H | P54 | H | H |
| 663 | H | H | P21 | H | P96 | H | H |
| 664 | H | H | P21 | H | P97 | H | H |
| 665 | H | H | P21 | H | P96 | P1 | H |
| 666 | H | H | P21 | H | P97 | P1 | H |
| 667 | H | H | P21 | H | P102 | H | H |
| 668 | H | H | P21 | H | P103 | H | H |
| 669 | H | H | P22 | H | H | H | H |
| 670 | H | H | P23 | H | H | H | H |
| 671 | H | H | P24 | H | H | H | H |
| 672 | H | H | P25 | H | H | H | H |
| 673 | H | H | P26 | H | H | H | H |
| 674 | H | H | P27 | H | H | H | H |
| 675 | H | H | P28 | H | H | H | H |
| 676 | H | H | P29 | H | H | H | H |
| 677 | H | H | P30 | H | H | H | H |
| 678 | H | H | P31 | H | H | H | H |
| 679 | H | H | P32 | H | H | H | H |
| 680 | H | H | P33 | H | H | H | H |
| 681 | H | H | P34 | H | H | H | H |
| 682 | H | H | P35 | H | H | H | H |
| 683 | H | H | P36 | H | H | H | H |
| 684 | H | H | P37 | H | H | H | H |
| 685 | H | H | P38 | H | H | H | H |
| 686 | H | H | P39 | H | H | H | H |
| 687 | H | H | P40 | H | H | H | H |
| 688 | H | H | P41 | H | H | H | H |
| 689 | H | H | P42 | H | H | H | H |
| 690 | H | H | P43 | H | H | H | H |
| 691 | H | H | P44 | H | H | H | H |
| 692 | H | H | P45 | H | H | H | H |
| 693 | H | H | P46 | H | H | H | H |
| 694 | H | H | P47 | H | H | H | H |
| 695 | H | H | P48 | H | H | H | H |
| 696 | H | H | P49 | H | H | H | H |
| 697 | H | H | P50 | H | H | H | H |
| 698 | H | H | P51 | H | H | H | H |
| 699 | H | H | P52 | H | H | H | H |
| 700 | H | H | P53 | H | H | H | H |
| 701 | H | H | P55 | H | H | H | H |
| 702 | H | H | P56 | H | H | H | H |
| 703 | H | H | P57 | H | H | H | H |
| 704 | H | H | P58 | H | H | H | H |
| 705 | H | H | P59 | H | H | H | H |
| 706 | H | H | P60 | H | H | H | H |
| 707 | H | H | P61 | H | H | H | H |
| 708 | H | H | P62 | H | H | H | H |
| 709 | H | H | P63 | H | H | H | H |
| 710 | H | H | P64 | H | H | H | H |
| 711 | H | H | P65 | H | H | H | H |
| 712 | H | H | P66 | H | H | H | H |
| 713 | H | H | P67 | H | H | H | H |
| 714 | H | H | P68 | H | H | H | H |
| 715 | H | H | P69 | H | H | H | H |
| 716 | H | H | P70 | H | H | H | H |
| 717 | H | H | P71 | H | H | H | H |
| 718 | H | H | P72 | H | H | H | H |
| 719 | H | H | P73 | H | H | H | H |
| 720 | H | H | P74 | H | H | H | H |
| 721 | H | H | P75 | H | H | H | H |
| 722 | H | H | P76 | H | H | H | H |
| 723 | H | H | P77 | H | H | H | H |
| 724 | H | H | P78 | H | H | H | H |
| 725 | H | H | P79 | H | H | H | H |
| 726 | H | H | P80 | H | H | H | H |
| 727 | H | H | P81 | H | H | H | H |
| 728 | H | H | P82 | H | H | H | H |
| 729 | H | H | P83 | H | H | H | H |
| 730 | H | H | P84 | H | H | H | H |
| 731 | H | H | P85 | H | H | H | H |
| 732 | H | H | P86 | H | H | H | H |
| 733 | H | H | P87 | H | H | H | H |
| 734 | H | H | P88 | H | H | H | H |
| 735 | H | H | P89 | H | H | H | H |
| 736 | H | H | P90 | H | H | H | H |
| 737 | H | H | P91 | H | H | H | H |
| 738 | H | H | P92 | H | H | H | H |
| 739 | H | H | P93 | H | H | H | H |
| 740 | H | H | P94 | H | H | H | H |
| 741 | H | H | P95 | H | H | H | H |
| 742 | H | H | P98 | H | H | H | H |
| 743 | P97 | H | P21 | H | H | H | H |
| 744 | P97 | H | P97 | H | H | H | H |
| 745 | H | H | P101 | H | H | H | H |
| 746 | H | H | P102 | H | H | H | H |
| 747 | H | H | P103 | H | H | H | H |
| 748 | H | H | P104 | H | H | H | H |
| 749 | H | H | P105 | H | H | H | H |
| 750 | H | H | P106 | H | H | H | H |
| 751 | H | H | P107 | H | H | H | H |
| 752 | H | H | P108 | H | H | H | H |
| 753 | H | H | P109 | H | H | H | H |
| 754 | H | H | P110 | H | H | H | H |
| 755 | H | H | P111 | H | H | H | H |
| 756 | H | H | P112 | H | H | H | H |
| 757 | H | H | P113 | H | H | H | H |
| 758 | H | H | P114 | H | H | H | H |
| 759 | H | H | P115 | H | H | H | H |
| 760 | H | H | P116 | H | H | H | H |
| 761 | H | H | P117 | H | H | H | H |
| 762 | H | H | P118 | H | H | H | H |
| 763 | H | H | P119 | H | H | H | H |
| 764 | H | H | P120 | H | H | H | H |
| 765 | H | H | P121 | H | H | H | H |
| 766 | H | H | P122 | H | H | H | H |
| 767 | H | H | P123 | H | H | H | H |
| 768 | H | H | P124 | H | H | H | H |
| 769 | H | H | P125 | H | H | H | H |
| 770 | H | H | P126 | H | H | H | H |
| 771 | H | H | P127 | H | H | H | H |
| 772 | H | H | P128 | H | H | H | H |
| 773 | H | H | P129 | H | H | H | H |
| 774 | H | H | P130 | H | H | H | H |
| 775 | H | H | P131 | H | H | H | H |
| 776 | H | H | P132 | H | H | H | H |
| 777 | H | H | P133 | H | H | H | H |
| 778 | H | H | P134 | H | H | H | H |
| 779 | H | H | P135 | H | H | H | H |
| 780 | H | H | P136 | H | H | H | H |
| 781 | H | H | P137 | H | H | H | H |
| 782 | H | H | P138 | H | H | H | H |
| 783 | H | H | P139 | H | H | H | H |
| 784 | H | H | P140 | H | H | H | H |
| 785 | H | H | P141 | H | H | H | H |
| 786 | H | H | P142 | H | H | H | H |
| 787 | H | H | P143 | H | H | H | H |
| 788 | H | H | P144 | H | H | H | H |
| 789 | H | H | P145 | H | H | H | H |
| 790 | H | H | P146 | H | H | H | H |
| 791 | H | H | P147 | H | H | H | H |
| 792 | H | H | P148 | H | H | H | H |
| 793 | H | H | P149 | H | H | H | H |
| 794 | H | H | P150 | H | H | H | H |
| 795 | H | H | P151 | H | H | H | H |
| 796 | H | P18 | H | H | H | H | H |
| 797 | H | P18 | D | H | H | H | H |
| 798 | H | P18 | P20 | H | H | H | H |
| 799 | H | P19 | H | H | H | H | H |
| 800 | H | P19 | D | H | H | H | H |
| 801 | H | P19 | P20 | H | H | H | H |
| 802 | H | P20 | H | H | H | H | H |
| 803 | H | P20 | D | H | H | H | H |
| 804 | H | P20 | H | H | P1 | H | H |
| 805 | H | P20 | D | H | P2 | H | H |
| 806 | H | P20 | H | H | H | P1 | H |
| 807 | H | P20 | D | H | H | P2 | H |
| 808 | H | P20 | H | H | P1 | P1 | H |
| 809 | H | P20 | D | H | P2 | P2 | H |
| 810 | H | P20 | H | H | P3 | H | H |
| 811 | H | P20 | D | H | P4 | H | H |
| 812 | H | P20 | H | H | P5 | H | H |
| 813 | H | P21 | H | H | H | H | H |
| 814 | H | P21 | D | H | H | H | H |
| 815 | H | P21 | H | H | P1 | H | H |
| 816 | H | P21 | D | H | P2 | H | H |
| 817 | H | P21 | H | H | H | P1 | H |
| 818 | H | P21 | D | H | H | P2 | H |
| 819 | H | P21 | H | H | P1 | P1 | H |
| 820 | H | P21 | D | H | P2 | P2 | H |
| 821 | H | P21 | H | H | P3 | H | H |
| 822 | H | P21 | D | H | P4 | H | H |
| 823 | H | P21 | H | H | P5 | H | H |

wherein P1 to P151 have the following structures: 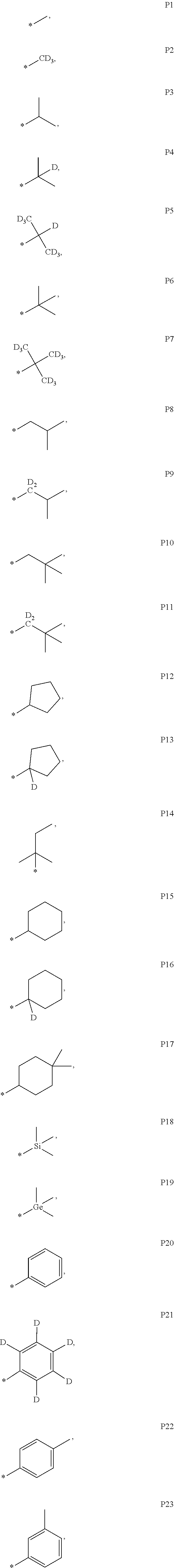 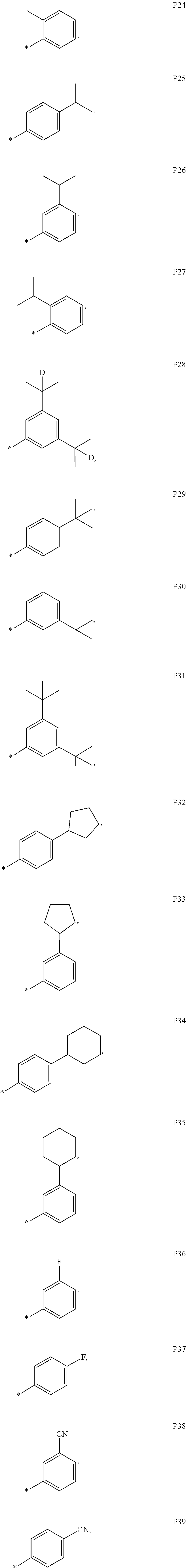 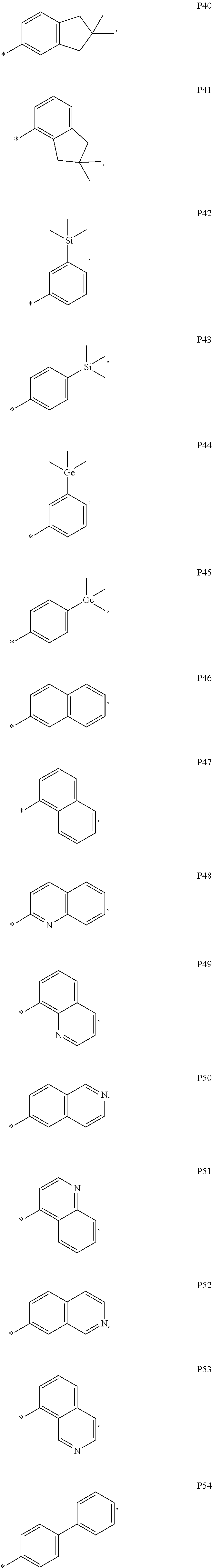 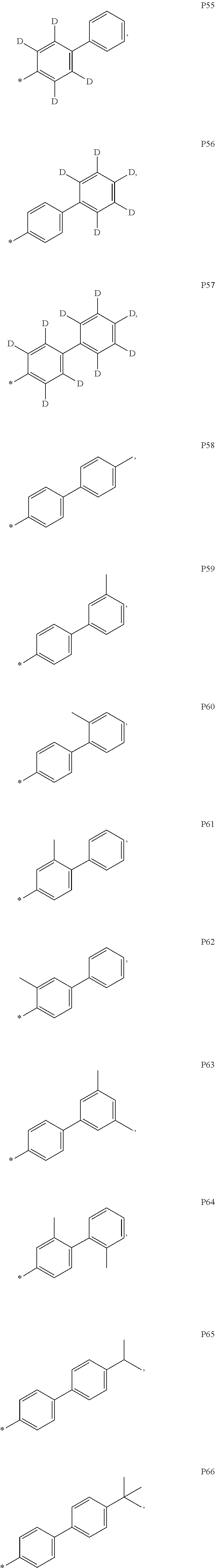 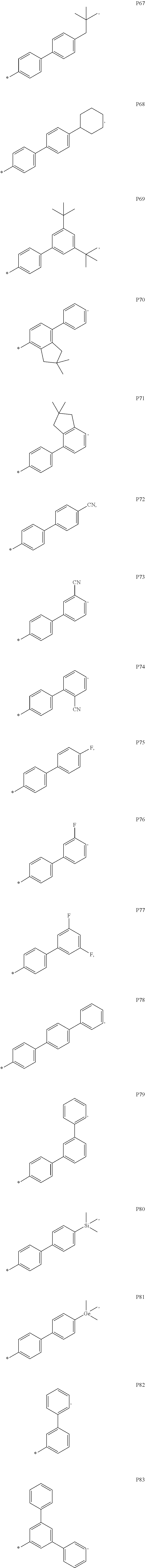 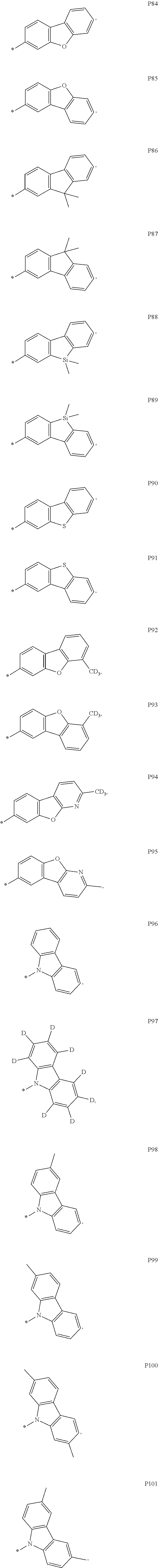 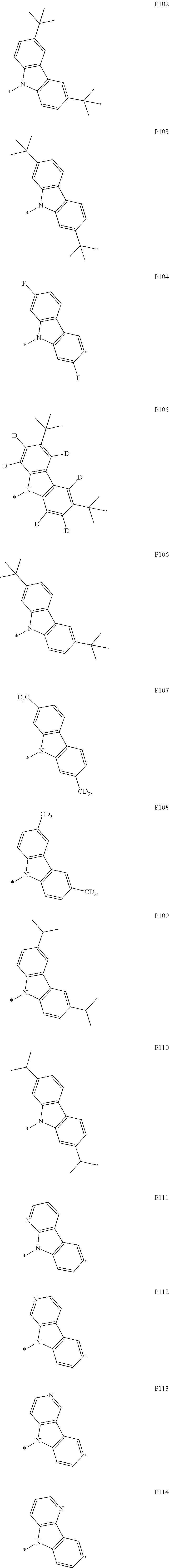 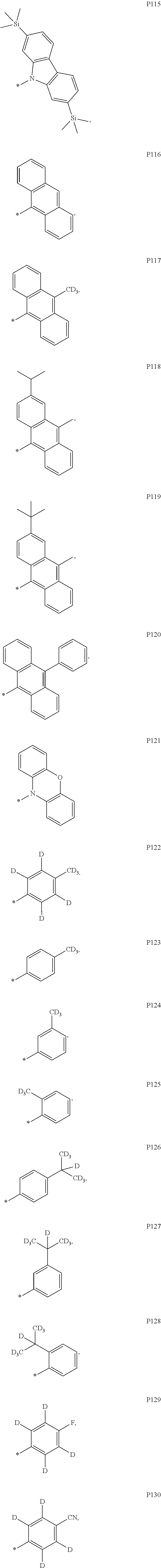 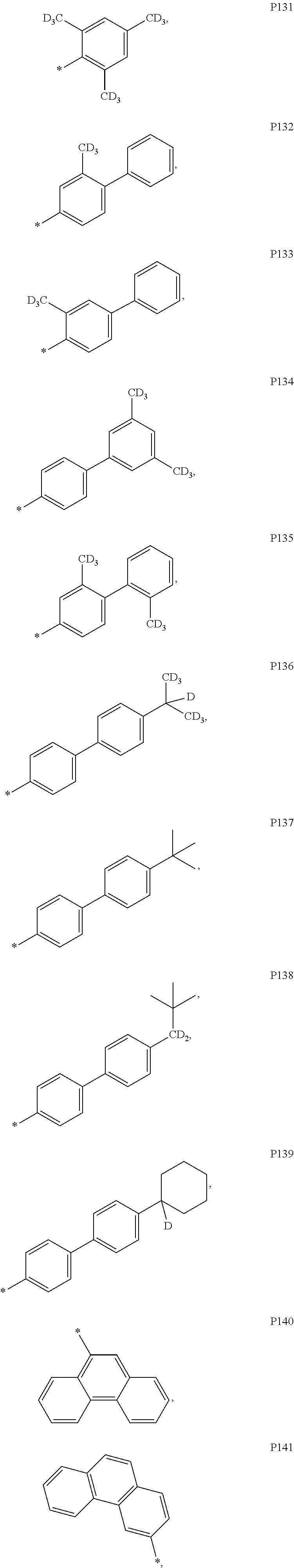 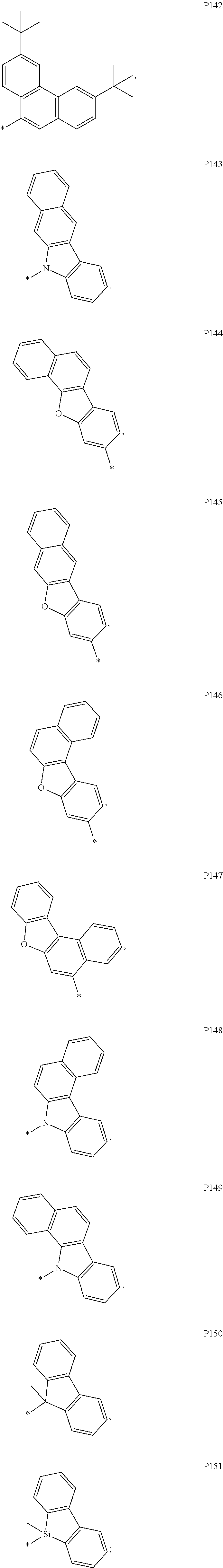
wherein “*” in P1 to P151 represents to the position of attachment to Lₐ; optionally, hydrogens in ligands Lₐ₋₁₋₁ to Lₐ₋₁₋₈₂₃, Lₐ₋₂₋₁ to Lₐ₋₂₋₈₂₃, Lₐ₋₃₋₁ to Lₐ₋₃₋₈₂₃, Lₐ₋₄₋₁ to Lₐ₋₄₋₈₂₃, Lₐ₋₅₋₁ to Lₐ₋₅₋₈₂₃, and Lₐ₋₆₋₁ to Lₐ₋₆₋₈₂₃ can be partially or completely substituted with deuterium.

15. The metal complex of claim 14, wherein L_{b} is, at each occurrence identically or differently, selected from the group consisting of L_{b1} to L_{b751}, wherein L_{b1} to L_{b751} have a structure represented by Formula 3: 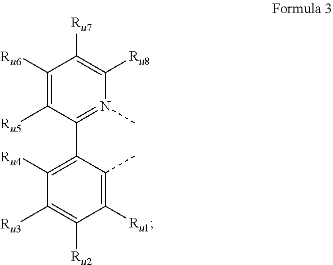
wherein Rᵤ₁ to Rᵤ₈ in Formula 3 correspond to the following table, respectively:

| L_{b} No. | Rᵤ₁ | Rᵤ₂ | Rᵤ₃ | Rᵤ₄ | Rᵤ₅ | Rᵤ₆ | Rᵤ₇ | Rᵤ₈ |
|---|---|---|---|---|---|---|---|---|
| L_{b1} | H | Rₚ₁ | H | H | H | Rₚ₁ | Rₚ₁ | H |
| L_{b2} | H | Rₚ₂ | H | H | H | Rₚ₁ | Rₚ₁ | H |
| L_{b3} | H | Rₚ₃ | H | H | H | Rₚ₁ | Rₚ₁ | H |
| L_{b4} | H | Rₚ₄ | H | H | H | Rₚ₁ | Rₚ₁ | H |
| L_{b5} | H | Rₚ₅ | H | H | H | Rₚ₁ | Rₚ₁ | H |
| L_{b6} | H | Rₚ₆ | H | H | H | Rₚ₁ | Rₚ₁ | H |
| L_{b7} | H | Rₚ₇ | H | H | H | Rₚ₁ | Rₚ₁ | H |
| L_{b8} | H | Rₚ₈ | H | H | H | Rₚ₁ | Rₚ₁ | H |
| L_{b9} | H | Rₚ₉ | H | H | H | Rₚ₁ | Rₚ₁ | H |
| L_{b10} | H | Rₚ₁₀ | H | H | H | Rₚ₁ | Rₚ₁ | H |
| L_{b11} | H | Rₚ₁₁ | H | H | H | Rₚ₁ | Rₚ₁ | H |
| L_{b12} | H | Rₚ₁₂ | H | H | H | Rₚ₁ | Rₚ₁ | H |
| L_{b13} | H | Rₚ₁₃ | H | H | H | Rₚ₁ | Rₚ₁ | H |
| L_{b14} | H | Rₚ₁₄ | H | H | H | Rₚ₁ | Rₚ₁ | H |
| L_{b15} | H | Rₚ₁₅ | H | H | H | Rₚ₁ | Rₚ₁ | H |
| L_{b16} | H | Rₚ₁₆ | H | H | H | Rₚ₁ | Rₚ₁ | H |
| L_{b17} | H | Rₚ₁₇ | H | H | H | Rₚ₁ | Rₚ₁ | H |
| L_{b18} | H | Rₚ₁₈ | H | H | H | Rₚ₁ | Rₚ₁ | H |
| L_{b19} | H | Rₚ₁₉ | H | H | H | Rₚ₁ | Rₚ₁ | H |
| L_{b20} | H | Rₚ₂₀ | H | H | H | Rₚ₂₀ | Rₚ₂₀ | H |
| L_{b21} | H | Rₚ₂₁ | H | H | H | Rₚ₂₀ | Rₚ₂₀ | H |
| L_{b22} | H | Rₚ₂₂ | H | H | H | Rₚ₂₀ | Rₚ₂₀ | H |
| L_{b23} | H | Rₚ₂₃ | H | H | H | Rₚ₂₀ | Rₚ₂₀ | H |
| L_{b24} | H | Rₚ₂₄ | H | H | H | Rₚ₂₀ | Rₚ₂₀ | H |
| L_{b25} | H | Rₚ₂₅ | H | H | H | Rₚ₂₀ | Rₚ₂₀ | H |
| L_{b26} | H | Rₚ₂₆ | H | H | H | Rₚ₂₀ | Rₚ₂₀ | H |
| L_{b27} | H | Rₚ₂₇ | H | H | H | Rₚ₂₀ | Rₚ₂₀ | H |
| L_{b28} | H | Rₚ₂₈ | H | H | H | Rₚ₂₀ | Rₚ₂₀ | H |
| L_{b29} | H | Rₚ₂₉ | H | H | H | Rₚ₂₀ | Rₚ₂₀ | H |
| L_{b30} | H | Rₚ₃₀ | H | H | H | Rₚ₂₀ | Rₚ₂₀ | H |
| L_{b31} | H | H | Rₚ₁ | H | H | Rₚ₁ | Rₚ₁ | H |
| L_{b32} | H | H | Rₚ₂ | H | H | Rₚ₁ | Rₚ₁ | H |
| L_{b33} | H | H | Rₚ₃ | H | H | Rₚ₁ | Rₚ₁ | H |
| L_{b34} | H | H | Rₚ₄ | H | H | Rₚ₁ | Rₚ₁ | H |
| L_{b35} | H | H | Rₚ₅ | H | H | Rₚ₁ | Rₚ₁ | H |
| L_{b36} | H | H | Rₚ₆ | H | H | Rₚ₁ | Rₚ₁ | H |
| L_{b37} | H | H | Rₚ₇ | H | H | Rₚ₁ | Rₚ₁ | H |
| L_{b38} | H | H | Rₚ₈ | H | H | Rₚ₁ | Rₚ₁ | H |
| L_{b39} | H | H | Rₚ₉ | H | H | Rₚ₁ | Rₚ₁ | H |
| L_{b40} | H | H | Rₚ₁₀ | H | H | Rₚ₁ | Rₚ₁ | H |
| L_{b41} | H | H | Rₚ₁₁ | H | H | Rₚ₁ | Rₚ₁ | H |
| L_{b42} | H | H | Rₚ₁₂ | H | H | Rₚ₁ | Rₚ₁ | H |
| L_{b43} | H | H | Rₚ₁₃ | H | H | Rₚ₁ | Rₚ₁ | H |
| L_{b44} | H | H | Rₚ₁₄ | H | H | Rₚ₁ | Rₚ₁ | H |
| L_{b45} | H | H | Rₚ₁₅ | H | H | Rₚ₁ | Rₚ₁ | H |
| L_{b46} | H | H | Rₚ₁₆ | H | H | Rₚ₁ | Rₚ₁ | H |
| L_{b47} | H | H | Rₚ₁₇ | H | H | Rₚ₁ | Rₚ₁ | H |
| L_{b48} | H | H | Rₚ₁₈ | H | H | Rₚ₁ | Rₚ₁ | H |
| L_{b49} | H | H | Rₚ₁₉ | H | H | Rₚ₁ | Rₚ₁ | H |
| L_{b50} | H | H | Rₚ₂₀ | H | H | Rₚ₂₀ | Rₚ₂₀ | H |
| L_{b51} | H | H | Rₚ₂₁ | H | H | Rₚ₂₀ | Rₚ₂₀ | H |
| L_{b52} | H | H | Rₚ₂₂ | H | H | Rₚ₂₀ | Rₚ₂₀ | H |
| L_{b53} | H | H | Rₚ₂₃ | H | H | Rₚ₂₀ | Rₚ₂₀ | H |
| L_{b54} | H | H | Rₚ₂₄ | H | H | Rₚ₂₀ | Rₚ₂₀ | H |
| L_{b55} | H | H | Rₚ₂₅ | H | H | Rₚ₂₀ | Rₚ₂₀ | H |
| L_{b56} | H | H | Rₚ₂₆ | H | H | Rₚ₂₀ | Rₚ₂₀ | H |
| L_{b57} | H | H | Rₚ₂₇ | H | H | Rₚ₂₀ | Rₚ₂₀ | H |
| L_{b58} | H | H | Rₚ₂₈ | H | H | Rₚ₂₀ | Rₚ₂₀ | H |
| L_{b59} | H | H | Rₚ₂₉ | H | H | Rₚ₂₀ | Rₚ₂₀ | H |
| L_{b60} | H | H | Rₚ₃₀ | H | H | Rₚ₂₀ | Rₚ₂₀ | H |
| L_{b61} | H | Rₚ₂₀ | H | H | D | Rₚ₂₀ | Rₚ₂₀ | D |
| L_{b62} | H | Rₚ₂₁ | H | H | D | Rₚ₂₀ | Rₚ₂₀ | D |
| L_{b63} | H | Rₚ₃ | H | H | D | Rₚ₂₀ | Rₚ₂₀ | D |
| L_{b64} | H | Rₚ₂₃ | H | H | D | Rₚ₂₀ | Rₚ₂₀ | D |
| L_{b65} | H | Rₚ₂₄ | H | H | D | Rₚ₂₀ | Rₚ₂₀ | D |
| L_{b66} | H | Rₚ₂₅ | H | H | D | Rₚ₂₀ | Rₚ₂₀ | D |
| L_{b67} | H | Rₚ₂₆ | H | H | D | Rₚ₂₀ | Rₚ₂₀ | D |
| L_{b68} | H | Rₚ₂₇ | H | H | D | Rₚ₂₀ | Rₚ₂₀ | D |
| L_{b69} | H | Rₚ₂₈ | H | H | D | Rₚ₂₀ | Rₚ₂₀ | D |
| L_{b70} | H | Rₚ₂₉ | H | H | D | Rₚ₂₀ | Rₚ₂₀ | D |
| L_{b71} | H | Rₚ₃₀ | H | H | D | Rₚ₂₀ | Rₚ₂₀ | D |
| L_{b72} | H | H | Rₚ₂₀ | H | D | Rₚ₂₀ | Rₚ₂₀ | D |
| L_{b73} | H | H | Rₚ₂₁ | H | D | Rₚ₂₀ | Rₚ₂₀ | D |
| L_{b74} | H | H | Rₚ₃ | H | D | Rₚ₂₀ | Rₚ₂₀ | D |
| L_{b75} | H | H | Rₚ₂₃ | H | D | Rₚ₂₀ | Rₚ₂₀ | D |
| L_{b76} | H | H | Rₚ₂₄ | H | D | Rₚ₂₀ | Rₚ₂₀ | D |
| L_{b77} | H | H | Rₚ₂₅ | H | D | Rₚ₂₀ | Rₚ₂₀ | D |
| L_{b78} | H | H | Rₚ₂₆ | H | D | Rₚ₂₀ | Rₚ₂₀ | D |
| L_{b79} | H | H | Rₚ₂₇ | H | D | Rₚ₂₀ | Rₚ₂₀ | D |
| L_{b80} | H | H | Rₚ₂₈ | H | D | Rₚ₂₀ | Rₚ₂₀ | D |
| L_{b81} | H | H | Rₚ₂₉ | H | D | Rₚ₂₀ | Rₚ₂₀ | D |
| L_{b82} | H | H | Rₚ₃₀ | H | D | Rₚ₂₀ | Rₚ₂₀ | D |
| L_{b83} | D | Rₚ₂₀ | D | D | D | Rₚ₂₀ | Rₚ₂₀ | D |
| L_{b84} | D | Rₚ₂₁ | D | D | D | Rₚ₂₀ | Rₚ₂₀ | D |
| L_{b85} | D | Rₚ₃ | D | D | D | Rₚ₂₀ | Rₚ₂₀ | D |
| L_{b86} | D | Rₚ₂₃ | D | D | D | Rₚ₂₀ | Rₚ₂₀ | D |
| L_{b87} | D | Rₚ₂₄ | D | D | D | Rₚ₂₀ | Rₚ₂₀ | D |
| L_{b88} | D | Rₚ₂₅ | D | D | D | Rₚ₂₀ | Rₚ₂₀ | D |
| L_{b89} | D | Rₚ₂₆ | D | D | D | Rₚ₂₀ | Rₚ₂₀ | D |
| L_{b90} | D | Rₚ₂₇ | D | D | D | Rₚ₂₀ | Rₚ₂₀ | D |
| L_{b91} | D | Rₚ₂₈ | D | D | D | Rₚ₂₀ | Rₚ₂₀ | D |
| L_{b92} | D | Rₚ₂₉ | D | D | D | Rₚ₂₀ | Rₚ₂₀ | D |
| L_{b93} | D | Rₚ₃₀ | D | D | D | Rₚ₂₀ | Rₚ₂₀ | D |
| L_{b94} | D | D | Rₚ₂₀ | D | D | Rₚ₂₀ | Rₚ₂₀ | D |
| L_{b95} | D | D | Rₚ₂₁ | D | D | Rₚ₂₀ | Rₚ₂₀ | D |
| L_{b96} | D | D | Rₚ₃ | D | D | Rₚ₂₀ | Rₚ₂₀ | D |
| L_{b97} | D | D | Rₚ₂₃ | D | D | Rₚ₂₀ | Rₚ₂₀ | D |
| L_{b98} | D | D | Rₚ₂₄ | D | D | Rₚ₂₀ | Rₚ₂₀ | D |
| L_{b99} | D | D | Rₚ₂₅ | D | D | Rₚ₂₀ | Rₚ₂₀ | D |
| L_{b100} | D | D | Rₚ₂₆ | D | D | Rₚ₂₀ | Rₚ₂₀ | D |
| L_{b101} | D | D | Rₚ₂₇ | D | D | Rₚ₂₀ | Rₚ₂₀ | D |
| L_{b102} | D | D | Rₚ₂₈ | D | D | Rₚ₂₀ | Rₚ₂₀ | D |
| L_{b103} | D | D | Rₚ₂₉ | D | D | Rₚ₂₀ | Rₚ₂₀ | D |
| L_{b104} | D | D | Rₚ₃₀ | D | D | Rₚ₂₀ | Rₚ₂₀ | D |
| L_{b105} | H | H | Rₚ₁ | H | H | Rₚ₁ | Rₚ₃ | H |
| L_{b106} | H | H | Rₚ₃ | H | H | Rₚ₁ | Rₚ₃ | H |
| L_{b107} | H | H | Rₚ₇ | H | H | Rₚ₁ | Rₚ₃ | H |
| L_{b108} | H | H | Rₚ₈ | H | H | Rₚ₁ | Rₚ₃ | H |
| L_{b109} | H | H | Rₚ₁₁ | H | H | Rₚ₁ | Rₚ₃ | H |
| L_{b110} | H | H | Rₚ₁ | H | H | Rₚ₃ | Rₚ₁ | H |
| L_{b111} | H | H | Rₚ₃ | H | H | Rₚ₃ | Rₚ₁ | H |
| L_{b112} | H | H | Rₚ₇ | H | H | Rₚ₃ | Rₚ₁ | H |
| L_{b113} | H | H | Rₚ₈ | H | H | Rₚ₃ | Rₚ₁ | H |
| L_{b114} | H | H | Rₚ₁₁ | H | H | Rₚ₃ | Rₚ₁ | H |
| L_{b115} | H | Rₚ₁ | H | H | H | Rₚ₁ | Rₚ₃ | H |
| L_{b116} | H | Rₚ₃ | H | H | H | Rₚ₁ | Rₚ₃ | H |
| L_{b117} | H | Rₚ₇ | H | H | H | Rₚ₁ | Rₚ₃ | H |
| L_{b118} | H | Rₚ₈ | H | H | H | Rₚ₁ | Rₚ₃ | H |
| L_{b119} | H | Rₚ₁₁ | H | H | H | Rₚ₁ | Rₚ₃ | H |
| L_{b120} | H | Rₚ₁ | H | H | H | Rₚ₃ | Rₚ₁ | H |
| L_{b121} | H | Rₚ₃ | H | H | H | Rₚ₃ | Rₚ₁ | H |
| L_{b122} | H | Rₚ₇ | H | H | H | Rₚ₃ | Rₚ₁ | H |
| L_{b123} | H | Rₚ₈ | H | H | H | Rₚ₃ | Rₚ₁ | H |
| L_{b124} | H | Rₚ₁₁ | H | H | H | Rₚ₃ | Rₚ₁ | H |
| L_{b125} | H | H | Rₚ₁ | H | H | Rₚ₁ | Rₚ₇ | H |
| L_{b126} | H | H | Rₚ₃ | H | H | Rₚ₁ | Rₚ₇ | H |
| L_{b127} | H | H | Rₚ₇ | H | H | Rₚ₁ | Rₚ₇ | H |
| L_{b128} | H | H | Rₚ₈ | H | H | Rₚ₁ | Rₚ₇ | H |
| L_{b129} | H | H | Rₚ₁₁ | H | H | Rₚ₁ | Rₚ₇ | H |
| L_{b130} | H | H | Rₚ₁ | H | H | Rₚ₇ | Rₚ₁ | H |
| L_{b131} | H | H | Rₚ₃ | H | H | Rₚ₇ | Rₚ₁ | H |
| L_{b132} | H | H | Rₚ₇ | H | H | Rₚ₇ | Rₚ₁ | H |
| L_{b133} | H | H | Rₚ₈ | H | H | Rₚ₇ | Rₚ₁ | H |
| L_{b134} | H | H | Rₚ₁₁ | H | H | Rₚ₇ | Rₚ₁ | H |
| L_{b135} | H | Rₚ₁ | H | H | H | Rₚ₁ | Rₚ₇ | H |
| L_{b136} | H | Rₚ₃ | H | H | H | Rₚ₁ | Rₚ₇ | H |
| L_{b137} | H | Rₚ₇ | H | H | H | Rₚ₁ | Rₚ₇ | H |
| L_{b138} | H | Rₚ₈ | H | H | H | Rₚ₁ | Rₚ₇ | H |
| L_{b139} | H | Rₚ₁₁ | H | H | H | Rₚ₁ | Rₚ₇ | H |
| L_{b140} | H | Rₚ₁ | H | H | H | Rₚ₇ | Rₚ₁ | H |
| L_{b141} | H | Rₚ₃ | H | H | H | Rₚ₇ | Rₚ₁ | H |
| L_{b142} | H | Rₚ₇ | H | H | H | Rₚ₇ | Rₚ₁ | H |
| L_{b143} | H | Rₚ₈ | H | H | H | Rₚ₇ | Rₚ₁ | H |
| L_{b144} | H | Rₚ₁₁ | H | H | H | Rₚ₇ | Rₚ₁ | H |
| L_{b145} | H | Rₚ₁ | H | H | H | Rₚ₁ | Rₚ₈ | H |
| L_{b146} | H | Rₚ₃ | H | H | H | Rₚ₁ | Rₚ₉ | H |
| L_{b147} | H | Rₚ₇ | H | H | H | Rₚ₁ | Rₚ₁₁ | H |
| L_{b148} | H | Rₚ₈ | H | H | H | Rₚ₁ | Rₚ₁₃ | H |
| L_{b149} | H | Rₚ₁₁ | H | H | H | Rₚ₁ | Rₚ₁₅ | H |
| L_{b150} | H | Rₚ₁ | H | H | H | Rₚ₈ | Rₚ₁ | H |
| L_{b151} | H | Rₚ₃ | H | H | H | Rₚ₉ | Rₚ₁ | H |
| L_{b152} | H | Rₚ₇ | H | H | H | Rₚ₁₁ | Rₚ₁ | H |
| L_{b153} | H | Rₚ₈ | H | H | H | Rₚ₁₃ | Rₚ₁ | H |
| L_{b154} | H | Rₚ₁₁ | H | H | H | Rₚ₁₅ | Rₚ₁ | H |
| L_{b155} | H | H | Rₚ₁ | H | H | Rₚ₁ | Rₚ₈ | H |
| L_{b156} | H | H | Rₚ₃ | H | H | Rₚ₁ | Rₚ₉ | H |
| L_{b157} | H | H | Rₚ₇ | H | H | Rₚ₁ | Rₚ₁₁ | H |
| L_{b158} | H | H | Rₚ₉ | H | H | Rₚ₁ | Rₚ₁₃ | H |
| L_{b159} | H | H | Rₚ₁₃ | H | H | Rₚ₁ | Rₚ₁₅ | H |
| L_{b160} | H | H | Rₚ₁ | H | H | Rₚ₈ | Rₚ₁ | H |
| L_{b161} | H | H | Rₚ₃ | H | H | Rₚ₉ | Rₚ₁ | H |
| L_{b162} | H | H | Rₚ₇ | H | H | Rₚ₁₁ | Rₚ₁ | H |
| L_{b163} | H | H | Rₚ₉ | H | H | Rₚ₁₃ | Rₚ₁ | H |
| L_{b164} | H | H | Rₚ₁₃ | H | H | Rₚ₁₅ | Rₚ₁ | H |
| L_{b165} | D | Rₚ₃ | D | D | D | Rₚ₂₀ | Rₚ₃ | D |
| L_{b166} | D | Rₚ₂₀ | D | D | D | Rₚ₂₀ | Rₚ₃ | D |
| L_{b167} | D | Rₚ₂₄ | D | D | D | Rₚ₂₀ | Rₚ₃ | D |
| L_{b168} | D | Rₚ₃ | D | D | D | Rₚ₃ | Rₚ₂₀ | D |
| L_{b169} | D | Rₚ₂₀ | D | D | D | Rₚ₃ | Rₚ₂₀ | D |
| L_{b170} | D | Rₚ₂₄ | D | D | D | Rₚ₃ | Rₚ₂₀ | D |
| L_{b171} | D | D | Rₚ₃ | D | D | Rₚ₂₀ | Rₚ₃ | D |
| L_{b172} | D | D | Rₚ₂₀ | D | D | Rₚ₂₀ | Rₚ₃ | D |
| L_{b173} | D | D | Rₚ₂₄ | D | D | Rₚ₂₀ | Rₚ₃ | D |
| L_{b174} | D | D | Rₚ₃ | D | D | Rₚ₃ | Rₚ₂₀ | D |
| L_{b175} | D | D | Rₚ₂₀ | D | D | Rₚ₃ | Rₚ₂₀ | D |
| L_{b176} | D | D | Rₚ₂₄ | D | D | Rₚ₃ | Rₚ₂₀ | D |
| L_{b177} | D | Rₚ₃ | D | D | D | Rₚ₂₄ | Rₚ₂₀ | D |
| L_{b178} | D | Rₚ₂₀ | D | D | D | Rₚ₂₄ | Rₚ₂₀ | D |
| L_{b179} | D | Rₚ₂₄ | D | D | D | Rₚ₂₄ | Rₚ₂₀ | D |
| L_{b180} | D | Rₚ₃ | D | D | D | Rₚ₂₀ | Rₚ₂₄ | D |
| L_{b181} | D | Rₚ₂₀ | D | D | D | Rₚ₂₀ | Rₚ₂₄ | D |
| L_{b182} | D | Rₚ₂₄ | D | D | D | Rₚ₂₀ | Rₚ₂₄ | D |
| L_{b183} | D | D | Rₚ₃ | D | D | Rₚ₂₄ | Rₚ₂₀ | D |
| L_{b184} | D | D | Rₚ₂₀ | D | D | Rₚ₂₄ | Rₚ₂₀ | D |
| L_{b185} | D | D | Rₚ₂₄ | D | D | Rₚ₂₄ | Rₚ₂₀ | D |
| L_{b186} | D | D | Rₚ₃ | D | D | Rₚ₂₀ | Rₚ₂₄ | D |
| L_{b187} | D | D | Rₚ₂₀ | D | D | Rₚ₂₀ | Rₚ₂₄ | D |
| L_{b188} | D | D | Rₚ₂₄ | D | D | Rₚ₂₀ | Rₚ₂₄ | D |
| L_{b189} | H | Rₚ₁ | H | H | H | Rₚ₃ | Rₚ₃ | H |
| L_{b190} | H | Rₚ₃ | H | H | H | Rₚ₃ | Rₚ₃ | H |
| L_{b191} | H | Rₚ₇ | H | H | H | Rₚ₃ | Rₚ₃ | H |
| L_{b192} | H | Rₚ₈ | H | H | H | Rₚ₃ | Rₚ₃ | H |
| L_{b193} | H | Rₚ₁₁ | H | H | H | Rₚ₃ | Rₚ₃ | H |
| L_{b194} | H | Rₚ₂₀ | H | H | D | Rₚ₃ | Rₚ₃ | D |
| L_{b195} | D | Rₚ₂₄ | D | D | D | Rₚ₃ | Rₚ₃ | D |
| L_{b196} | H | H | Rₚ₁ | H | H | Rₚ₃ | Rₚ₃ | H |
| L_{b197} | H | H | Rₚ₃ | H | H | Rₚ₃ | Rₚ₃ | H |
| L_{b198} | H | H | Rₚ₇ | H | H | Rₚ₃ | Rₚ₃ | H |
| L_{b199} | H | H | Rₚ₈ | H | H | Rₚ₃ | Rₚ₃ | H |
| L_{b200} | H | H | Rₚ₁₁ | H | H | Rₚ₃ | Rₚ₃ | H |
| L_{b201} | H | H | Rₚ₂₀ | H | D | Rₚ₃ | Rₚ₃ | D |
| L_{b202} | D | D | Rₚ₂₄ | D | D | Rₚ₃ | Rₚ₃ | D |
| L_{b203} | H | H | Rₚ₂₀ | H | D | Rₚ₃ | Rₚ₂₄ | D |
| L_{b204} | D | D | Rₚ₂₄ | D | D | Rₚ₃ | Rₚ₂₄ | D |
| L_{b205} | H | H | Rₚ₂₀ | H | D | Rₚ₂₄ | Rₚ₃ | D |
| L_{b206} | D | D | Rₚ₂₄ | D | D | Rₚ₂₄ | Rₚ₃ | D |
| L_{b207} | D | D | Rₚ₃ | D | D | Rₚ₂₄ | Rₚ₂₄ | D |
| L_{b208} | D | Rₚ₃ | D | D | D | Rₚ₂₄ | Rₚ₂₄ | D |
| L_{b209} | D | Rₚ₂₀ | D | D | D | Rₚ₂₄ | Rₚ₂₄ | D |
| L_{b210} | D | D | Rₚ₂₀ | D | D | Rₚ₂₄ | Rₚ₂₄ | D |
| L_{b211} | D | D | Rₚ₂₄ | D | D | Rₚ₂₄ | Rₚ₂₄ | D |
| L_{b212} | H | Rₚ₃ | H | H | H | Rₚ₁ | Rₚ₁₆ | H |
| L_{b213} | H | Rₚ₃ | H | H | H | Rₚ₁ | Rₚ₁₇ | H |
| L_{b214} | H | Rₚ₃ | H | H | D | Rₚ₂₀ | Rₚ₃₀ | D |
| L_{b215} | H | H | Rₚ₃ | H | H | Rₚ₁ | Rₚ₁₆ | H |
| L_{b216} | H | H | Rₚ₃ | H | H | Rₚ₁ | Rₚ₁₇ | H |
| L_{b217} | H | H | Rₚ₃ | H | D | Rₚ₂₀ | Rₚ₃₀ | D |
| L_{b218} | H | Rₚ₃ | H | H | H | Rₚ₁₆ | Rₚ₁ | H |
| L_{b219} | H | Rₚ₃ | H | H | H | Rₚ₁₇ | Rₚ₁ | H |
| L_{b220} | H | Rₚ₃ | H | H | H | Rₚ₃₀ | Rₚ₂₀ | H |
| L_{b221} | H | H | Rₚ₃ | H | H | Rₚ₁₆ | Rₚ₁ | H |
| L_{b222} | H | H | Rₚ₃ | H | H | Rₚ₁₇ | Rₚ₁ | H |
| L_{b223} | H | H | Rₚ₃ | H | D | Rₚ₃₀ | Rₚ₂₀ | D |
| L_{b224} | H | Rₚ₈ | H | H | H | Rₚ₁ | Rₚ₁₆ | H |
| L_{b225} | H | Rₚ₉ | H | H | H | Rₚ₁ | Rₚ₁₇ | H |
| L_{b226} | H | Rₚ₁₁ | H | H | H | Rₚ₂₀ | Rₚ₃₀ | H |
| L_{b227} | H | H | Rₚ₇ | H | H | Rₚ₁ | Rₚ₁₆ | H |
| L_{b228} | H | H | Rₚ₉ | H | H | Rₚ₁ | Rₚ₁₇ | H |
| L_{b229} | H | H | Rₚ₁₃ | H | D | Rₚ₂₀ | Rₚ₃₀ | D |
| L_{b230} | H | Rₚ₇ | H | H | H | Rₚ₁₆ | Rₚ₁ | H |
| L_{b231} | H | Rₚ₁₁ | H | H | H | Rₚ₁₇ | Rₚ₁ | H |
| L_{b232} | H | Rₚ₁₃ | H | H | H | Rₚ₃₀ | Rₚ₂₀ | H |
| L_{b233} | H | H | Rₚ₇ | H | H | Rₚ₁₆ | Rₚ₁ | H |
| L_{b234} | H | H | Rₚ₉ | H | H | Rₚ₁₇ | Rₚ₁ | H |
| L_{b235} | D | D | Rₚ₂₄ | D | D | Rₚ₃₀ | Rₚ₂₀ | D |
| L_{b236} | D | D | Rₚ₂₄ | D | D | Rₚ₃₀ | Rₚ₂₀ | D |
| L_{b237} | D | D | Rₚ₃ | D | D | Rₚ₃₀ | Rₚ₂₀ | D |
| L_{b238} | D | Rₚ₃ | D | D | D | Rₚ₂₀ | Rₚ₃₀ | D |
| L_{b239} | D | Rₚ₃ | D | D | D | Rₚ₂₀ | Rₚ₃₀ | D |
| L_{b240} | D | Rₚ₃ | D | D | D | Rₚ₂₀ | Rₚ₃₀ | D |
| L_{b241} | H | Rₚ₁ | H | H | H | H | Rₚ₁ | Rₚ₁ |
| L_{b242} | H | Rₚ₃ | H | H | H | Rₚ₁ | H | Rₚ₁ |
| L_{b243} | H | Rₚ₇ | H | H | H | H | Rₚ₁ | Rₚ₁ |
| L_{b244} | H | Rₚ₈ | H | H | Rₚ₁ | H | H | Rₚ₁ |
| L_{b245} | H | Rₚ₁₁ | H | H | H | H | Rₚ₃ | Rₚ₂₀ |
| L_{b246} | H | Rₚ₂₀ | H | H | H | Rₚ₃ | H | Rₚ₁ |
| L_{b247} | H | Rₚ₂₄ | H | H | Rₚ₃ | H | H | Rₚ₂₀ |
| L_{b248} | H | H | Rₚ₁ | H | H | H | Rₚ₁ | Rₚ₂₀ |
| L_{b249} | H | H | Rₚ₃ | H | H | Rₚ₁ | H | Rₚ₁ |
| L_{b250} | H | H | Rₚ₇ | H | H | H | Rₚ₁ | Rₚ₂₀ |
| L_{b251} | H | H | Rₚ₈ | H | Rₚ₁ | H | H | Rₚ₁ |
| L_{b252} | H | H | Rₚ₁₁ | H | H | H | Rₚ₃ | Rₚ₂₀ |
| L_{b253} | H | H | Rₚ₂₀ | H | H | Rₚ₃ | H | Rₚ₁ |
| L_{b254} | H | H | Rₚ₂₄ | H | Rₚ₃ | H | H | Rₚ₂₀ |
| L_{b255} | H | H | H | Rₚ₁ | H | H | Rₚ₁ | Rₚ₂₀ |
| L_{b256} | H | H | H | Rₚ₁ | Rₚ₁ | H | H | Rₚ₁ |
| L_{b257} | Rₚ₁ | H | H | H | H | H | Rₚ₃ | Rₚ₁ |
| L_{b258} | Rₚ₂₀ | D | D | D | D | Rₚ₃ | D | Rₚ₂₀ |
| L_{b259} | Rₚ₂₀ | D | D | D | Rₚ₂₀ | Rₚ₃ | D | D |
| L_{b260} | Rₚ₂₀ | D | D | D | Rₚ₂₀ | D | Rₚ₃ | D |
| L_{b261} | H | Rₚ₁ | Rₚ₁ | H | H | H | Rₚ₁ | H |
| L_{b262} | H | Rₚ₁ | Rₚ₁ | H | H | H | Rₚ₂ | H |
| L_{b263} | H | Rₚ₁ | Rₚ₁ | H | H | H | Rₚ₃ | H |
| L_{b264} | H | Rₚ₁ | Rₚ₁ | H | H | H | Rₚ₄ | H |
| L_{b265} | H | Rₚ₁ | Rₚ₁ | H | H | H | Rₚ₅ | H |
| L_{b266} | H | Rₚ₁ | Rₚ₁ | H | H | H | Rₚ₆ | H |
| L_{b267} | H | Rₚ₁ | Rₚ₁ | H | H | H | Rₚ₇ | H |
| L_{b268} | H | Rₚ₁ | Rₚ₁ | H | H | H | Rₚ₈ | H |
| L_{b269} | H | Rₚ₁ | Rₚ₁ | H | H | H | Rₚ₉ | H |
| L_{b270} | H | Rₚ₁ | Rₚ₁ | H | H | H | Rₚ₁₀ | H |
| L_{b271} | H | Rₚ₁ | Rₚ₁ | H | H | H | Rₚ₁₁ | H |
| L_{b272} | H | Rₚ₁ | Rₚ₁ | H | H | H | Rₚ₁₂ | H |
| L_{b273} | H | Rₚ₁ | Rₚ₁ | H | H | H | Rₚ₁₃ | H |
| L_{b274} | H | Rₚ₁ | Rₚ₁ | H | H | H | Rₚ₁₄ | H |
| L_{b275} | H | Rₚ₁ | Rₚ₁ | H | H | H | Rₚ₁₅ | H |
| L_{b276} | H | Rₚ₁ | Rₚ₁ | H | H | H | Rₚ₁₆ | H |
| L_{b277} | H | Rₚ₁ | Rₚ₁ | H | H | H | Rₚ₁₇ | H |
| L_{b278} | H | Rₚ₁ | Rₚ₁ | H | H | H | Rₚ₁₈ | H |
| L_{b279} | H | Rₚ₁ | Rₚ₁ | H | H | H | Rₚ₁₉ | H |
| L_{b280} | H | Rₚ₂₀ | Rₚ₂₀ | H | H | H | Rₚ₂₀ | H |
| L_{b281} | H | Rₚ₂₀ | Rₚ₂₀ | H | H | H | Rₚ₂₁ | H |
| L_{b282} | H | Rₚ₂₀ | Rₚ₂₀ | H | H | H | Rₚ₂₂ | H |
| L_{b283} | H | Rₚ₂₀ | Rₚ₂₀ | H | H | H | Rₚ₂₃ | H |
| L_{b284} | H | Rₚ₂₀ | Rₚ₂₀ | H | H | H | Rₚ₂₄ | H |
| L_{b285} | H | Rₚ₂₀ | Rₚ₂₀ | H | H | H | Rₚ₂₅ | H |
| L_{b286} | H | Rₚ₂₀ | Rₚ₂₀ | H | H | H | Rₚ₂₆ | H |
| L_{b287} | H | Rₚ₂₀ | Rₚ₂₀ | H | H | H | Rₚ₂₇ | H |
| L_{b288} | H | Rₚ₂₀ | Rₚ₂₀ | H | H | H | Rₚ₂₈ | H |
| L_{b289} | H | Rₚ₂₀ | Rₚ₂₀ | H | H | H | Rₚ₂₉ | H |
| L_{b290} | H | Rₚ₂₀ | Rₚ₂₀ | H | H | H | Rₚ₃₀ | H |
| L_{b291} | H | Rₚ₁ | Rₚ₁ | H | H | Rₚ₁ | H | H |
| L_{b292} | H | Rₚ₁ | Rₚ₁ | H | H | Rₚ₂ | H | H |
| L_{b293} | H | Rₚ₁ | Rₚ₁ | H | H | Rₚ₃ | H | H |
| L_{b294} | H | Rₚ₁ | Rₚ₁ | H | H | Rₚ₄ | H | H |
| L_{b295} | H | Rₚ₁ | Rₚ₁ | H | H | Rₚ₅ | H | H |
| L_{b296} | H | Rₚ₁ | Rₚ₁ | H | H | Rₚ₆ | H | H |
| L_{b297} | H | Rₚ₁ | Rₚ₁ | H | H | Rₚ₇ | H | H |
| L_{b298} | H | Rₚ₁ | Rₚ₁ | H | H | Rₚ₈ | H | H |
| L_{b299} | H | Rₚ₁ | Rₚ₁ | H | H | Rₚ₉ | H | H |
| L_{b300} | H | Rₚ₁ | Rₚ₁ | H | H | Rₚ₁₀ | H | H |
| L_{b301} | H | Rₚ₁ | Rₚ₁ | H | H | Rₚ₁₁ | H | H |
| L_{b302} | H | Rₚ₁ | Rₚ₁ | H | H | Rₚ₁₂ | H | H |
| L_{b303} | H | Rₚ₁ | Rₚ₁ | H | H | Rₚ₁₃ | H | H |
| L_{b304} | H | Rₚ₁ | Rₚ₁ | H | H | Rₚ₁₄ | H | H |
| L_{b305} | H | Rₚ₁ | Rₚ₁ | H | H | Rₚ₁₅ | H | H |
| L_{b306} | H | Rₚ₁ | Rₚ₁ | H | H | Rₚ₁₆ | H | H |
| L_{b307} | H | Rₚ₁ | Rₚ₁ | H | H | Rₚ₁₇ | H | H |
| L_{b308} | H | Rₚ₁ | Rₚ₁ | H | H | Rₚ₁₈ | H | H |
| L_{b309} | H | Rₚ₁ | Rₚ₁ | H | H | Rₚ₁₉ | H | H |
| L_{b310} | H | Rₚ₂₀ | Rₚ₂₀ | H | H | Rₚ₂₀ | H | H |
| L_{b311} | H | Rₚ₂₀ | Rₚ₂₀ | H | H | Rₚ₂₁ | H | H |
| L_{b312} | H | Rₚ₂₀ | Rₚ₂₀ | H | H | Rₚ₂₂ | H | H |
| L_{b313} | H | Rₚ₂₀ | Rₚ₂₀ | H | H | Rₚ₂₃ | H | H |
| L_{b314} | H | Rₚ₂₀ | Rₚ₂₀ | H | H | Rₚ₂₄ | H | H |
| L_{b315} | H | Rₚ₂₀ | Rₚ₂₀ | H | H | Rₚ₂₅ | H | H |
| L_{b316} | H | Rₚ₂₀ | Rₚ₂₀ | H | H | Rₚ₂₆ | H | H |
| L_{b317} | H | Rₚ₂₀ | Rₚ₂₀ | H | H | Rₚ₂₇ | H | H |
| L_{b318} | H | Rₚ₂₀ | Rₚ₂₀ | H | H | Rₚ₂₈ | H | H |
| L_{b319} | H | Rₚ₂₀ | Rₚ₂₀ | H | H | Rₚ₂₉ | H | H |
| L_{b320} | H | Rₚ₂₀ | Rₚ₂₀ | H | H | Rₚ₃₀ | H | H |
| L_{b321} | D | Rₚ₂₀ | Rₚ₂₀ | D | H | H | Rₚ₂₀ | H |
| L_{b322} | D | Rₚ₂₀ | Rₚ₂₀ | D | H | H | Rₚ₂₁ | H |
| L_{b323} | D | Rₚ₂₀ | Rₚ₂₀ | D | H | H | Rₚ₃ | H |
| L_{b324} | D | Rₚ₂₀ | Rₚ₂₀ | D | H | H | Rₚ₂₃ | H |
| L_{b325} | D | Rₚ₂₀ | Rₚ₂₀ | D | H | H | Rₚ₂₄ | H |
| L_{b326} | D | Rₚ₂₀ | Rₚ₂₀ | D | H | H | Rₚ₂₅ | H |
| L_{b327} | D | Rₚ₂₀ | Rₚ₂₀ | D | H | H | Rₚ₂₆ | H |
| L_{b328} | D | Rₚ₂₀ | Rₚ₂₀ | D | H | H | Rₚ₂₇ | H |
| L_{b329} | D | Rₚ₂₀ | Rₚ₂₀ | D | H | H | Rₚ₂₈ | H |
| L_{b330} | D | Rₚ₂₀ | Rₚ₂₀ | D | H | H | Rₚ₂₉ | H |
| L_{b331} | D | Rₚ₂₀ | Rₚ₂₀ | D | H | H | Rₚ₃₀ | H |
| L_{b332} | D | Rₚ₂₀ | Rₚ₂₀ | D | H | Rₚ₂₀ | H | H |
| L_{b333} | D | Rₚ₂₀ | Rₚ₂₀ | D | H | Rₚ₂₁ | H | H |
| L_{b334} | D | Rₚ₂₀ | Rₚ₂₀ | D | H | Rₚ₃ | H | H |
| L_{b335} | D | Rₚ₂₀ | Rₚ₂₀ | D | H | Rₚ₂₃ | H | H |
| L_{b336} | D | Rₚ₂₀ | Rₚ₂₀ | D | H | Rₚ₂₄ | H | H |
| L_{b337} | D | Rₚ₂₀ | Rₚ₂₀ | D | H | Rₚ₂₅ | H | H |
| L_{b338} | D | Rₚ₂₀ | Rₚ₂₀ | D | H | Rₚ₂₆ | H | H |
| L_{b339} | D | Rₚ₂₀ | Rₚ₂₀ | D | H | Rₚ₂₇ | H | H |
| L_{b340} | D | Rₚ₂₀ | Rₚ₂₀ | D | H | Rₚ₂₈ | H | H |
| L_{b341} | D | Rₚ₂₀ | Rₚ₂₀ | D | H | Rₚ₂₉ | H | H |
| L_{b342} | D | Rₚ₂₀ | Rₚ₂₀ | D | H | Rₚ₃₀ | H | H |
| L_{b343} | D | Rₚ₂₀ | Rₚ₂₀ | D | D | D | Rₚ₂₀ | D |
| L_{b344} | D | Rₚ₂₀ | Rₚ₂₀ | D | D | D | Rₚ₂₁ | D |
| L_{b345} | D | Rₚ₂₀ | Rₚ₂₀ | D | D | D | Rₚ₃ | D |
| L_{b346} | D | Rₚ₂₀ | Rₚ₂₀ | D | D | D | Rₚ₂₃ | D |
| L_{b347} | D | Rₚ₂₀ | Rₚ₂₀ | D | D | D | Rₚ₂₄ | D |
| L_{b348} | D | Rₚ₂₀ | Rₚ₂₀ | D | D | D | Rₚ₂₅ | D |
| L_{b349} | D | Rₚ₂₀ | Rₚ₂₀ | D | D | D | Rₚ₂₆ | D |
| L_{b350} | D | Rₚ₂₀ | Rₚ₂₀ | D | D | D | Rₚ₂₇ | D |
| L_{b351} | D | Rₚ₂₀ | Rₚ₂₀ | D | D | D | Rₚ₂₈ | D |
| L_{b352} | D | Rₚ₂₀ | Rₚ₂₀ | D | D | D | Rₚ₂₉ | D |
| L_{b353} | D | Rₚ₂₀ | Rₚ₂₀ | D | D | D | Rₚ₃₀ | D |
| L_{b354} | D | Rₚ₂₀ | Rₚ₂₀ | D | D | Rₚ₂₀ | D | D |
| L_{b355} | D | Rₚ₂₀ | Rₚ₂₀ | D | D | Rₚ₂₁ | D | D |
| L_{b356} | D | Rₚ₂₀ | Rₚ₂₀ | D | D | Rₚ₃ | D | D |
| L_{b357} | D | Rₚ₂₀ | Rₚ₂₀ | D | D | Rₚ₂₃ | D | D |
| L_{b358} | D | Rₚ₂₀ | Rₚ₂₀ | D | D | Rₚ₂₄ | D | D |
| L_{b359} | D | Rₚ₂₀ | Rₚ₂₀ | D | D | Rₚ₂₅ | D | D |
| L_{b360} | D | Rₚ₂₀ | Rₚ₂₀ | D | D | Rₚ₂₆ | D | D |
| L_{b361} | D | Rₚ₂₀ | Rₚ₂₀ | D | D | Rₚ₂₇ | D | D |
| L_{b362} | D | Rₚ₂₀ | Rₚ₂₀ | D | D | Rₚ₂₈ | D | D |
| L_{b363} | D | Rₚ₂₀ | Rₚ₂₀ | D | D | Rₚ₂₉ | D | D |
| L_{b364} | D | Rₚ₂₀ | Rₚ₂₀ | D | D | Rₚ₃₀ | D | D |
| L_{b365} | H | Rₚ₃ | Rₚ₁ | H | H | Rₚ₁ | H | H |
| L_{b366} | H | Rₚ₃ | Rₚ₁ | H | H | Rₚ₃ | H | H |
| L_{b367} | H | Rₚ₃ | Rₚ₁ | H | H | Rₚ₇ | H | H |
| L_{b368} | H | Rₚ₃ | Rₚ₁ | H | H | Rₚ₈ | H | H |
| L_{b369} | H | Rₚ₃ | Rₚ₁ | H | H | Rₚ₁₁ | H | H |
| L_{b370} | H | Rₚ₁ | Rₚ₃ | H | H | Rₚ₁ | H | H |
| L_{b371} | H | Rₚ₁ | Rₚ₃ | H | H | Rₚ₃ | H | H |
| L_{b372} | H | Rₚ₁ | Rₚ₃ | H | H | Rₚ₇ | H | H |
| L_{b373} | H | Rₚ₁ | Rₚ₃ | H | H | Rₚ₈ | H | H |
| L_{b374} | H | Rₚ₁ | Rₚ₃ | H | H | Rₚ₁₁ | H | H |
| L_{b375} | H | Rₚ₃ | Rₚ₁ | H | H | H | Rₚ₁ | H |
| L_{b376} | H | Rₚ₃ | Rₚ₁ | H | H | H | Rₚ₃ | H |
| L_{b377} | H | Rₚ₃ | Rₚ₁ | H | H | H | Rₚ₇ | H |
| L_{b378} | H | Rₚ₃ | Rₚ₁ | H | H | H | Rₚ₈ | H |
| L_{b379} | H | Rₚ₃ | Rₚ₁ | H | H | H | Rₚ₁₁ | H |
| L_{b380} | H | Rₚ₁ | Rₚ₃ | H | H | H | Rₚ₁ | H |
| L_{b381} | H | Rₚ₁ | Rₚ₃ | H | H | H | Rₚ₃ | H |
| L_{b382} | H | Rₚ₁ | Rₚ₃ | H | H | H | Rₚ₇ | H |
| L_{b383} | H | Rₚ₁ | Rₚ₃ | H | H | H | Rₚ₈ | H |
| L_{b384} | H | Rₚ₁ | Rₚ₃ | H | H | H | Rₚ₁₁ | H |
| L_{b385} | H | Rₚ₇ | Rₚ₁ | H | H | Rₚ₁ | H | H |
| L_{b386} | H | Rₚ₇ | Rₚ₁ | H | H | Rₚ₃ | H | H |
| L_{b387} | H | Rₚ₇ | Rₚ₁ | H | H | Rₚ₇ | H | H |
| L_{b388} | H | Rₚ₇ | Rₚ₁ | H | H | Rₚ₈ | H | H |
| L_{b389} | H | Rₚ₇ | Rₚ₁ | H | H | Rₚ₁₁ | H | H |
| L_{b390} | H | Rₚ₁ | Rₚ₇ | H | H | Rₚ₁ | H | H |
| L_{b391} | H | Rₚ₁ | Rₚ₇ | H | H | Rₚ₃ | H | H |
| L_{b392} | H | Rₚ₁ | Rₚ₇ | H | H | Rₚ₇ | H | H |
| L_{b393} | H | Rₚ₁ | Rₚ₇ | H | H | Rₚ₈ | H | H |
| L_{b394} | H | Rₚ₁ | Rₚ₇ | H | H | Rₚ₁₁ | H | H |
| L_{b395} | H | Rₚ₇ | Rₚ₁ | H | H | H | Rₚ₁ | H |
| L_{b396} | H | Rₚ₇ | Rₚ₁ | H | H | H | Rₚ₃ | H |
| L_{b397} | H | Rₚ₇ | Rₚ₁ | H | H | H | Rₚ₇ | H |
| L_{b398} | H | Rₚ₇ | Rₚ₁ | H | H | H | Rₚ₈ | H |
| L_{b399} | H | Rₚ₇ | Rₚ₁ | H | H | H | Rₚ₁₁ | H |
| L_{b400} | H | Rₚ₁ | Rₚ₇ | H | H | H | Rₚ₁ | H |
| L_{b401} | H | Rₚ₁ | Rₚ₇ | H | H | H | Rₚ₃ | H |
| L_{b402} | H | Rₚ₁ | Rₚ₇ | H | H | H | Rₚ₇ | H |
| L_{b403} | H | Rₚ₁ | Rₚ₇ | H | H | H | Rₚ₈ | H |
| L_{b404} | H | Rₚ₁ | Rₚ₇ | H | H | H | Rₚ₁₁ | H |
| L_{b405} | H | Rₚ₈ | Rₚ₁ | H | H | H | Rₚ₁ | H |
| L_{b406} | H | Rₚ₉ | Rₚ₁ | H | H | H | Rₚ₃ | H |
| L_{b407} | H | Rₚ₁₁ | Rₚ₁ | H | H | H | Rₚ₇ | H |
| L_{b408} | H | Rₚ₁₃ | Rₚ₁ | H | H | H | Rₚ₈ | H |
| L_{b409} | H | Rₚ₁₅ | Rₚ₁ | H | H | H | Rₚ₁₁ | H |
| L_{b410} | H | Rₚ₁ | Rₚ₈ | H | H | H | Rₚ₁ | H |
| L_{b411} | H | Rₚ₁ | Rₚ₉ | H | H | H | Rₚ₃ | H |
| L_{b412} | H | Rₚ₁ | Rₚ₁₁ | H | H | H | Rₚ₇ | H |
| L_{b413} | H | Rₚ₁ | Rₚ₁₃ | H | H | H | Rₚ₈ | H |
| L_{b414} | H | Rₚ₁ | Rₚ₁₅ | H | H | H | Rₚ₁₁ | H |
| L_{b415} | H | Rₚ₈ | Rₚ₁ | H | H | Rₚ₁ | H | H |
| L_{b416} | H | Rₚ₉ | Rₚ₁ | H | H | Rₚ₃ | H | H |
| L_{b417} | H | Rₚ₁₁ | Rₚ₁ | H | H | Rₚ₇ | H | H |
| L_{b418} | H | Rₚ₁₃ | Rₚ₁ | H | H | Rₚ₉ | H | H |
| L_{b419} | H | Rₚ₁₅ | Rₚ₁ | H | H | Rₚ₁₃ | H | H |
| L_{b420} | H | Rₚ₁ | Rₚ₈ | H | H | Rₚ₁ | H | H |
| L_{b421} | H | Rₚ₁ | Rₚ₉ | H | H | Rₚ₃ | H | H |
| L_{b422} | H | Rₚ₁ | Rₚ₁₁ | H | H | Rₚ₇ | H | H |
| L_{b423} | H | Rₚ₁ | Rₚ₁₃ | H | H | Rₚ₉ | H | H |
| L_{b424} | H | Rₚ₁ | Rₚ₁₅ | H | H | Rₚ₁₃ | H | H |
| L_{b425} | D | Rₚ₃ | Rₚ₂₀ | D | D | D | Rₚ₃ | D |
| L_{b426} | D | Rₚ₃ | Rₚ₂₀ | D | D | D | Rₚ₂₀ | D |
| L_{b427} | D | Rₚ₃ | Rₚ₂₀ | D | D | D | Rₚ₂₄ | D |
| L_{b428} | D | Rₚ₂₀ | Rₚ₃ | D | D | D | Rₚ₃ | D |
| L_{b429} | D | Rₚ₂₀ | Rₚ₃ | D | D | D | Rₚ₂₀ | D |
| L_{b430} | D | Rₚ₂₀ | Rₚ₃ | D | D | D | Rₚ₂₄ | D |
| L_{b431} | D | Rₚ₃ | Rₚ₂₀ | D | D | Rₚ₃ | D | D |
| L_{b432} | D | Rₚ₃ | Rₚ₂₀ | D | D | Rₚ₂₀ | D | D |
| L_{b433} | D | Rₚ₃ | Rₚ₂₀ | D | D | Rₚ₂₄ | D | D |
| L_{b434} | D | Rₚ₂₀ | Rₚ₃ | D | D | Rₚ₃ | D | D |
| L_{b435} | D | Rₚ₂₀ | Rₚ₃ | D | D | Rₚ₂₀ | D | D |
| L_{b436} | D | Rₚ₂₀ | Rₚ₃ | D | D | Rₚ₂₄ | D | D |
| L_{b437} | D | Rₚ₂₀ | Rₚ₂₄ | D | D | D | Rₚ₃ | D |
| L_{b438} | D | Rₚ₂₀ | Rₚ₂₄ | D | D | D | Rₚ₂₀ | D |
| L_{b439} | D | Rₚ₂₀ | Rₚ₂₄ | D | D | D | Rₚ₂₄ | D |
| L_{b440} | D | Rₚ₂₄ | Rₚ₂₀ | D | D | D | Rₚ₃ | D |
| L_{b441} | D | Rₚ₂₄ | Rₚ₂₀ | D | D | D | Rₚ₂₀ | D |
| L_{b442} | D | Rₚ₂₄ | Rₚ₂₀ | D | D | D | Rₚ₂₄ | D |
| L_{b443} | D | Rₚ₂₀ | Rₚ₂₄ | D | D | Rₚ₃ | D | D |
| L_{b444} | D | Rₚ₂₀ | Rₚ₂₄ | D | D | Rₚ₂₀ | D | D |
| L_{b445} | D | Rₚ₂₀ | Rₚ₂₄ | D | D | Rₚ₂₄ | D | D |
| L_{b446} | D | Rₚ₂₄ | Rₚ₂₀ | D | D | Rₚ₃ | D | D |
| L_{b447} | D | Rₚ₂₄ | Rₚ₂₀ | D | D | Rₚ₂₀ | D | D |
| L_{b448} | D | Rₚ₂₄ | Rₚ₂₀ | D | D | Rₚ₂₄ | D | D |
| L_{b449} | H | Rₚ₃ | Rₚ₃ | H | H | H | Rₚ₁ | H |
| L_{b450} | H | Rₚ₃ | Rₚ₃ | H | H | H | Rₚ₃ | H |
| L_{b451} | H | Rₚ₃ | Rₚ₃ | H | H | H | Rₚ₇ | H |
| L_{b452} | H | Rₚ₃ | Rₚ₃ | H | H | H | Rₚ₈ | H |
| L_{b453} | H | Rₚ₃ | Rₚ₃ | H | H | H | Rₚ₁₁ | H |
| L_{b454} | D | Rₚ₃ | Rₚ₃ | D | H | H | Rₚ₂₀ | H |
| L_{b455} | D | Rₚ₃ | Rₚ₃ | D | D | D | Rₚ₂₄ | D |
| L_{b456} | H | Rₚ₃ | Rₚ₃ | H | H | Rₚ₁ | H | H |
| L_{b457} | H | Rₚ₃ | Rₚ₃ | H | H | Rₚ₃ | H | H |
| L_{b458} | H | Rₚ₃ | Rₚ₃ | H | H | Rₚ₇ | H | H |
| L_{b459} | H | Rₚ₃ | Rₚ₃ | H | H | Rₚ₈ | H | H |
| L_{b460} | H | Rₚ₃ | Rₚ₃ | H | H | Rₚ₁₁ | H | H |
| L_{b461} | D | Rₚ₃ | Rₚ₃ | D | H | Rₚ₂₀ | H | H |
| L_{b462} | D | Rₚ₃ | Rₚ₃ | D | D | Rₚ₂₄ | D | D |
| L_{b463} | D | Rₚ₂₄ | Rₚ₃ | D | H | Rₚ₂₀ | H | H |
| L_{b464} | D | Rₚ₂₄ | Rₚ₃ | D | D | Rₚ₂₄ | D | D |
| L_{b465} | D | Rₚ₃ | Rₚ₂₄ | D | H | Rₚ₂₀ | H | H |
| L_{b466} | D | Rₚ₃ | Rₚ₂₄ | D | D | Rₚ₂₄ | D | D |
| L_{b467} | D | Rₚ₂₄ | Rₚ₂₄ | D | D | Rₚ₃ | D | D |
| L_{b468} | D | Rₚ₂₄ | Rₚ₂₄ | D | D | D | Rₚ₃ | D |
| L_{b469} | D | Rₚ₂₄ | Rₚ₂₄ | D | D | D | Rₚ₂₀ | D |
| L_{b470} | D | Rₚ₂₄ | Rₚ₂₄ | D | D | Rₚ₂₀ | D | D |
| L_{b471} | D | Rₚ₂₄ | Rₚ₂₄ | D | D | Rₚ₂₄ | D | D |
| L_{b472} | H | Rₚ₁₆ | Rₚ₁ | H | H | H | Rₚ₃ | H |
| L_{b473} | H | Rₚ₁₇ | Rₚ₁ | H | H | H | Rₚ₃ | H |
| L_{b474} | D | Rₚ₃₀ | Rₚ₂₀ | D | H | H | Rₚ₃ | H |
| L_{b475} | H | Rₚ₁₆ | Rₚ₁ | H | H | Rₚ₃ | H | H |
| L_{b476} | H | Rₚ₁₇ | Rₚ₁ | H | H | Rₚ₃ | H | H |
| L_{b477} | D | Rₚ₃₀ | Rₚ₂₀ | D | H | Rₚ₃ | H | H |
| L_{b478} | H | Rₚ₁ | Rₚ₁₆ | H | H | H | Rₚ₃ | H |
| L_{b479} | H | Rₚ₁ | Rₚ₁₇ | H | H | H | Rₚ₃ | H |
| L_{b480} | H | Rₚ₂₀ | Rₚ₃₀ | H | H | H | Rₚ₃ | H |
| L_{b481} | H | Rₚ₁ | Rₚ₁₆ | H | H | Rₚ₃ | H | H |
| L_{b482} | H | Rₚ₁ | Rₚ₁₇ | H | H | Rₚ₃ | H | H |
| L_{b483} | D | Rₚ₂₀ | Rₚ₃₀ | D | H | Rₚ₃ | H | H |
| L_{b484} | H | Rₚ₁₆ | Rₚ₁ | H | H | H | Rₚ₈ | H |
| L_{b485} | H | Rₚ₁₇ | Rₚ₁ | H | H | H | Rₚ₉ | H |
| L_{b486} | H | Rₚ₃₀ | Rₚ₂₀ | H | H | H | Rₚ₁₁ | H |
| L_{b487} | H | Rₚ₁₆ | Rₚ₁ | H | H | Rₚ₇ | H | H |
| L_{b488} | H | Rₚ₁₇ | Rₚ₁ | H | H | Rₚ₉ | H | H |
| L_{b489} | D | Rₚ₃₀ | Rₚ₂₀ | D | H | Rₚ₁₃ | H | H |
| L_{b490} | H | Rₚ₁ | Rₚ₁₆ | H | H | H | Rₚ₇ | H |
| L_{b491} | H | Rₚ₁ | Rₚ₁₇ | H | H | H | Rₚ₁₁ | H |
| L_{b492} | H | Rₚ₂₀ | Rₚ₃₀ | H | H | H | Rₚ₁₃ | H |
| L_{b493} | H | Rₚ₁ | Rₚ₁₆ | H | H | Rₚ₇ | H | H |
| L_{b494} | H | Rₚ₁ | Rₚ₁₇ | H | H | Rₚ₉ | H | H |
| L_{b495} | D | Rₚ₂₀ | Rₚ₃₀ | D | D | Rₚ₂₄ | D | D |
| L_{b496} | D | Rₚ₂₀ | Rₚ₃₀ | D | D | Rₚ₂₄ | D | D |
| L_{b497} | D | Rₚ₂₀ | Rₚ₃₀ | D | D | Rₚ₃ | D | D |
| L_{b498} | D | Rₚ₃₀ | Rₚ₂₀ | D | D | D | Rₚ₃ | D |
| L_{b499} | D | Rₚ₃₀ | Rₚ₂₀ | D | D | D | Rₚ₃ | D |
| L_{b500} | D | Rₚ₃₀ | Rₚ₂₀ | D | D | D | Rₚ₃ | D |
| L_{b501} | Rₚ₁ | Rₚ₁ | H | H | H | H | Rₚ₁ | H |
| L_{b502} | Rₚ₁ | H | Rₚ₁ | H | H | H | Rₚ₃ | H |
| L_{b503} | Rₚ₁ | Rₚ₁ | H | H | H | H | Rₚ₇ | H |
| L_{b504} | Rₚ₁ | H | H | Rₚ₁ | H | H | Rₚ₈ | H |
| L_{b505} | Rₚ₂₀ | Rₚ₃ | H | H | H | H | Rₚ₁₁ | H |
| L_{b506} | Rₚ₁ | H | Rₚ₃ | H | H | H | Rₚ₂₀ | H |
| L_{b507} | Rₚ₂₀ | H | H | Rₚ₃ | H | H | Rₚ₂₄ | H |
| L_{b508} | Rₚ₂₀ | Rₚ₁ | H | H | H | Rₚ₁ | H | H |
| L_{b509} | Rₚ₁ | H | Rₚ₁ | H | H | Rₚ₃ | H | H |
| L_{b510} | Rₚ₂₀ | Rₚ₁ | H | H | H | Rₚ₇ | H | H |
| L_{b511} | Rₚ₁ | H | H | Rₚ₁ | H | Rₚ₈ | H | H |
| L_{b512} | Rₚ₂₀ | Rₚ₃ | H | H | H | Rₚ₁₁ | H | H |
| L_{b513} | Rₚ₁ | H | Rₚ₃ | H | H | Rₚ₂₀ | H | H |
| L_{b514} | Rₚ₂ | H | H | Rₚ₃ | H | Rₚ₂₄ | H | H |
| L_{b515} | Rₚ₂₀ | Rₚ₁ | H | H | Rₚ₁ | H | H | H |
| L_{b516} | Rₚ₁ | H | H | Rₚ₁ | Rₚ₁ | H | H | H |
| L_{b517} | Rₚ₁ | Rₚ₃ | H | H | H | H | H | Rₚ₁ |
| L_{b518} | Rₚ₂₀ | D | Rₚ₃ | D | D | 1 | D | Rₚ₂₀ |
| L_{b519} | D | D | Rₚ₃ | Rₚ₂₀ | D | D | D | Rₚ₂₀ |
| L_{b520} | D | Rₚ₃ | D | Rₚ₂₀ | D | D | D | Rₚ₂₀ |
| L_{b521} | H | Rₚ₁ | Rₚ₁ | H | H | Rₚ₁ | Rₚ₁ | H |
| L_{b522} | H | Rₚ₁ | Rₚ₂ | H | H | Rₚ₁ | Rₚ₁ | H |
| L_{b523} | H | Rₚ₁ | Rₚ₃ | H | H | Rₚ₁ | Rₚ₁ | H |
| L_{b524} | H | Rₚ₁ | Rₚ₄ | H | H | Rₚ₁ | Rₚ₁ | H |
| L_{b525} | H | Rₚ₁ | Rₚ₅ | H | H | Rₚ₁ | Rₚ₁ | H |
| L_{b526} | H | Rₚ₁ | Rₚ₆ | H | H | Rₚ₁ | Rₚ₁ | H |
| L_{b527} | H | Rₚ₁ | Rₚ₇ | H | H | Rₚ₁ | Rₚ₁ | H |
| L_{b528} | H | Rₚ₁ | Rₚ₈ | H | H | Rₚ₁ | Rₚ₁ | H |
| L_{b529} | H | Rₚ₁ | Rₚ₉ | H | H | Rₚ₁ | Rₚ₁ | H |
| L_{b530} | H | Rₚ₁ | Rₚ₁₀ | H | H | Rₚ₁ | Rₚ₁ | H |
| L_{b531} | H | Rₚ₁ | Rₚ₁₁ | H | H | Rₚ₁ | Rₚ₁ | H |
| L_{b532} | H | Rₚ₁ | Rₚ₁₂ | H | H | Rₚ₁ | Rₚ₁ | H |
| L_{b533} | H | Rₚ₁ | Rₚ₁₃ | H | H | Rₚ₁ | Rₚ₁ | H |
| L_{b534} | H | Rₚ₁ | Rₚ₁₄ | H | H | Rₚ₁ | Rₚ₁ | H |
| L_{b535} | H | Rₚ₁ | Rₚ₁₅ | H | H | Rₚ₁ | Rₚ₁ | H |
| L_{b536} | H | Rₚ₁ | Rₚ₁₆ | H | H | Rₚ₁ | Rₚ₁ | H |
| L_{b537} | H | Rₚ₁ | Rₚ₁₇ | H | H | Rₚ₁ | Rₚ₁ | H |
| L_{b538} | H | Rₚ₁ | Rₚ₁₈ | H | H | Rₚ₁ | Rₚ₁ | H |
| L_{b539} | H | Rₚ₁ | Rₚ₁₉ | H | H | Rₚ₁ | Rₚ₁ | H |
| L_{b540} | H | Rₚ₂₀ | Rₚ₂₀ | H | H | Rₚ₂₀ | Rₚ₂₀ | H |
| L_{b541} | H | Rₚ₂₀ | Rₚ₂₁ | H | H | Rₚ₂₀ | Rₚ₂₀ | H |
| L_{b542} | H | Rₚ₂₀ | Rₚ₂₂ | H | H | Rₚ₂₀ | Rₚ₂₀ | H |
| L_{b543} | H | Rₚ₂₀ | Rₚ₂₃ | H | H | Rₚ₂₀ | Rₚ₂₀ | H |
| L_{b544} | H | Rₚ₂₀ | Rₚ₂₄ | H | H | Rₚ₂₀ | Rₚ₂₀ | H |
| L_{b545} | H | Rₚ₂₀ | Rₚ₂₅ | H | H | Rₚ₂₀ | Rₚ₂₀ | H |
| L_{b546} | H | Rₚ₂₀ | Rₚ₂₆ | H | H | Rₚ₂₀ | Rₚ₂₀ | H |
| L_{b547} | H | Rₚ₂₀ | Rₚ₂₇ | H | H | Rₚ₂₀ | Rₚ₂₀ | H |
| L_{b548} | H | Rₚ₂₀ | Rₚ₂₈ | H | H | Rₚ₂₀ | Rₚ₂₀ | H |
| L_{b549} | H | Rₚ₂₀ | Rₚ₂₉ | H | H | Rₚ₂₀ | Rₚ₂₀ | H |
| L_{b550} | H | Rₚ₂₀ | Rₚ₃₀ | H | H | Rₚ₂₀ | Rₚ₂₀ | H |
| L_{b551} | D | Rₚ₂₀ | Rₚ₂₀ | D | D | Rₚ₂₀ | Rₚ₂₀ | D |
| L_{b552} | H | Rₚ₂ | Rₚ₁ | H | H | Rₚ₁ | Rₚ₁ | H |
| L_{b553} | H | Rₚ₃ | Rₚ₁ | H | H | Rₚ₁ | Rₚ₁ | H |
| L_{b554} | H | Rₚ₄ | Rₚ₁ | H | H | Rₚ₁ | Rₚ₁ | H |
| L_{b555} | H | Rₚ₅ | Rₚ₁ | H | H | Rₚ₁ | Rₚ₁ | H |
| L_{b556} | H | Rₚ₆ | Rₚ₁ | H | H | Rₚ₁ | Rₚ₁ | H |
| L_{b557} | H | Rₚ₇ | Rₚ₁ | H | H | Rₚ₁ | Rₚ₁ | H |
| L_{b558} | H | Rₚ₈ | Rₚ₁ | H | H | Rₚ₁ | Rₚ₁ | H |
| L_{b559} | H | Rₚ₉ | Rₚ₁ | H | H | Rₚ₁ | Rₚ₁ | H |
| L_{b560} | H | Rₚ₁₀ | Rₚ₁ | H | H | Rₚ₁ | Rₚ₁ | H |
| L_{b561} | H | Rₚ₁₁ | Rₚ₁ | H | H | Rₚ₁ | Rₚ₁ | H |
| L_{b562} | H | Rₚ₁₂ | Rₚ₁ | H | H | Rₚ₁ | Rₚ₁ | H |
| L_{b563} | H | Rₚ₁₃ | Rₚ₁ | H | H | Rₚ₁ | Rₚ₁ | H |
| L_{b564} | H | Rₚ₁₄ | Rₚ₁ | H | H | Rₚ₁ | Rₚ₁ | H |
| L_{b565} | H | Rₚ₁₅ | Rₚ₁ | H | H | Rₚ₁ | Rₚ₁ | H |
| L_{b566} | H | Rₚ₁₆ | Rₚ₁ | H | H | Rₚ₁ | Rₚ₁ | H |
| L_{b567} | H | Rₚ₁₇ | Rₚ₁ | H | H | Rₚ₁ | Rₚ₁ | H |
| L_{b568} | H | Rₚ₁₈ | Rₚ₁ | H | H | Rₚ₁ | Rₚ₁ | H |
| L_{b569} | H | Rₚ₁₉ | Rₚ₁ | H | H | Rₚ₁ | Rₚ₁ | H |
| L_{b570} | H | Rₚ₂₁ | Rₚ₂₀ | H | H | Rₚ₂₀ | Rₚ₂₀ | H |
| L_{b571} | H | Rₚ₂₂ | Rₚ₂₀ | H | H | Rₚ₂₀ | Rₚ₂₀ | H |
| L_{b572} | H | Rₚ₂₃ | Rₚ₂₀ | H | H | Rₚ₂₀ | Rₚ₂₀ | H |
| L_{b573} | H | Rₚ₂₄ | Rₚ₂₀ | H | H | Rₚ₂₀ | Rₚ₂₀ | H |
| L_{b574} | H | Rₚ₂₅ | Rₚ₂₀ | H | H | Rₚ₂₀ | Rₚ₂₀ | H |
| L_{b575} | H | Rₚ₂₆ | Rₚ₂₀ | H | H | Rₚ₂₀ | Rₚ₂₀ | H |
| L_{b576} | H | Rₚ₂₇ | Rₚ₂₀ | H | H | Rₚ₂₀ | Rₚ₂₀ | H |
| L_{b577} | H | Rₚ₂₈ | Rₚ₂₀ | H | H | Rₚ₂₀ | Rₚ₂₀ | H |
| L_{b578} | H | Rₚ₂₉ | Rₚ₂₀ | H | H | Rₚ₂₀ | Rₚ₂₀ | H |
| L_{b579} | H | Rₚ₃₀ | Rₚ₂₀ | H | H | Rₚ₂₀ | Rₚ₂₀ | H |
| L_{b580} | H | Rₚ₁ | Rₚ₁ | H | H | Rₚ₁ | Rₚ₂ | H |
| L_{b581} | H | Rₚ₁ | Rₚ₁ | H | H | Rₚ₁ | Rₚ₃ | H |
| L_{b582} | H | Rₚ₁ | Rₚ₁ | H | H | Rₚ₁ | Rₚ₄ | H |
| L_{b583} | H | Rₚ₁ | Rₚ₁ | H | H | Rₚ₁ | Rₚ₅ | H |
| L_{b584} | H | Rₚ₁ | Rₚ₁ | H | H | Rₚ₁ | Rₚ₆ | H |
| L_{b585} | H | Rₚ₁ | Rₚ₁ | H | H | Rₚ₁ | Rₚ₇ | H |
| L_{b586} | H | Rₚ₁ | Rₚ₁ | H | H | Rₚ₁ | Rₚ₈ | H |
| L_{b587} | H | Rₚ₁ | Rₚ₁ | H | H | Rₚ₁ | Rₚ₉ | H |
| L_{b588} | H | Rₚ₁ | Rₚ₁ | H | H | Rₚ₁ | Rₚ₁₀ | H |
| L_{b589} | H | Rₚ₁ | Rₚ₁ | H | H | Rₚ₁ | Rₚ₁₁ | H |
| L_{b590} | H | Rₚ₁ | Rₚ₁ | H | H | Rₚ₁ | Rₚ₁₂ | H |
| L_{b591} | H | Rₚ₁ | Rₚ₁ | H | H | Rₚ₁ | Rₚ₁₃ | H |
| L_{b592} | H | Rₚ₁ | Rₚ₁ | H | H | Rₚ₁ | Rₚ₁₄ | H |
| L_{b593} | H | Rₚ₁ | Rₚ₁ | H | H | Rₚ₁ | Rₚ₁₅ | H |
| L_{b594} | H | Rₚ₁ | Rₚ₁ | H | H | Rₚ₁ | Rₚ₁₆ | H |
| L_{b595} | H | Rₚ₁ | Rₚ₁ | H | H | Rₚ₁ | Rₚ₁₇ | H |
| L_{b596} | H | Rₚ₁ | Rₚ₁ | H | H | Rₚ₁ | Rₚ₁₈ | H |
| L_{b597} | H | Rₚ₁ | Rₚ₁ | H | H | Rₚ₁ | Rₚ₁₉ | H |
| L_{b598} | H | Rₚ₂₀ | Rₚ₂₀ | H | H | Rₚ₂₀ | Rₚ₂₁ | H |
| L_{b599} | H | Rₚ₂₀ | Rₚ₂₀ | H | H | Rₚ₂₀ | Rₚ₂₂ | H |
| L_{b600} | H | Rₚ₂₀ | Rₚ₂₀ | H | H | Rₚ₂₀ | Rₚ₂₃ | H |
| L_{b601} | H | Rₚ₂₀ | Rₚ₂₀ | H | H | Rₚ₂₀ | Rₚ₂₄ | H |
| L_{b602} | H | Rₚ₂₀ | Rₚ₂₀ | H | H | Rₚ₂₀ | Rₚ₂₅ | H |
| L_{b603} | H | Rₚ₂₀ | Rₚ₂₀ | H | H | Rₚ₂₀ | Rₚ₂₆ | H |
| L_{b604} | H | Rₚ₂₀ | Rₚ₂₀ | H | H | Rₚ₂₀ | Rₚ₂₇ | H |
| L_{b605} | H | Rₚ₂₀ | Rₚ₂₀ | H | H | Rₚ₂₀ | Rₚ₂₈ | H |
| L_{b606} | H | Rₚ₂₀ | Rₚ₂₀ | H | H | Rₚ₂₀ | Rₚ₂₉ | H |
| L_{b607} | H | Rₚ₂₀ | Rₚ₂₀ | H | H | Rₚ₂₀ | Rₚ₃₀ | H |
| L_{b608} | H | Rₚ₁ | Rₚ₁ | H | H | Rₚ₂ | Rₚ₁ | H |
| L_{b609} | H | Rₚ₁ | Rₚ₁ | H | H | Rₚ₃ | Rₚ₁ | H |
| L_{b610} | H | Rₚ₁ | Rₚ₁ | H | H | Rₚ₄ | Rₚ₁ | H |
| L_{b611} | H | Rₚ₁ | Rₚ₁ | H | H | Rₚ₅ | Rₚ₁ | H |
| L_{b612} | H | Rₚ₁ | Rₚ₁ | H | H | Rₚ₆ | Rₚ₁ | H |
| L_{b613} | H | Rₚ₁ | Rₚ₁ | H | H | Rₚ₇ | Rₚ₁ | H |
| L_{b614} | H | Rₚ₁ | Rₚ₁ | H | H | Rₚ₈ | Rₚ₁ | H |
| L_{b615} | H | Rₚ₁ | Rₚ₁ | H | H | Rₚ₉ | Rₚ₁ | H |
| L_{b616} | H | Rₚ₁ | Rₚ₁ | H | H | Rₚ₁₀ | Rₚ₁ | H |
| L_{b617} | H | Rₚ₁ | Rₚ₁ | H | H | Rₚ₁₁ | Rₚ₁ | H |
| L_{b618} | H | Rₚ₁ | Rₚ₁ | H | H | Rₚ₁₂ | Rₚ₁ | H |
| L_{b619} | H | Rₚ₁ | Rₚ₁ | H | H | Rₚ₁₃ | Rₚ₁ | H |
| L_{b620} | H | Rₚ₁ | Rₚ₁ | H | H | Rₚ₁₄ | Rₚ₁ | H |
| L_{b621} | H | Rₚ₁ | Rₚ₁ | H | H | Rₚ₁₅ | Rₚ₁ | H |
| L_{b622} | H | Rₚ₁ | Rₚ₁ | H | H | Rₚ₁₆ | Rₚ₁ | H |
| L_{b623} | H | Rₚ₁ | Rₚ₁ | H | H | Rₚ₁₇ | Rₚ₁ | H |
| L_{b624} | H | Rₚ₁ | Rₚ₁ | H | H | Rₚ₁₈ | Rₚ₁ | H |
| L_{b625} | H | Rₚ₁ | Rₚ₁ | H | H | Rₚ₁₉ | Rₚ₁ | H |
| L_{b626} | H | Rₚ₂₀ | Rₚ₂₀ | H | H | Rₚ₂₁ | Rₚ₂₀ | H |
| L_{b627} | H | Rₚ₂₀ | Rₚ₂₀ | H | H | Rₚ₂₂ | Rₚ₂₀ | H |
| L_{b628} | H | Rₚ₂₀ | Rₚ₂₀ | H | H | Rₚ₂₃ | Rₚ₂₀ | H |
| L_{b629} | H | Rₚ₂₀ | Rₚ₂₀ | H | H | Rₚ₂₄ | Rₚ₂₀ | H |
| L_{b630} | H | Rₚ₂₀ | Rₚ₂₀ | H | H | Rₚ₂₅ | Rₚ₂₀ | H |
| L_{b631} | H | Rₚ₂₀ | Rₚ₂₀ | H | H | Rₚ₂₆ | Rₚ₂₀ | H |
| L_{b632} | H | Rₚ₂₀ | Rₚ₂₀ | H | H | Rₚ₂₇ | Rₚ₂₀ | H |
| L_{b633} | H | Rₚ₂₀ | Rₚ₂₀ | H | H | Rₚ₂₈ | Rₚ₂₀ | H |
| L_{b634} | H | Rₚ₂₀ | Rₚ₂₀ | H | H | Rₚ₂₉ | Rₚ₂₀ | H |
| L_{b635} | H | Rₚ₂₀ | Rₚ₂₀ | H | H | Rₚ₃₀ | Rₚ₂₀ | H |
| L_{b636} | H | Rₚ₁ | Rₚ₂ | H | H | Rₚ₁ | Rₚ₂ | H |
| L_{b637} | H | Rₚ₁ | Rₚ₃ | H | H | Rₚ₁ | Rₚ₃ | H |
| L_{b638} | H | Rₚ₁ | Rₚ₄ | H | H | Rₚ₁ | Rₚ₄ | H |
| L_{b639} | H | Rₚ₁ | Rₚ₅ | H | H | Rₚ₁ | Rₚ₅ | H |
| L_{b640} | H | Rₚ₁ | Rₚ₆ | H | H | Rₚ₁ | Rₚ₆ | H |
| L_{b641} | H | Rₚ₁ | Rₚ₇ | H | H | Rₚ₁ | Rₚ₇ | H |
| L_{b642} | H | Rₚ₁ | Rₚ₈ | H | H | Rₚ₁ | Rₚ₈ | H |
| L_{b643} | H | Rₚ₁ | Rₚ₉ | H | H | Rₚ₁ | Rₚ₉ | H |
| L_{b644} | H | Rₚ₁ | Rₚ₁₀ | H | H | Rₚ₁ | Rₚ₁₀ | H |
| L_{b645} | H | Rₚ₁ | Rₚ₁₁ | H | H | Rₚ₁ | Rₚ₁₁ | H |
| L_{b646} | H | Rₚ₁ | Rₚ₁₂ | H | H | Rₚ₁ | Rₚ₁₂ | H |
| L_{b647} | H | Rₚ₁ | Rₚ₁₃ | H | H | Rₚ₁ | Rₚ₁₃ | H |
| L_{b648} | H | Rₚ₁ | Rₚ₁₄ | H | H | Rₚ₁ | Rₚ₁₄ | H |
| L_{b649} | H | Rₚ₁ | Rₚ₁₅ | H | H | Rₚ₁ | Rₚ₁₅ | H |
| L_{b650} | H | Rₚ₁ | Rₚ₁₆ | H | H | Rₚ₁ | Rₚ₁₆ | H |
| L_{b651} | H | Rₚ₁ | Rₚ₁₇ | H | H | Rₚ₁ | Rₚ₁₇ | H |
| L_{b652} | H | Rₚ₁ | Rₚ₁₈ | H | H | Rₚ₁ | Rₚ₁₈ | H |
| L_{b653} | H | Rₚ₁ | Rₚ₁₉ | H | H | Rₚ₁ | Rₚ₁₉ | H |
| L_{b654} | H | Rₚ₂₀ | Rₚ₂₀ | H | H | Rₚ₂₀ | Rₚ₂₀ | H |
| L_{b655} | H | Rₚ₂₀ | Rₚ₂₁ | H | H | Rₚ₂₀ | Rₚ₂₁ | H |
| L_{b656} | H | Rₚ₂₀ | Rₚ₂₂ | H | H | Rₚ₂₀ | Rₚ₂₂ | H |
| L_{b657} | H | Rₚ₂₀ | Rₚ₂₃ | H | H | Rₚ₂₀ | Rₚ₂₃ | H |
| L_{b658} | H | Rₚ₂₀ | Rₚ₂₄ | H | H | Rₚ₂₀ | Rₚ₂₄ | H |
| L_{b659} | H | Rₚ₂₀ | Rₚ₂₅ | H | H | Rₚ₂₀ | Rₚ₂₅ | H |
| L_{b660} | H | Rₚ₂₀ | Rₚ₂₆ | H | H | Rₚ₂₀ | Rₚ₂₆ | H |
| L_{b661} | H | Rₚ₂₀ | Rₚ₂₇ | H | H | Rₚ₂₀ | Rₚ₂₇ | H |
| L_{b662} | H | Rₚ₂₀ | Rₚ₂₈ | H | H | Rₚ₂₀ | Rₚ₂₈ | H |
| L_{b663} | H | Rₚ₂₀ | Rₚ₂₉ | H | H | Rₚ₂₀ | Rₚ₂₉ | H |
| L_{b664} | H | Rₚ₂₀ | Rₚ₃₀ | H | H | Rₚ₂₀ | Rₚ₃₀ | H |
| L_{b665} | H | Rₚ₁ | Rₚ₂ | H | H | Rₚ₂ | Rₚ₁ | H |
| L_{b666} | H | Rₚ₁ | Rₚ₃ | H | H | Rₚ₃ | Rₚ₁ | H |
| L_{b667} | H | Rₚ₁ | Rₚ₄ | H | H | Rₚ₄ | Rₚ₁ | H |
| L_{b668} | H | Rₚ₁ | Rₚ₅ | H | H | Rₚ₅ | Rₚ₁ | H |
| L_{b669} | H | Rₚ₁ | Rₚ₆ | H | H | Rₚ₆ | Rₚ₁ | H |
| L_{b670} | H | Rₚ₁ | Rₚ₇ | H | H | Rₚ₇ | Rₚ₁ | H |
| L_{b671} | H | Rₚ₁ | Rₚ₈ | H | H | Rₚ₈ | Rₚ₁ | H |
| L_{b672} | H | Rₚ₁ | Rₚ₉ | H | H | Rₚ₉ | Rₚ₁ | H |
| L_{b673} | H | Rₚ₁ | Rₚ₁₀ | H | H | Rₚ₁₀ | Rₚ₁ | H |
| L_{b674} | H | Rₚ₁ | Rₚ₁₁ | H | H | Rₚ₁₁ | Rₚ₁ | H |
| L_{b675} | H | Rₚ₁ | Rₚ₁₂ | H | H | Rₚ₁₂ | Rₚ₁ | H |
| L_{b676} | H | Rₚ₁ | Rₚ₁₃ | H | H | Rₚ₁₃ | Rₚ₁ | H |
| L_{b677} | H | Rₚ₁ | Rₚ₁₄ | H | H | Rₚ₁₄ | Rₚ₁ | H |
| L_{b678} | H | Rₚ₁ | Rₚ₁₅ | H | H | Rₚ₁₅ | Rₚ₁ | H |
| L_{b679} | H | Rₚ₁ | Rₚ₁₆ | H | H | Rₚ₁₆ | Rₚ₁ | H |
| L_{b680} | H | Rₚ₁ | Rₚ₁₇ | H | H | Rₚ₁₇ | Rₚ₁ | H |
| L_{b681} | H | Rₚ₁ | Rₚ₁₈ | H | H | Rₚ₁₈ | Rₚ₁ | H |
| L_{b682} | H | Rₚ₁ | Rₚ₁₉ | H | H | Rₚ₁₉ | Rₚ₁ | H |
| L_{b683} | H | Rₚ₂₀ | Rₚ₂₀ | H | H | Rₚ₂₀ | Rₚ₂₀ | H |
| L_{b684} | H | Rₚ₂₀ | Rₚ₂₁ | H | H | Rₚ₂₁ | Rₚ₂₀ | H |
| L_{b685} | H | Rₚ₂₀ | Rₚ₂₂ | H | H | Rₚ₂₂ | Rₚ₂₀ | H |
| L_{b686} | H | Rₚ₂₀ | Rₚ₂₃ | H | H | Rₚ₂₃ | Rₚ₂₀ | H |
| L_{b687} | H | Rₚ₂₀ | Rₚ₂₄ | H | H | Rₚ₂₄ | Rₚ₂₀ | H |
| L_{b688} | H | Rₚ₂₀ | Rₚ₂₅ | H | H | Rₚ₂₅ | Rₚ₂₀ | H |
| L_{b689} | H | Rₚ₂₀ | Rₚ₂₆ | H | H | Rₚ₂₆ | Rₚ₂₀ | H |
| L_{b690} | H | Rₚ₂₀ | Rₚ₂₇ | H | H | Rₚ₂₇ | Rₚ₂₀ | H |
| L_{b691} | H | Rₚ₂₀ | Rₚ₂₈ | H | H | Rₚ₂₈ | Rₚ₂₀ | H |
| L_{b692} | H | Rₚ₂₀ | Rₚ₂₉ | H | H | Rₚ₂₉ | Rₚ₂₀ | H |
| L_{b693} | H | Rₚ₂₀ | Rₚ₃₀ | H | H | Rₚ₃₀ | Rₚ₂₀ | H |
| L_{b694} | H | Rₚ₂ | Rₚ₁ | H | H | Rₚ₁ | Rₚ₂ | H |
| L_{b695} | H | Rₚ₃ | Rₚ₁ | H | H | Rₚ₁ | Rₚ₃ | H |
| L_{b696} | H | Rₚ₄ | Rₚ₁ | H | H | Rₚ₁ | Rₚ₄ | H |
| L_{b697} | H | Rₚ₅ | Rₚ₁ | H | H | Rₚ₁ | Rₚ₅ | H |
| L_{b698} | H | Rₚ₆ | Rₚ₁ | H | H | Rₚ₁ | Rₚ₆ | H |
| L_{b699} | H | Rₚ₇ | Rₚ₁ | H | H | Rₚ₁ | Rₚ₇ | H |
| L_{b700} | H | Rₚ₈ | Rₚ₁ | H | H | Rₚ₁ | Rₚ | H |
| L_{b701} | H | Rₚ₉ | Rₚ₁ | H | H | Rₚ₁ | Rₚ₉ | H |
| L_{b702} | H | Rₚ₁₀ | Rₚ₁ | H | H | Rₚ₁ | Rₚ₁₀ | H |
| L_{b703} | H | Rₚ₁₁ | Rₚ₁ | H | H | Rₚ₁ | Rₚ₁₁ | H |
| L_{b704} | H | Rₚ₁₂ | Rₚ₁ | H | H | Rₚ₁ | Rₚ₁₂ | H |
| L_{b705} | H | Rₚ₁₃ | Rₚ₁ | H | H | Rₚ₁ | Rₚ₁₃ | H |
| L_{b706} | H | Rₚ₁₄ | Rₚ₁ | H | H | Rₚ₁ | Rₚ₁₄ | H |
| L_{b707} | H | Rₚ₁₅ | Rₚ₁ | H | H | Rₚ₁ | Rₚ₁₅ | H |
| L_{b708} | H | Rₚ₁₆ | Rₚ₁ | H | H | Rₚ₁ | Rₚ₁₆ | H |
| L_{b709} | H | Rₚ₁₇ | Rₚ₁ | H | H | Rₚ₁ | Rₚ₁₇ | H |
| L_{b710} | H | Rₚ₁₈ | Rₚ₁ | H | H | Rₚ₁ | Rₚ₁₈ | H |
| L_{b711} | H | Rₚ₁₉ | Rₚ₁ | H | H | Rₚ₁ | Rₚ₁₉ | H |
| L_{b712} | H | Rₚ₂₀ | Rₚ₂₀ | H | H | Rₚ₂₀ | Rₚ₂₀ | H |
| L_{b713} | H | Rₚ₂₁ | Rₚ₂₀ | H | H | Rₚ₂₀ | Rₚ₂₁ | H |
| L_{b714} | H | Rₚ₂₂ | Rₚ₂₀ | H | H | Rₚ₂₀ | Rₚ₂₂ | H |
| L_{b715} | H | Rₚ₂₃ | Rₚ₂₀ | H | H | Rₚ₂₀ | Rₚ₂₃ | H |
| L_{b716} | H | Rₚ₂₄ | Rₚ₂₀ | H | H | Rₚ₂₀ | Rₚ₂₄ | H |
| L_{b717} | H | Rₚ₂₅ | Rₚ₂₀ | H | H | Rₚ₂₀ | Rₚ₂₅ | H |
| L_{b718} | H | Rₚ₂₆ | Rₚ₂₀ | H | H | Rₚ₂₀ | Rₚ₂₆ | H |
| L_{b719} | H | Rₚ₂₇ | Rₚ₂₀ | H | H | Rₚ₂₀ | Rₚ₂₇ | H |
| L_{b720} | H | Rₚ₂₈ | Rₚ₂₀ | H | H | Rₚ₂₀ | Rₚ₂₈ | H |
| L_{b721} | H | Rₚ₂₉ | Rₚ₂₀ | H | H | Rₚ₂₀ | Rₚ₂₉ | H |
| L_{b722} | H | Rₚ₃₀ | Rₚ₂₀ | H | H | Rₚ₂₀ | Rₚ₃₀ | H |
| L_{b723} | H | Rₚ₂ | Rₚ₁ | H | H | Rₚ₂ | Rₚ₁ | H |
| L_{b724} | H | Rₚ₃ | Rₚ₁ | H | H | Rₚ₃ | Rₚ₁ | H |
| L_{b725} | H | Rₚ₄ | Rₚ₁ | H | H | Rₚ₄ | Rₚ₁ | H |
| L_{b726} | H | Rₚ₅ | Rₚ₁ | H | H | Rₚ₅ | Rₚ₁ | H |
| L_{b727} | H | Rₚ₆ | Rₚ₁ | H | H | Rₚ₆ | Rₚ₁ | H |
| L_{b728} | H | Rₚ₇ | Rₚ₁ | H | H | Rₚ₇ | Rₚ₁ | H |
| L_{b729} | H | Rₚ₈ | Rₚ₁ | H | H | Rₚ₈ | Rₚ₁ | H |
| L_{b730} | H | Rₚ₉ | Rₚ₁ | H | H | Rₚ₉ | Rₚ₁ | H |
| L_{b731} | H | Rₚ₁₀ | Rₚ₁ | H | H | Rₚ₁₀ | Rₚ₁ | H |
| L_{b732} | H | Rₚ₁₁ | Rₚ₁ | H | H | Rₚ₁₁ | Rₚ₁ | H |
| L_{b733} | H | Rₚ₁₂ | Rₚ₁ | H | H | Rₚ₁₂ | Rₚ₁ | H |
| L_{b734} | H | Rₚ₁₃ | Rₚ₁ | H | H | Rₚ₁₃ | Rₚ₁ | H |
| L_{b735} | H | Rₚ₁₄ | Rₚ₁ | H | H | Rₚ₁₄ | Rₚ₁ | H |
| L_{b736} | H | Rₚ₁₅ | Rₚ₁ | H | H | Rₚ₁₅ | Rₚ₁ | H |
| L_{b737} | H | Rₚ₁₆ | Rₚ₁ | H | H | Rₚ₁₆ | Rₚ₁ | H |
| L_{b738} | H | Rₚ₁₇ | Rₚ₁ | H | H | Rₚ₁₇ | Rₚ₁ | H |
| L_{b739} | H | Rₚ₁₈ | Rₚ₁ | H | H | Rₚ₁₈ | Rₚ₁ | H |
| L_{b740} | H | Rₚ₁₉ | Rₚ₁ | H | H | Rₚ₁₉ | Rₚ₁ | H |
| L_{b741} | H | Rₚ₂₀ | Rₚ₂₀ | H | H | Rₚ₂₀ | Rₚ₂₀ | H |
| L_{b742} | H | Rₚ₂₁ | Rₚ₂₀ | H | H | Rₚ₂₁ | Rₚ₂₀ | H |
| L_{b743} | H | Rₚ₂₂ | Rₚ₂₀ | H | H | Rₚ₂₂ | Rₚ₂₀ | H |
| L_{b744} | H | Rₚ₂₃ | Rₚ₂₀ | H | H | Rₚ₂₃ | Rₚ₂₀ | H |
| L_{b745} | H | Rₚ₂₄ | Rₚ₂₀ | H | H | Rₚ₂₄ | Rₚ₂₀ | H |
| L_{b746} | H | Rₚ₂₅ | Rₚ₂₀ | H | H | Rₚ₂₅ | Rₚ₂₀ | H |
| L_{b747} | H | Rₚ₂₆ | Rₚ₂₀ | H | H | Rₚ₂₆ | Rₚ₂₀ | H |
| L_{b748} | H | Rₚ₂₇ | Rₚ₂₀ | H | H | Rₚ₂₇ | Rₚ₂₀ | H |
| L_{b749} | H | Rₚ₂₈ | Rₚ₂₀ | H | H | Rₚ₂₈ | Rₚ₂₀ | H |
| L_{b750} | H | Rₚ₂₉ | Rₚ₂₀ | H | H | Rₚ₂₉ | Rₚ₂₀ | H |
| L_{b751} | H | Rₚ₃₀ | Rₚ₂₀ | H | H | Rₚ₃₀ | Rₚ₂₀ | H |

wherein Rₚ₁ to Rₚ₃₀ have the following structures: 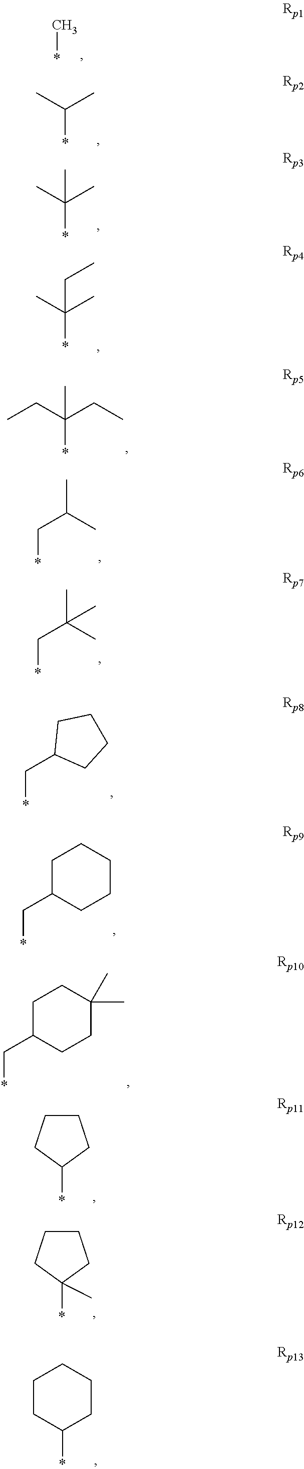 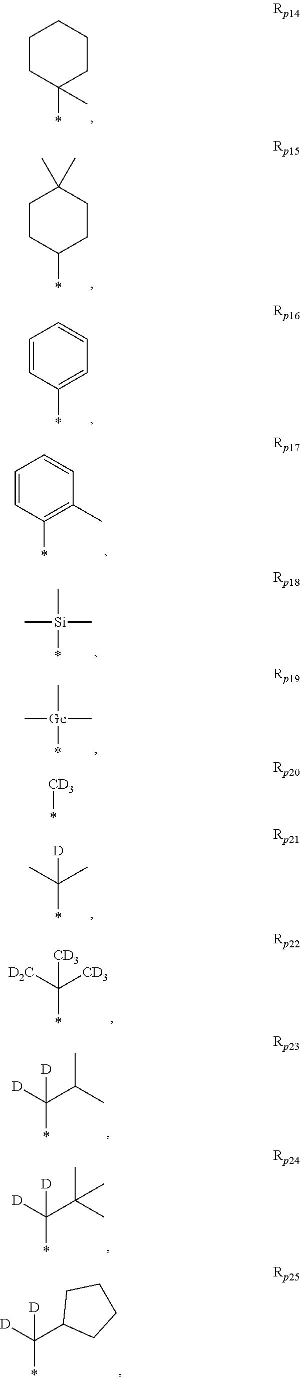 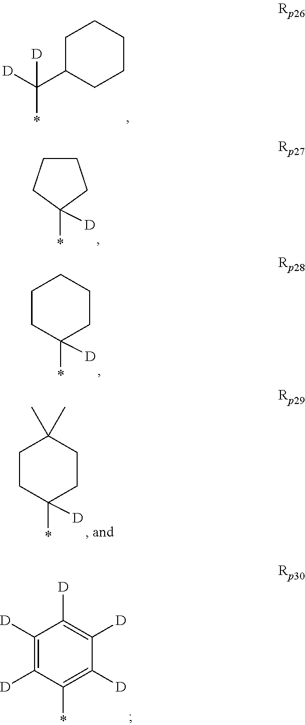
wherein “*” in Rₚ₁ to Rₚ₃₀ represents to the position of attachment to Formula 3; optionally, hydrogens in ligands L_{b1} to L_{b751} can be partially or completely substituted with deuterium.

16. The metal complex of claim 15, wherein the metal complex is selected from the group consisting of metal complex 1-1 to metal complex 1938-1, metal complex 1-2 to metal complex 1938-2, metal complex 1-3 to metal complex 1938-3, metal complex 1-4 to metal complex 1938-4, metal complex 1-5 to metal complex 1938-5, metal complex 1-6 to metal complex 1938-6, and metal complex 1-7 to metal complex 40-7;
wherein metal complex 1-1 to metal complex 1938-1 are represented by h-1: Ir(Lₐ₋₁₋ₖ)(L_{b})₂;
metal complex 1-2 to metal complex 1938-2 are represented by h-2: Ir(Lₐ₋₂₋ₖ)(L_{b})₂;
metal complex 1-3 to metal complex 1938-3 are represented by h-3: Ir(Lₐ₋₃₋ₖ)(L_{b})₂;
metal complex 1-4 to metal complex 1938-4 are represented by h-4: Ir(Lₐ₋₄₋ₖ)(L_{b})₂;
metal complex 1-5 to metal complex 1938-5 are represented by h-5: Ir(Lₐ₋₅₋ₖ)(L_{b})₂;
metal complex 1-6 to metal complex 1938-6 are represented by h-6: Ir(Lₐ₋₆₋ₖ)(L_{b})₂;
wherein h, k, and L_{b} correspond to the structures in the following table, respectively:

| h | k | L_{b} | h | k | L_{b} | h | k | L_{b} |
|---|---|---|---|---|---|---|---|---|
| 1 | 1 | L_{b1} | 2 | 7 | L_{b1} | 3 | 11 | L_{b1} |
| 4 | 21 | L_{b1} | 5 | 49 | L_{b1} | 6 | 63 | L_{b1} |
| 7 | 105 | L_{b1} | 8 | 106 | L_{b1} | 9 | 107 | L_{b1} |
| 10 | 110 | L_{b1} | 11 | 130 | L_{b1} | 12 | 131 | L_{b1} |
| 13 | 136 | L_{b1} | 14 | 140 | L_{b1} | 15 | 150 | L_{b1} |
| 16 | 152 | L_{b1} | 17 | 157 | L_{b1} | 18 | 161 | L_{b1} |
| 19 | 168 | L_{b1} | 20 | 196 | L_{b1} | 21 | 201 | L_{b1} |
| 22 | 207 | L_{b1} | 23 | 228 | L_{b1} | 24 | 267 | L_{b1} |
| 25 | 272 | L_{b1} | 26 | 278 | L_{b1} | 27 | 299 | L_{b1} |
| 28 | 311 | L_{b1} | 29 | 338 | L_{b1} | 30 | 343 | L_{b1} |
| 31 | 349 | L_{b1} | 32 | 370 | L_{b1} | 33 | 409 | L_{b1} |
| 34 | 414 | L_{b1} | 35 | 420 | L_{b1} | 36 | 441 | L_{b1} |
| 37 | 480 | L_{b1} | 38 | 490 | L_{b1} | 39 | 511 | L_{b1} |
| 40 | 522 | L_{b1} | 41 | 550 | L_{b1} | 42 | 560 | L_{b1} |
| 43 | 581 | L_{b1} | 44 | 593 | L_{b1} | 45 | 620 | L_{b1} |
| 46 | 626 | L_{b1} | 47 | 648 | L_{b1} | 48 | 659 | L_{b1} |
| 49 | 746 | L_{b1} | 50 | 747 | L_{b1} | 51 | 749 | L_{b1} |
| 52 | 1 | L_{b2} | 53 | 7 | L_{b2} | 54 | 11 | L_{b2} |
| 55 | 21 | L_{b2} | 56 | 49 | L_{b2} | 57 | 63 | L_{b2} |
| 58 | 105 | L_{b2} | 59 | 106 | L_{b2} | 60 | 107 | L_{b2} |
| 61 | 110 | L_{b2} | 62 | 130 | L_{b2} | 63 | 131 | L_{b2} |
| 64 | 136 | L_{b2} | 65 | 140 | L_{b2} | 66 | 150 | L_{b2} |
| 67 | 152 | L_{b2} | 68 | 157 | L_{b2} | 69 | 161 | L_{b2} |
| 70 | 168 | L_{b2} | 71 | 196 | L_{b2} | 72 | 201 | L_{b2} |
| 73 | 207 | L_{b2} | 74 | 228 | L_{b2} | 75 | 267 | L_{b2} |
| 76 | 272 | L_{b2} | 77 | 278 | L_{b2} | 78 | 299 | L_{b2} |
| 79 | 311 | L_{b2} | 80 | 338 | L_{b2} | 81 | 343 | L_{b2} |
| 82 | 349 | L_{b2} | 83 | 370 | L_{b2} | 84 | 409 | L_{b2} |
| 85 | 414 | L_{b2} | 86 | 420 | L_{b2} | 87 | 441 | L_{b2} |
| 88 | 480 | L_{b2} | 89 | 490 | L_{b2} | 90 | 511 | L_{b2} |
| 91 | 522 | L_{b2} | 92 | 550 | L_{b2} | 93 | 560 | L_{b2} |
| 94 | 581 | L_{b2} | 95 | 593 | L_{b2} | 96 | 620 | L_{b2} |
| 97 | 626 | L_{b2} | 98 | 648 | L_{b2} | 99 | 659 | L_{b2} |
| 100 | 746 | L_{b2} | 101 | 747 | L_{b2} | 102 | 749 | L_{b2} |
| 103 | 1 | L_{b3} | 104 | 7 | L_{b3} | 105 | 11 | L_{b3} |
| 106 | 21 | L_{b3} | 107 | 49 | L_{b3} | 108 | 63 | L_{b3} |
| 109 | 105 | L_{b3} | 110 | 106 | L_{b3} | 111 | 107 | L_{b3} |
| 112 | 110 | L_{b3} | 113 | 130 | L_{b3} | 114 | 131 | L_{b3} |
| 115 | 136 | L_{b3} | 116 | 140 | L_{b3} | 117 | 150 | L_{b3} |
| 118 | 152 | L_{b3} | 119 | 157 | L_{b3} | 120 | 161 | L_{b3} |
| 121 | 168 | L_{b3} | 122 | 196 | L_{b3} | 123 | 201 | L_{b3} |
| 124 | 207 | L_{b3} | 125 | 228 | L_{b3} | 126 | 267 | L_{b3} |
| 127 | 272 | L_{b3} | 128 | 278 | L_{b3} | 129 | 299 | L_{b3} |
| 130 | 311 | L_{b3} | 131 | 338 | L_{b3} | 132 | 343 | L_{b3} |
| 133 | 349 | L_{b3} | 134 | 370 | L_{b3} | 135 | 409 | L_{b3} |
| 136 | 414 | L_{b3} | 137 | 420 | L_{b3} | 138 | 441 | L_{b3} |
| 139 | 480 | L_{b3} | 140 | 490 | L_{b3} | 141 | 511 | L_{b3} |
| 142 | 522 | L_{b3} | 143 | 550 | L_{b3} | 144 | 560 | L_{b3} |
| 145 | 581 | L_{b3} | 146 | 593 | L_{b3} | 147 | 620 | L_{b3} |
| 148 | 626 | L_{b3} | 149 | 648 | L_{b3} | 150 | 659 | L_{b3} |
| 151 | 746 | L_{b3} | 152 | 747 | L_{b3} | 153 | 749 | L_{b3} |
| 154 | 1 | L_{b32} | 155 | 7 | L_{b32} | 156 | 11 | L_{b32} |
| 157 | 21 | L_{b32} | 158 | 49 | L_{b32} | 159 | 63 | L_{b32} |
| 160 | 105 | L_{b32} | 161 | 106 | L_{b32} | 162 | 107 | L_{b32} |
| 163 | 110 | L_{b32} | 164 | 130 | L_{b32} | 165 | 131 | L_{b32} |
| 166 | 136 | L_{b32} | 167 | 140 | L_{b32} | 168 | 150 | L_{b32} |
| 169 | 152 | L_{b32} | 170 | 157 | L_{b32} | 171 | 161 | L_{b32} |
| 172 | 168 | L_{b32} | 173 | 196 | L_{b32} | 174 | 201 | L_{b32} |
| 175 | 207 | L_{b32} | 176 | 228 | L_{b32} | 177 | 267 | L_{b32} |
| 178 | 272 | L_{b32} | 179 | 278 | L_{b32} | 180 | 299 | L_{b32} |
| 181 | 311 | L_{b32} | 182 | 338 | L_{b32} | 183 | 343 | L_{b32} |
| 184 | 349 | L_{b32} | 185 | 370 | L_{b32} | 186 | 409 | L_{b32} |
| 187 | 414 | L_{b32} | 188 | 420 | L_{b32} | 189 | 44 | L_{b32} |
| 190 | 480 | L_{b32} | 191 | 490 | L_{b32} | 192 | 511 | L_{b32} |
| 193 | 522 | L_{b32} | 194 | 550 | L_{b32} | 195 | 560 | L_{b32} |
| 196 | 581 | L_{b32} | 197 | 593 | L_{b32} | 198 | 620 | L_{b32} |
| 199 | 626 | L_{b32} | 200 | 648 | L_{b32} | 201 | 659 | L_{b32} |
| 202 | 746 | L_{b32} | 203 | 747 | L_{b32} | 204 | 749 | L_{b32} |
| 205 | 1 | L_{b33} | 206 | 7 | L_{b33} | 207 | 11 | L_{b33} |
| 208 | 21 | L_{b33} | 209 | 49 | L_{b33} | 210 | 63 | L_{b33} |
| 211 | 105 | L_{b33} | 212 | 106 | L_{b33} | 213 | 107 | L_{b33} |
| 214 | 110 | L_{b33} | 215 | 130 | L_{b33} | 216 | 131 | L_{b33} |
| 217 | 136 | L_{b33} | 218 | 140 | L_{b33} | 219 | 150 | L_{b33} |
| 220 | 152 | L_{b33} | 221 | 157 | L_{b33} | 222 | 161 | L_{b33} |
| 223 | 168 | L_{b33} | 224 | 196 | L_{b33} | 225 | 201 | L_{b33} |
| 226 | 207 | L_{b33} | 227 | 228 | L_{b33} | 228 | 267 | L_{b33} |
| 229 | 272 | L_{b33} | 230 | 278 | L_{b33} | 231 | 299 | L_{b33} |
| 232 | 311 | L_{b33} | 233 | 338 | L_{b33} | 234 | 343 | L_{b33} |
| 235 | 349 | L_{b33} | 236 | 370 | L_{b33} | 237 | 409 | L_{b33} |
| 238 | 414 | L_{b33} | 239 | 420 | L_{b33} | 240 | 441 | L_{b33} |
| 241 | 480 | L_{b33} | 242 | 490 | L_{b33} | 243 | 511 | L_{b33} |
| 244 | 522 | L_{b33} | 245 | 550 | L_{b33} | 246 | 560 | L_{b33} |
| 247 | 581 | L_{b33} | 248 | 593 | L_{b33} | 249 | 620 | L_{b33} |
| 250 | 626 | L_{b33} | 251 | 648 | L_{b33} | 252 | 659 | L_{b33} |
| 253 | 746 | L_{b33} | 254 | 747 | L_{b33} | 255 | 749 | L_{b33} |
| 256 | 1 | L_{b34} | 257 | 7 | L_{b34} | 258 | 11 | L_{b34} |
| 259 | 21 | L_{b34} | 260 | 49 | L_{b34} | 261 | 63 | L_{b34} |
| 262 | 105 | L_{b34} | 263 | 106 | L_{b34} | 264 | 107 | L_{b34} |
| 265 | 110 | L_{b34} | 266 | 130 | L_{b34} | 267 | 131 | L_{b34} |
| 268 | 136 | L_{b34} | 269 | 140 | L_{b34} | 270 | 150 | L_{b34} |
| 271 | 152 | L_{b34} | 272 | 157 | L_{b34} | 273 | 161 | L_{b34} |
| 274 | 168 | L_{b34} | 275 | 196 | L_{b34} | 276 | 20 | L_{b34} |
| 277 | 207 | L_{b34} | 278 | 228 | L_{b34} | 279 | 267 | L_{b34} |
| 280 | 272 | L_{b34} | 281 | 278 | L_{b34} | 282 | 299 | L_{b34} |
| 283 | 311 | L_{b34} | 284 | 338 | L_{b34} | 285 | 343 | L_{b34} |
| 286 | 349 | L_{b34} | 287 | 370 | L_{b34} | 288 | 409 | L_{b34} |
| 289 | 414 | L_{b34} | 290 | 420 | L_{b34} | 291 | 441 | L_{b34} |
| 292 | 480 | L_{b34} | 293 | 490 | L_{b34} | 294 | 511 | L_{b34} |
| 295 | 522 | L_{b34} | 296 | 550 | L_{b34} | 297 | 560 | L_{b34} |
| 298 | 581 | L_{b34} | 299 | 593 | L_{b34} | 300 | 620 | L_{b34} |
| 301 | 626 | L_{b34} | 302 | 648 | L_{b34} | 303 | 659 | L_{b34} |
| 304 | 746 | L_{b34} | 305 | 747 | L_{b34} | 306 | 749 | L_{b34} |
| 307 | 1 | L_{b37} | 308 | 7 | L_{b37} | 309 | 11 | L_{b37} |
| 310 | 21 | L_{b37} | 311 | 49 | L_{b37} | 312 | 63 | L_{b37} |
| 313 | 105 | L_{b37} | 314 | 106 | L_{b37} | 315 | 107 | L_{b37} |
| 316 | 110 | L_{b37} | 317 | 130 | L_{b37} | 318 | 131 | L_{b37} |
| 319 | 136 | L_{b37} | 320 | 140 | L_{b37} | 321 | 150 | L_{b37} |
| 322 | 152 | L_{b37} | 323 | 157 | L_{b37} | 324 | 161 | L_{b37} |
| 325 | 168 | L_{b37} | 326 | 196 | L_{b37} | 327 | 201 | L_{b37} |
| 328 | 207 | L_{b37} | 329 | 228 | L_{b37} | 330 | 267 | L_{b37} |
| 331 | 272 | L_{b37} | 332 | 278 | L_{b37} | 333 | 299 | L_{b37} |
| 334 | 311 | L_{b37} | 335 | 338 | L_{b37} | 336 | 343 | L_{b37} |
| 337 | 349 | L_{b37} | 338 | 370 | L_{b37} | 339 | 409 | L_{b37} |
| 340 | 414 | L_{b37} | 341 | 420 | L_{b37} | 342 | 441 | L_{b37} |
| 343 | 480 | L_{b37} | 344 | 490 | L_{b37} | 345 | 511 | L_{b37} |
| 346 | 522 | L_{b37} | 347 | 550 | L_{b37} | 348 | 560 | L_{b37} |
| 349 | 581 | L_{b37} | 350 | 593 | L_{b37} | 351 | 620 | L_{b37} |
| 352 | 626 | L_{b37} | 353 | 648 | L_{b37} | 354 | 659 | L_{b37} |
| 355 | 746 | L_{b37} | 356 | 747 | L_{b37} | 357 | 749 | L_{b37} |
| 358 | 1 | L_{b38} | 359 | 7 | L_{b38} | 360 | 11 | L_{b38} |
| 361 | 21 | L_{b38} | 362 | 49 | L_{b38} | 363 | 63 | L_{b38} |
| 364 | 105 | L_{b38} | 365 | 106 | L_{b38} | 366 | 107 | L_{b38} |
| 367 | 110 | L_{b38} | 368 | 130 | L_{b38} | 369 | 131 | L_{b38} |
| 370 | 136 | L_{b38} | 371 | 140 | L_{b38} | 372 | 150 | L_{b38} |
| 373 | 152 | L_{b38} | 374 | 157 | L_{b38} | 375 | 161 | L_{b38} |
| 376 | 168 | L_{b38} | 377 | 196 | L_{b38} | 378 | 201 | L_{b38} |
| 379 | 207 | L_{b38} | 380 | 228 | L_{b38} | 381 | 267 | L_{b38} |
| 382 | 272 | L_{b38} | 383 | 278 | L_{b38} | 384 | 299 | L_{b38} |
| 385 | 311 | L_{b38} | 386 | 338 | L_{b38} | 387 | 343 | L_{b38} |
| 388 | 349 | L_{b38} | 389 | 370 | L_{b38} | 390 | 409 | L_{b38} |
| 391 | 414 | L_{b38} | 392 | 420 | L_{b38} | 393 | 441 | L_{b38} |
| 394 | 480 | L_{b38} | 395 | 490 | L_{b38} | 396 | 511 | L_{b38} |
| 397 | 522 | L_{b38} | 398 | 550 | L_{b38} | 399 | 560 | L_{b38} |
| 400 | 581 | L_{b38} | 401 | 593 | L_{b38} | 402 | 620 | L_{b38} |
| 403 | 626 | L_{b38} | 404 | 648 | L_{b38} | 405 | 659 | L_{b38} |
| 406 | 746 | L_{b38} | 407 | 747 | L_{b38} | 408 | 749 | L_{b38} |
| 409 | 1 | L_{b42} | 410 | 7 | L_{b42} | 411 | 11 | L_{b42} |
| 412 | 21 | L_{b42} | 413 | 49 | L_{b42} | 414 | 63 | L_{b42} |
| 415 | 105 | L_{b42} | 416 | 106 | L_{b42} | 417 | 107 | L_{b42} |
| 418 | 110 | L_{b42} | 419 | 130 | L_{b42} | 420 | 131 | L_{b42} |
| 42 | 136 | L_{b42} | 422 | 140 | L_{b42} | 423 | 150 | L_{b42} |
| 424 | 152 | L_{b42} | 425 | 157 | L_{b42} | 426 | 161 | L_{b42} |
| 427 | 168 | L_{b42} | 428 | 196 | L_{b42} | 429 | 201 | L_{b42} |
| 430 | 207 | L_{b42} | 431 | 228 | L_{b42} | 432 | 267 | L_{b42} |
| 433 | 272 | L_{b42} | 434 | 278 | L_{b42} | 435 | 299 | L_{b42} |
| 436 | 311 | L_{b42} | 437 | 338 | L_{b42} | 438 | 343 | L_{b42} |
| 439 | 349 | L_{b42} | 440 | 370 | L_{b42} | 441 | 409 | L_{b42} |
| 442 | 414 | L_{b42} | 443 | 420 | L_{b42} | 444 | 441 | L_{b42} |
| 445 | 480 | L_{b42} | 446 | 490 | L_{b42} | 447 | 511 | L_{b42} |
| 448 | 522 | L_{b42} | 449 | 550 | L_{b42} | 450 | 560 | L_{b42} |
| 451 | 581 | L_{b42} | 452 | 593 | L_{b42} | 453 | 620 | L_{b42} |
| 454 | 626 | L_{b42} | 455 | 648 | L_{b42} | 456 | 659 | L_{b42} |
| 457 | 746 | L_{b42} | 458 | 747 | L_{b42} | 459 | 749 | L_{b42} |
| 460 | 1 | L_{b43} | 461 | 7 | L_{b43} | 462 | 11 | L_{b43} |
| 463 | 21 | L_{b43} | 464 | 49 | L_{b43} | 465 | 63 | L_{b43} |
| 466 | 105 | L_{b43} | 467 | 106 | L_{b43} | 468 | 107 | L_{b43} |
| 469 | 110 | L_{b43} | 470 | 130 | L_{b43} | 471 | 131 | L_{b43} |
| 472 | 136 | L_{b43} | 473 | 140 | L_{b43} | 474 | 150 | L_{b43} |
| 475 | 152 | L_{b43} | 476 | 157 | L_{b43} | 477 | 161 | L_{b43} |
| 478 | 168 | L_{b43} | 479 | 196 | L_{b43} | 480 | 201 | L_{b43} |
| 481 | 207 | L_{b43} | 482 | 228 | L_{b43} | 483 | 267 | L_{b43} |
| 484 | 272 | L_{b43} | 485 | 278 | L_{b43} | 486 | 299 | L_{b43} |
| 487 | 311 | L_{b43} | 488 | 338 | L_{b43} | 489 | 343 | L_{b43} |
| 490 | 349 | L_{b43} | 491 | 370 | L_{b43} | 492 | 409 | L_{b43} |
| 493 | 414 | L_{b43} | 494 | 420 | L_{b43} | 495 | 441 | L_{b43} |
| 496 | 480 | L_{b43} | 497 | 490 | L_{b43} | 498 | 511 | L_{b43} |
| 499 | 522 | L_{b43} | 500 | 550 | L_{b43} | 501 | 560 | L_{b43} |
| 502 | 581 | L_{b43} | 503 | 593 | L_{b43} | 504 | 620 | L_{b43} |
| 505 | 626 | L_{b43} | 506 | 648 | L_{b43} | 507 | 659 | L_{b43} |
| 508 | 746 | L_{b43} | 509 | 747 | L_{b43} | 510 | 749 | L_{b43} |
| 511 | 1 | L_{b44} | 512 | 7 | L_{b44} | 513 | 11 | L_{b44} |
| 514 | 21 | L_{b44} | 515 | 49 | L_{b44} | 516 | 63 | L_{b44} |
| 517 | 105 | L_{b44} | 518 | 106 | L_{b44} | 519 | 107 | L_{b44} |
| 520 | 110 | L_{b44} | 521 | 130 | L_{b44} | 522 | 131 | L_{b44} |
| 523 | 136 | L_{b44} | 524 | 140 | L_{b44} | 525 | 150 | L_{b44} |
| 526 | 152 | L_{b44} | 527 | 157 | L_{b44} | 528 | 161 | L_{b44} |
| 529 | 168 | L_{b44} | 530 | 196 | L_{b44} | 531 | 201 | L_{b44} |
| 532 | 207 | L_{b44} | 533 | 228 | L_{b44} | 534 | 267 | L_{b44} |
| 535 | 272 | L_{b44} | 536 | 278 | L_{b44} | 537 | 299 | L_{b44} |
| 538 | 311 | L_{b44} | 539 | 338 | L_{b44} | 540 | 343 | L_{b44} |
| 541 | 349 | L_{b44} | 542 | 370 | L_{b44} | 543 | 409 | L_{b44} |
| 544 | 414 | L_{b44} | 545 | 420 | L_{b44} | 546 | 441 | L_{b44} |
| 547 | 480 | L_{b44} | 548 | 490 | L_{b44} | 549 | 511 | L_{b44} |
| 550 | 522 | L_{b44} | 551 | 550 | L_{b44} | 552 | 560 | L_{b44} |
| 553 | 581 | L_{b44} | 554 | 593 | L_{b44} | 555 | 620 | L_{b44} |
| 556 | 626 | L_{b44} | 557 | 648 | L_{b44} | 558 | 659 | L_{b44} |
| 559 | 746 | L_{b44} | 560 | 747 | L_{b44} | 561 | 749 | L_{b44} |
| 562 | 1 | L_{b45} | 563 | 7 | L_{b45} | 564 | 11 | L_{b45} |
| 565 | 21 | L_{b45} | 566 | 49 | L_{b45} | 567 | 63 | L_{b45} |
| 568 | 105 | L_{b45} | 569 | 106 | L_{b45} | 570 | 107 | L_{b45} |
| 571 | 110 | L_{b45} | 572 | 130 | L_{b45} | 573 | 131 | L_{b45} |
| 574 | 136 | L_{b45} | 575 | 140 | L_{b45} | 576 | 150 | L_{b45} |
| 577 | 152 | L_{b45} | 578 | 157 | L_{b45} | 579 | 161 | L_{b45} |
| 580 | 168 | L_{b45} | 581 | 196 | L_{b45} | 582 | 201 | L_{b45} |
| 583 | 207 | L_{b45} | 584 | 228 | L_{b45} | 585 | 267 | L_{b45} |
| 586 | 272 | L_{b45} | 587 | 278 | L_{b45} | 588 | 299 | L_{b45} |
| 589 | 311 | L_{b45} | 590 | 338 | L_{b45} | 591 | 343 | L_{b45} |
| 592 | 349 | L_{b45} | 593 | 370 | L_{b45} | 594 | 409 | L_{b45} |
| 595 | 414 | L_{b45} | 596 | 420 | L_{b45} | 597 | 441 | L_{b45} |
| 598 | 480 | L_{b45} | 599 | 490 | L_{b45} | 600 | 511 | L_{b45} |
| 601 | 522 | L_{b45} | 602 | 550 | L_{b45} | 603 | 560 | L_{b45} |
| 604 | 581 | L_{b45} | 605 | 593 | L_{b45} | 606 | 620 | L_{b45} |
| 607 | 626 | L_{b45} | 608 | 648 | L_{b45} | 609 | 659 | L_{b45} |
| 610 | 746 | L_{b45} | 611 | 747 | L_{b45} | 612 | 749 | L_{b45} |
| 613 | 1 | L_{b49} | 614 | 7 | L_{b49} | 615 | 11 | L_{b49} |
| 616 | 21 | L_{b49} | 617 | 49 | L_{b49} | 618 | 63 | L_{b49} |
| 619 | 105 | L_{b49} | 620 | 106 | L_{b49} | 621 | 107 | L_{b49} |
| 622 | 110 | L_{b49} | 623 | 130 | L_{b49} | 624 | 131 | L_{b49} |
| 625 | 136 | L_{b49} | 626 | 140 | L_{b49} | 627 | 150 | L_{b49} |
| 628 | 152 | L_{b49} | 629 | 157 | L_{b49} | 630 | 161 | L_{b49} |
| 631 | 168 | L_{b49} | 632 | 196 | L_{b49} | 633 | 201 | L_{b49} |
| 634 | 207 | L_{b49} | 635 | 228 | L_{b49} | 636 | 267 | L_{b49} |
| 637 | 272 | L_{b49} | 638 | 278 | L_{b49} | 639 | 299 | L_{b49} |
| 640 | 311 | L_{b49} | 641 | 338 | L_{b49} | 642 | 343 | L_{b49} |
| 643 | 349 | L_{b49} | 644 | 370 | L_{b49} | 645 | 409 | L_{b49} |
| 646 | 414 | L_{b49} | 647 | 420 | L_{b49} | 648 | 441 | L_{b49} |
| 649 | 480 | L_{b49} | 650 | 490 | L_{b49} | 651 | 511 | L_{b49} |
| 652 | 522 | L_{b49} | 653 | 550 | L_{b49} | 654 | 560 | L_{b49} |
| 655 | 581 | L_{b49} | 656 | 593 | L_{b49} | 657 | 620 | L_{b49} |
| 658 | 626 | L_{b49} | 659 | 648 | L_{b49} | 660 | 659 | L_{b49} |
| 661 | 746 | L_{b49} | 662 | 747 | L_{b49} | 663 | 749 | L_{b49} |
| 664 | 1 | L_{b51} | 665 | 7 | L_{b51} | 666 | 11 | L_{b51} |
| 667 | 21 | L_{b51} | 668 | 49 | L_{b51} | 669 | 63 | L_{b51} |
| 670 | 105 | L_{b51} | 67 | 106 | L_{b51} | 672 | 107 | L_{b51} |
| 673 | 110 | L_{b51} | 674 | 130 | L_{b51} | 675 | 131 | L_{b51} |
| 676 | 136 | L_{b51} | 677 | 140 | L_{b51} | 678 | 150 | L_{b51} |
| 679 | 152 | L_{b51} | 680 | 157 | L_{b51} | 681 | 161 | L_{b51} |
| 682 | 168 | L_{b51} | 683 | 196 | L_{b51} | 684 | 201 | L_{b51} |
| 685 | 207 | L_{b51} | 686 | 228 | L_{b51} | 687 | 267 | L_{b51} |
| 688 | 272 | L_{b51} | 689 | 278 | L_{b51} | 690 | 299 | L_{b51} |
| 691 | 311 | L_{b51} | 692 | 338 | L_{b51} | 693 | 343 | L_{b51} |
| 694 | 349 | L_{b51} | 695 | 370 | L_{b51} | 696 | 409 | L_{b51} |
| 697 | 414 | L_{b51} | 698 | 420 | L_{b51} | 699 | 441 | L_{b51} |
| 700 | 480 | L_{b51} | 701 | 490 | L_{b51} | 702 | 511 | L_{b51} |
| 703 | 522 | L_{b51} | 704 | 550 | L_{b51} | 705 | 560 | L_{b51} |
| 706 | 581 | L_{b51} | 707 | 593 | L_{b51} | 708 | 620 | L_{b51} |
| 709 | 626 | L_{b51} | 710 | 648 | L_{b51} | 711 | 659 | L_{b51} |
| 712 | 746 | L_{b51} | 713 | 747 | L_{b51} | 714 | 749 | L_{b51} |
| 715 | 1 | L_{b52} | 716 | 7 | L_{b52} | 717 | 11 | L_{b52} |
| 718 | 21 | L_{b52} | 719 | 49 | L_{b52} | 720 | 63 | L_{b52} |
| 721 | 105 | L_{b52} | 722 | 106 | L_{b52} | 723 | 107 | L_{b52} |
| 724 | 110 | L_{b52} | 725 | 130 | L_{b52} | 726 | 131 | L_{b52} |
| 727 | 136 | L_{b52} | 728 | 140 | L_{b52} | 729 | 150 | L_{b52} |
| 730 | 152 | L_{b52} | 731 | 157 | L_{b52} | 732 | 161 | L_{b52} |
| 733 | 168 | L_{b52} | 734 | 196 | L_{b52} | 735 | 201 | L_{b52} |
| 736 | 207 | L_{b52} | 737 | 228 | L_{b52} | 738 | 267 | L_{b52} |
| 739 | 272 | L_{b52} | 740 | 278 | L_{b52} | 741 | 299 | L_{b52} |
| 742 | 311 | L_{b52} | 743 | 338 | L_{b52} | 744 | 343 | L_{b52} |
| 745 | 349 | L_{b52} | 746 | 370 | L_{b52} | 747 | 409 | L_{b52} |
| 748 | 414 | L_{b52} | 749 | 420 | L_{b52} | 750 | 441 | L_{b52} |
| 751 | 480 | L_{b52} | 752 | 490 | L_{b52} | 753 | 511 | L_{b52} |
| 754 | 522 | L_{b52} | 755 | 550 | L_{b52} | 756 | 560 | L_{b52} |
| 757 | 58 | L_{b52} | 758 | 593 | L_{b52} | 759 | 620 | L_{b52} |
| 760 | 626 | L_{b52} | 761 | 648 | L_{b52} | 762 | 659 | L_{b52} |
| 763 | 746 | L_{b52} | 764 | 747 | L_{b52} | 765 | 749 | L_{b52} |
| 766 | 1 | L_{b53} | 767 | 7 | L_{b53} | 768 | 11 | L_{b53} |
| 769 | 21 | L_{b53} | 770 | 49 | L_{b53} | 771 | 63 | L_{b53} |
| 772 | 105 | L_{b53} | 773 | 106 | L_{b53} | 774 | 107 | L_{b53} |
| 775 | 110 | L_{b53} | 776 | 130 | L_{b53} | 777 | 131 | L_{b53} |
| 778 | 136 | L_{b53} | 779 | 140 | L_{b53} | 780 | 150 | L_{b53} |
| 781 | 152 | L_{b53} | 782 | 157 | L_{b53} | 783 | 161 | L_{b53} |
| 784 | 168 | L_{b53} | 785 | 196 | L_{b53} | 786 | 201 | L_{b53} |
| 787 | 207 | L_{b53} | 788 | 228 | L_{b53} | 789 | 267 | L_{b53} |
| 790 | 272 | L_{b53} | 791 | 278 | L_{b53} | 792 | 299 | L_{b53} |
| 793 | 311 | L_{b53} | 794 | 338 | L_{b53} | 795 | 343 | L_{b53} |
| 796 | 349 | L_{b53} | 797 | 370 | L_{b53} | 798 | 409 | L_{b53} |
| 799 | 414 | L_{b53} | 800 | 420 | L_{b53} | 801 | 441 | L_{b53} |
| 802 | 480 | L_{b53} | 803 | 490 | L_{b53} | 804 | 511 | L_{b53} |
| 805 | 522 | L_{b53} | 806 | 550 | L_{b53} | 807 | 560 | L_{b53} |
| 808 | 581 | L_{b53} | 809 | 593 | L_{b53} | 810 | 620 | L_{b53} |
| 811 | 626 | L_{b53} | 812 | 648 | L_{b53} | 813 | 659 | L_{b53} |
| 814 | 746 | L_{b53} | 815 | 747 | L_{b53} | 816 | 749 | L_{b53} |
| 817 | 1 | L_{b54} | 818 | 7 | L_{b54} | 819 | 11 | L_{b54} |
| 820 | 21 | L_{b54} | 821 | 49 | L_{b54} | 822 | 63 | L_{b54} |
| 823 | 105 | L_{b54} | 824 | 106 | L_{b54} | 825 | 107 | L_{b54} |
| 826 | 110 | L_{b54} | 827 | 130 | L_{b54} | 828 | 131 | L_{b54} |
| 829 | 136 | L_{b54} | 830 | 140 | L_{b54} | 831 | 150 | L_{b54} |
| 832 | 152 | L_{b54} | 833 | 157 | L_{b54} | 834 | 161 | L_{b54} |
| 835 | 168 | L_{b54} | 836 | 196 | L_{b54} | 837 | 201 | L_{b54} |
| 838 | 207 | L_{b54} | 839 | 228 | L_{b54} | 840 | 267 | L_{b54} |
| 841 | 272 | L_{b54} | 842 | 278 | L_{b54} | 843 | 299 | L_{b54} |
| 844 | 311 | L_{b54} | 845 | 338 | L_{b54} | 846 | 343 | L_{b54} |
| 847 | 349 | L_{b54} | 848 | 370 | L_{b54} | 849 | 409 | L_{b54} |
| 850 | 414 | L_{b54} | 851 | 420 | L_{b54} | 852 | 441 | L_{b54} |
| 853 | 480 | L_{b54} | 854 | 490 | L_{b54} | 855 | 511 | L_{b54} |
| 856 | 522 | L_{b54} | 857 | 550 | L_{b54} | 858 | 560 | L_{b54} |
| 859 | 581 | L_{b54} | 860 | 593 | L_{b54} | 861 | 620 | L_{b54} |
| 862 | 626 | L_{b54} | 863 | 648 | L_{b54} | 864 | 659 | L_{b54} |
| 865 | 746 | L_{b54} | 866 | 747 | L_{b54} | 867 | 749 | L_{b54} |
| 868 | 1 | L_{b56} | 869 | 7 | L_{b56} | 870 | 11 | L_{b56} |
| 871 | 21 | L_{b56} | 872 | 49 | L_{b56} | 873 | 63 | L_{b56} |
| 874 | 105 | L_{b56} | 875 | 106 | L_{b56} | 876 | 107 | L_{b56} |
| 877 | 110 | L_{b56} | 878 | 130 | L_{b56} | 879 | 131 | L_{b56} |
| 880 | 136 | L_{b56} | 881 | 140 | L_{b56} | 882 | 150 | L_{b56} |
| 883 | 152 | L_{b56} | 884 | 157 | L_{b56} | 885 | 161 | L_{b56} |
| 886 | 168 | L_{b56} | 887 | 196 | L_{b56} | 888 | 201 | L_{b56} |
| 889 | 207 | L_{b56} | 890 | 228 | L_{b56} | 891 | 267 | L_{b56} |
| 892 | 272 | L_{b56} | 893 | 278 | L_{b56} | 894 | 299 | L_{b56} |
| 895 | 311 | L_{b56} | 896 | 338 | L_{b56} | 897 | 343 | L_{b56} |
| 898 | 349 | L_{b56} | 899 | 370 | L_{b56} | 900 | 409 | L_{b56} |
| 901 | 414 | L_{b56} | 902 | 420 | L_{b56} | 903 | 441 | L_{b56} |
| 904 | 480 | L_{b56} | 905 | 490 | L_{b56} | 906 | 511 | L_{b56} |
| 907 | 522 | L_{b56} | 908 | 550 | L_{b56} | 909 | 560 | L_{b56} |
| 910 | 581 | L_{b56} | 911 | 593 | L_{b56} | 912 | 620 | L_{b56} |
| 913 | 626 | L_{b56} | 914 | 648 | L_{b56} | 915 | 659 | L_{b56} |
| 916 | 746 | L_{b56} | 917 | 747 | L_{b56} | 918 | 749 | L_{b56} |
| 919 | 1 | L_{b59} | 920 | 7 | L_{b59} | 921 | 11 | L_{b59} |
| 922 | 21 | L_{b59} | 923 | 49 | L_{b59} | 924 | 63 | L_{b59} |
| 925 | 105 | L_{b59} | 926 | 106 | L_{b59} | 927 | 107 | L_{b59} |
| 928 | 110 | L_{b59} | 929 | 130 | L_{b59} | 930 | 131 | L_{b59} |
| 931 | 136 | L_{b59} | 932 | 140 | L_{b59} | 933 | 150 | L_{b59} |
| 934 | 152 | L_{b59} | 935 | 157 | L_{b59} | 936 | 161 | L_{b59} |
| 937 | 168 | L_{b59} | 938 | 196 | L_{b59} | 939 | 201 | L_{b59} |
| 940 | 207 | L_{b59} | 941 | 228 | L_{b59} | 942 | 267 | L_{b59} |
| 943 | 272 | L_{b59} | 944 | 278 | L_{b59} | 945 | 299 | L_{b59} |
| 946 | 311 | L_{b59} | 947 | 338 | L_{b59} | 948 | 343 | L_{b59} |
| 949 | 349 | L_{b59} | 950 | 370 | L_{b59} | 951 | 409 | L_{b59} |
| 952 | 414 | L_{b59} | 953 | 420 | L_{b59} | 954 | 441 | L_{b59} |
| 955 | 480 | L_{b59} | 956 | 490 | L_{b59} | 957 | 511 | L_{b59} |
| 958 | 522 | L_{b59} | 959 | 550 | L_{b59} | 960 | 560 | L_{b59} |
| 961 | 581 | L_{b59} | 962 | 593 | L_{b59} | 963 | 620 | L_{b59} |
| 964 | 626 | L_{b59} | 965 | 648 | L_{b59} | 966 | 659 | L_{b59} |
| 967 | 746 | L_{b59} | 968 | 747 | L_{b59} | 969 | 749 | L_{b59} |
| 970 | 1 | L_{b60} | 97 | 7 | L_{b60} | 972 | 11 | L_{b60} |
| 973 | 21 | L_{b60} | 974 | 49 | L_{b60} | 975 | 63 | L_{b60} |
| 976 | 105 | L_{b60} | 977 | 106 | L_{b60} | 978 | 107 | L_{b60} |
| 979 | 110 | L_{b60} | 980 | 130 | L_{b60} | 981 | 131 | L_{b60} |
| 982 | 136 | L_{b60} | 983 | 140 | L_{b60} | 984 | 150 | L_{b60} |
| 985 | 152 | L_{b60} | 986 | 157 | L_{b60} | 987 | 161 | L_{b60} |
| 988 | 168 | L_{b60} | 989 | 196 | L_{b60} | 990 | 201 | L_{b60} |
| 991 | 207 | L_{b60} | 992 | 228 | L_{b60} | 993 | 267 | L_{b60} |
| 994 | 272 | L_{b60} | 995 | 278 | L_{b60} | 996 | 299 | L_{b60} |
| 997 | 311 | L_{b60} | 998 | 338 | L_{b60} | 999 | 343 | L_{b60} |
| 1000 | 349 | L_{b60} | 1001 | 370 | L_{b60} | 1002 | 409 | L_{b60} |
| 1003 | 414 | L_{b60} | 1004 | 420 | L_{b60} | 1005 | 441 | L_{b60} |
| 1006 | 480 | L_{b60} | 1007 | 490 | L_{b60} | 1008 | 511 | L_{b60} |
| 1009 | 522 | L_{b60} | 1010 | 550 | L_{b60} | 1011 | 560 | L_{b60} |
| 1012 | 581 | L_{b60} | 1013 | 593 | L_{b60} | 1014 | 620 | L_{b60} |
| 1015 | 626 | L_{b60} | 1016 | 648 | L_{b60} | 1017 | 659 | L_{b60} |
| 1018 | 746 | L_{b60} | 1019 | 747 | L_{b60} | 1020 | 749 | L_{b60} |
| 1021 | 1 | L_{b65} | 1022 | 7 | L_{b65} | 1023 | 11 | L_{b65} |
| 1024 | 21 | L_{b65} | 1025 | 49 | L_{b65} | 1026 | 63 | L_{b65} |
| 1027 | 105 | L_{b65} | 1028 | 106 | L_{b65} | 1029 | 107 | L_{b65} |
| 1030 | 110 | L_{b65} | 1031 | 130 | L_{b65} | 1032 | 131 | L_{b65} |
| 1033 | 136 | L_{b65} | 1034 | 140 | L_{b65} | 1035 | 150 | L_{b65} |
| 1036 | 152 | L_{b65} | 1037 | 157 | L_{b65} | 1038 | 161 | L_{b65} |
| 1039 | 168 | L_{b65} | 1040 | 196 | L_{b65} | 1041 | 201 | L_{b65} |
| 1042 | 207 | L_{b65} | 1043 | 228 | L_{b65} | 1044 | 267 | L_{b65} |
| 1045 | 272 | L_{b65} | 1046 | 278 | L_{b65} | 1047 | 299 | L_{b65} |
| 1048 | 311 | L_{b65} | 1049 | 338 | L_{b65} | 1050 | 343 | L_{b65} |
| 1051 | 349 | L_{b65} | 1052 | 370 | L_{b65} | 1053 | 409 | L_{b65} |
| 1054 | 414 | L_{b65} | 1055 | 420 | L_{b65} | 1056 | 441 | L_{b65} |
| 1057 | 480 | L_{b65} | 1058 | 490 | L_{b65} | 1059 | 511 | L_{b65} |
| 1060 | 522 | L_{b65} | 1061 | 550 | L_{b65} | 1062 | 560 | L_{b65} |
| 1063 | 581 | L_{b65} | 1064 | 593 | L_{b65} | 1065 | 620 | L_{b65} |
| 1066 | 626 | L_{b65} | 1067 | 648 | L_{b65} | 1068 | 659 | L_{b65} |
| 1069 | 746 | L_{b65} | 1070 | 747 | L_{b65} | 1071 | 749 | L_{b65} |
| 1072 | 1 | L_{b74} | 1073 | 7 | L_{b74} | 1074 | 11 | L_{b74} |
| 1075 | 21 | L_{b74} | 1076 | 49 | L_{b74} | 1077 | 63 | L_{b74} |
| 1078 | 105 | L_{b74} | 1079 | 106 | L_{b74} | 1080 | 107 | L_{b74} |
| 1081 | 110 | L_{b74} | 1082 | 130 | L_{b74} | 1083 | 131 | L_{b74} |
| 1084 | 136 | L_{b74} | 1085 | 140 | L_{b74} | 1086 | 150 | L_{b74} |
| 1087 | 152 | L_{b74} | 1088 | 157 | L_{b74} | 1089 | 161 | L_{b74} |
| 1090 | 168 | L_{b74} | 1091 | 196 | L_{b74} | 1092 | 201 | L_{b74} |
| 1093 | 207 | L_{b74} | 1094 | 228 | L_{b74} | 1095 | 267 | L_{b74} |
| 1096 | 272 | L_{b74} | 1097 | 278 | L_{b74} | 1098 | 299 | L_{b74} |
| 1099 | 311 | L_{b74} | 1100 | 338 | L_{b74} | 1101 | 343 | L_{b74} |
| 1102 | 349 | L_{b74} | 1103 | 370 | L_{b74} | 1104 | 40 | L_{b74} |
| 1105 | 414 | L_{b74} | 1106 | 420 | L_{b74} | 1107 | 441 | L_{b74} |
| 1108 | 480 | L_{b74} | 1109 | 490 | L_{b74} | 1110 | 511 | L_{b74} |
| 1111 | 522 | L_{b74} | 1112 | 550 | L_{b74} | 1113 | 560 | L_{b74} |
| 1114 | 58 | L_{b74} | 1115 | 593 | L_{b74} | 1116 | 620 | L_{b74} |
| 1117 | 626 | L_{b74} | 1118 | 648 | L_{b74} | 1119 | 659 | L_{b74} |
| 1120 | 746 | L_{b74} | 1121 | 747 | L_{b74} | 1122 | 749 | L_{b74} |
| 1123 | 1 | L_{b87} | 1124 | 7 | L_{b87} | 1125 | 11 | L_{b87} |
| 1126 | 21 | L_{b87} | 1127 | 49 | L_{b87} | 1128 | 63 | L_{b87} |
| 1129 | 105 | L_{b87} | 1130 | 106 | L_{b87} | 1131 | 107 | L_{b87} |
| 1132 | 110 | L_{b87} | 1133 | 130 | L_{b87} | 1134 | 131 | L_{b87} |
| 1135 | 136 | L_{b87} | 1136 | 140 | L_{b87} | 1137 | 150 | L_{b87} |
| 1138 | 152 | L_{b87} | 1139 | 157 | L_{b87} | 1140 | 161 | L_{b87} |
| 1141 | 168 | L_{b87} | 1142 | 196 | L_{b87} | 1143 | 201 | L_{b87} |
| 1144 | 207 | L_{b87} | 1145 | 228 | L_{b87} | 1146 | 267 | L_{b87} |
| 1147 | 272 | L_{b87} | 1148 | 278 | L_{b87} | 1149 | 299 | L_{b87} |
| 1150 | 311 | L_{b87} | 1151 | 338 | L_{b87} | 1152 | 343 | L_{b87} |
| 1153 | 349 | L_{b87} | 1154 | 370 | L_{b87} | 1155 | 409 | L_{b87} |
| 1156 | 414 | L_{b87} | 1157 | 420 | L_{b87} | 1158 | 441 | L_{b87} |
| 1159 | 480 | L_{b87} | 1160 | 490 | L_{b87} | 1161 | 511 | L_{b87} |
| 1162 | 522 | L_{b87} | 1163 | 550 | L_{b87} | 1164 | 560 | L_{b87} |
| 1165 | 581 | L_{b87} | 1166 | 593 | L_{b87} | 1167 | 620 | L_{b87} |
| 1168 | 626 | L_{b87} | 1169 | 648 | L_{b87} | 1170 | 659 | L_{b87} |
| 1171 | 746 | L_{b87} | 1172 | 747 | L_{b87} | 1173 | 749 | L_{b87} |
| 1174 | 1 | L_{b98} | 1175 | 7 | L_{b98} | 1176 | 11 | L_{b98} |
| 1177 | 21 | L_{b98} | 1178 | 49 | L_{b98} | 1179 | 63 | L_{b98} |
| 1180 | 105 | L_{b98} | 1181 | 106 | L_{b98} | 1182 | 107 | L_{b98} |
| 1183 | 110 | L_{b98} | 1184 | 130 | L_{b98} | 1185 | 131 | L_{b98} |
| 1186 | 136 | L_{b98} | 1187 | 140 | L_{b98} | 1188 | 150 | L_{b98} |
| 1189 | 152 | L_{b98} | 1190 | 157 | L_{b98} | 1191 | 161 | L_{b98} |
| 1192 | 168 | L_{b98} | 1193 | 196 | L_{b98} | 1194 | 201 | L_{b98} |
| 1195 | 207 | L_{b98} | 1196 | 228 | L_{b98} | 1197 | 267 | L_{b98} |
| 1198 | 272 | L_{b98} | 1199 | 278 | L_{b98} | 1200 | 299 | L_{b98} |
| 1201 | 311 | L_{b98} | 1202 | 338 | L_{b98} | 1203 | 343 | L_{b98} |
| 1204 | 349 | L_{b98} | 1205 | 370 | L_{b98} | 1206 | 409 | L_{b98} |
| 1207 | 414 | L_{b98} | 1208 | 420 | L_{b98} | 1209 | 441 | L_{b98} |
| 1210 | 480 | L_{b98} | 1211 | 490 | L_{b98} | 1212 | 511 | L_{b98} |
| 1213 | 522 | L_{b98} | 1214 | 550 | L_{b98} | 1215 | 560 | L_{b98} |
| 1216 | 581 | L_{b98} | 1217 | 593 | L_{b98} | 1218 | 620 | L_{b98} |
| 1219 | 626 | L_{b98} | 1220 | 648 | L_{b98} | 1221 | 659 | L_{b98} |
| 1222 | 746 | L_{b98} | 1223 | 747 | L_{b98} | 1224 | 749 | L_{b98} |
| 1225 | 1 | L_{b128} | 1226 | 7 | L_{b128} | 1227 | 11 | L_{b128} |
| 1228 | 21 | L_{b128} | 1229 | 49 | L_{b128} | 1230 | 63 | L_{b128} |
| 1231 | 105 | L_{b128} | 1232 | 106 | L_{b128} | 1233 | 107 | L_{b128} |
| 1234 | 110 | L_{b128} | 1235 | 130 | L_{b128} | 1236 | 131 | L_{b128} |
| 1237 | 136 | L_{b128} | 1238 | 140 | L_{b128} | 1239 | 150 | L_{b128} |
| 1240 | 152 | L_{b128} | 1241 | 157 | L_{b128} | 1242 | 161 | L_{b128} |
| 1243 | 168 | L_{b128} | 1244 | 196 | L_{b128} | 1245 | 201 | L_{b128} |
| 1246 | 207 | L_{b128} | 1247 | 228 | L_{b128} | 1248 | 267 | L_{b128} |
| 1249 | 272 | L_{b128} | 1250 | 278 | L_{b128} | 1251 | 299 | L_{b128} |
| 1252 | 311 | L_{b128} | 1253 | 338 | L_{b128} | 1254 | 343 | L_{b128} |
| 1255 | 349 | L_{b128} | 1256 | 370 | L_{b128} | 1257 | 409 | L_{b128} |
| 1258 | 414 | L_{b128} | 1259 | 420 | L_{b128} | 1260 | 441 | L_{b128} |
| 1261 | 480 | L_{b128} | 1262 | 490 | L_{b128} | 1263 | 511 | L_{b128} |
| 1264 | 522 | L_{b128} | 1265 | 550 | L_{b128} | 1266 | 560 | L_{b128} |
| 1267 | 581 | L_{b128} | 1268 | 593 | L_{b128} | 1269 | 620 | L_{b128} |
| 1270 | 626 | L_{b128} | 1271 | 648 | L_{b128} | 1272 | 659 | L_{b128} |
| 1273 | 746 | L_{b128} | 1274 | 747 | L_{b128} | 1275 | 749 | L_{b128} |
| 1276 | 1 | L_{b263} | 1277 | 7 | L_{b263} | 1278 | 11 | L_{b263} |
| 1279 | 21 | L_{b263} | 1280 | 49 | L_{b263} | 1281 | 63 | L_{b263} |
| 1282 | 105 | L_{b263} | 1283 | 106 | L_{b263} | 1284 | 107 | L_{b263} |
| 1285 | 110 | L_{b263} | 1286 | 130 | L_{b263} | 1287 | 131 | L_{b263} |
| 1288 | 136 | L_{b263} | 1289 | 140 | L_{b263} | 1290 | 150 | L_{b263} |
| 1291 | 152 | L_{b263} | 1292 | 157 | L_{b263} | 1293 | 161 | L_{b263} |
| 1294 | 168 | L_{b263} | 1295 | 196 | L_{b263} | 1296 | 201 | L_{b263} |
| 1297 | 207 | L_{b263} | 1298 | 228 | L_{b263} | 1299 | 267 | L_{b263} |
| 1300 | 272 | L_{b263} | 1301 | 278 | L_{b263} | 1302 | 299 | L_{b263} |
| 1303 | 311 | L_{b263} | 1304 | 338 | L_{b263} | 1305 | 343 | L_{b263} |
| 1306 | 349 | L_{b263} | 1307 | 370 | L_{b263} | 1308 | 409 | L_{b263} |
| 1309 | 414 | L_{b263} | 1310 | 420 | L_{b263} | 1311 | 441 | L_{b263} |
| 1312 | 480 | L_{b263} | 1313 | 490 | L_{b263} | 1314 | 511 | L_{b263} |
| 1315 | 522 | L_{b263} | 1316 | 550 | L_{b263} | 1317 | 560 | L_{b263} |
| 1318 | 581 | L_{b263} | 1319 | 593 | L_{b263} | 1320 | 620 | L_{b263} |
| 1321 | 626 | L_{b263} | 1322 | 648 | L_{b263} | 1323 | 659 | L_{b263} |
| 1324 | 746 | L_{b263} | 1325 | 747 | L_{b263} | 1326 | 749 | L_{b263} |
| 1327 | 1 | L_{b264} | 1328 | 7 | L_{b264} | 1329 | 11 | L_{b264} |
| 1330 | 21 | L_{b264} | 1331 | 49 | L_{b264} | 1332 | 63 | L_{b264} |
| 1333 | 105 | L_{b264} | 1334 | 106 | L_{b264} | 1335 | 107 | L_{b264} |
| 1336 | 110 | L_{b264} | 1337 | 130 | L_{b264} | 1338 | 131 | L_{b264} |
| 1339 | 136 | L_{b264} | 1340 | 140 | L_{b264} | 1341 | 150 | L_{b264} |
| 1342 | 152 | L_{b264} | 1343 | 157 | L_{b264} | 1344 | 161 | L_{b264} |
| 1345 | 168 | L_{b264} | 1346 | 196 | L_{b264} | 1347 | 201 | L_{b264} |
| 1348 | 207 | L_{b264} | 1349 | 228 | L_{b264} | 1350 | 267 | L_{b264} |
| 1351 | 272 | L_{b264} | 1352 | 278 | L_{b264} | 1353 | 299 | L_{b264} |
| 1354 | 311 | L_{b264} | 1355 | 338 | L_{b264} | 1356 | 343 | L_{b264} |
| 1357 | 349 | L_{b264} | 1358 | 370 | L_{b264} | 1359 | 409 | L_{b264} |
| 1360 | 414 | L_{b264} | 1361 | 420 | L_{b264} | 1362 | 441 | L_{b264} |
| 1363 | 480 | L_{b264} | 1364 | 490 | L_{b264} | 1365 | 511 | L_{b264} |
| 1366 | 522 | L_{b264} | 1367 | 550 | L_{b264} | 1368 | 560 | L_{b264} |
| 1369 | 581 | L_{b264} | 1370 | 593 | L_{b264} | 1371 | 620 | L_{b264} |
| 1372 | 626 | L_{b264} | 1373 | 648 | L_{b264} | 1374 | 659 | L_{b264} |
| 1375 | 746 | L_{b264} | 1376 | 747 | L_{b264} | 1377 | 749 | L_{b264} |
| 1378 | 1 | L_{b265} | 1379 | 7 | L_{b265} | 1380 | 11 | L_{b265} |
| 1381 | 21 | L_{b265} | 1382 | 49 | L_{b265} | 1383 | 63 | L_{b265} |
| 1384 | 105 | L_{b265} | 1385 | 106 | L_{b265} | 1386 | 107 | L_{b265} |
| 1387 | 110 | L_{b265} | 1388 | 130 | L_{b265} | 1389 | 131 | L_{b265} |
| 1390 | 136 | L_{b265} | 1391 | 140 | L_{b265} | 1392 | 150 | L_{b265} |
| 1393 | 152 | L_{b265} | 1394 | 157 | L_{b265} | 1395 | 161 | L_{b265} |
| 1396 | 168 | L_{b265} | 1397 | 196 | L_{b265} | 1398 | 201 | L_{b265} |
| 1399 | 207 | L_{b265} | 1400 | 228 | L_{b265} | 1401 | 267 | L_{b265} |
| 1402 | 272 | L_{b265} | 1403 | 278 | L_{b265} | 1404 | 299 | L_{b265} |
| 1405 | 311 | L_{b265} | 1406 | 338 | L_{b265} | 1407 | 343 | L_{b265} |
| 1408 | 349 | L_{b265} | 1409 | 370 | L_{b265} | 1410 | 409 | L_{b265} |
| 1411 | 414 | L_{b265} | 1412 | 420 | L_{b265} | 1413 | 441 | L_{b265} |
| 1414 | 480 | L_{b265} | 1415 | 490 | L_{b265} | 1416 | 511 | L_{b265} |
| 1417 | 522 | L_{b265} | 1418 | 550 | L_{b265} | 1419 | 560 | L_{b265} |
| 1420 | 58 | L_{b265} | 1421 | 593 | L_{b265} | 1422 | 620 | L_{b265} |
| 1423 | 626 | L_{b265} | 1424 | 648 | L_{b265} | 1425 | 659 | L_{b265} |
| 1426 | 746 | L_{b265} | 1427 | 747 | L_{b265} | 1428 | 749 | L_{b265} |
| 1429 | 1 | L_{b294} | 1430 | 7 | L_{b294} | 1431 | 11 | L_{b294} |
| 1432 | 21 | L_{b294} | 1433 | 49 | L_{b294} | 1434 | 63 | L_{b294} |
| 1435 | 105 | L_{b294} | 1436 | 106 | L_{b294} | 1437 | 107 | L_{b294} |
| 1438 | 110 | L_{b294} | 1439 | 130 | L_{b294} | 1440 | 131 | L_{b294} |
| 1441 | 136 | L_{b294} | 1442 | 140 | L_{b294} | 1443 | 150 | L_{b294} |
| 1444 | 152 | L_{b294} | 1445 | 157 | L_{b294} | 1446 | 161 | L_{b294} |
| 1447 | 168 | L_{b294} | 1448 | 196 | L_{b294} | 1449 | 201 | L_{b294} |
| 1450 | 207 | L_{b294} | 1451 | 228 | L_{b294} | 1452 | 267 | L_{b294} |
| 1453 | 272 | L_{b294} | 1454 | 278 | L_{b294} | 1455 | 299 | L_{b294} |
| 1456 | 311 | L_{b294} | 1457 | 338 | L_{b294} | 1458 | 343 | L_{b294} |
| 1459 | 349 | L_{b294} | 1460 | 370 | L_{b294} | 1461 | 409 | L_{b294} |
| 1462 | 414 | L_{b294} | 1463 | 420 | L_{b294} | 1464 | 441 | L_{b294} |
| 1465 | 480 | L_{b294} | 1466 | 490 | L_{b294} | 1467 | 511 | L_{b294} |
| 1468 | 522 | L_{b294} | 1469 | 550 | L_{b294} | 1470 | 560 | L_{b294} |
| 1471 | 581 | L_{b294} | 1472 | 593 | L_{b294} | 1473 | 620 | L_{b294} |
| 1474 | 626 | L_{b294} | 1475 | 648 | L_{b294} | 1476 | 659 | L_{b294} |
| 1477 | 746 | L_{b294} | 1478 | 747 | L_{b294} | 1479 | 749 | L_{b294} |
| 1480 | 1 | L_{b296} | 1481 | 7 | L_{b296} | 1482 | 11 | L_{b296} |
| 1483 | 21 | L_{b296} | 1484 | 49 | L_{b296} | 1485 | 63 | L_{b296} |
| 1486 | 105 | L_{b296} | 1487 | 106 | L_{b296} | 1488 | 107 | L_{b296} |
| 1489 | 110 | L_{b296} | 1490 | 130 | L_{b296} | 1491 | 131 | L_{b296} |
| 1492 | 136 | L_{b296} | 1493 | 140 | L_{b296} | 1494 | 150 | L_{b296} |
| 1495 | 152 | L_{b296} | 1496 | 157 | L_{b296} | 1497 | 161 | L_{b296} |
| 1498 | 168 | L_{b296} | 1499 | 196 | L_{b296} | 1500 | 201 | L_{b296} |
| 1501 | 207 | L_{b296} | 1502 | 228 | L_{b296} | 1503 | 267 | L_{b296} |
| 1504 | 272 | L_{b296} | 1505 | 278 | L_{b296} | 1506 | 299 | L_{b296} |
| 1507 | 311 | L_{b296} | 1508 | 338 | L_{b296} | 1509 | 343 | L_{b296} |
| 1510 | 349 | L_{b296} | 1511 | 370 | L_{b296} | 1512 | 409 | L_{b296} |
| 1513 | 414 | L_{b296} | 1514 | 420 | L_{b296} | 1515 | 441 | L_{b296} |
| 1516 | 480 | L_{b296} | 1517 | 490 | L_{b296} | 1518 | 511 | L_{b296} |
| 1519 | 522 | L_{b296} | 1520 | 550 | L_{b296} | 1521 | 560 | L_{b296} |
| 1522 | 581 | L_{b296} | 1523 | 593 | L_{b296} | 1524 | 620 | L_{b296} |
| 1525 | 626 | L_{b296} | 1526 | 648 | L_{b296} | 1527 | 659 | L_{b296} |
| 1528 | 746 | L_{b296} | 1529 | 747 | L_{b296} | 1530 | 749 | L_{b296} |
| 1531 | 1 | L_{b349} | 1532 | 7 | L_{b349} | 1533 | 11 | L_{b349} |
| 1534 | 21 | L_{b349} | 1535 | 49 | L_{b349} | 1536 | 63 | L_{b349} |
| 1537 | 105 | L_{b349} | 1538 | 106 | L_{b349} | 1539 | 107 | L_{b349} |
| 1540 | 110 | L_{b349} | 1541 | 130 | L_{b349} | 1542 | 131 | L_{b349} |
| 1543 | 136 | L_{b349} | 1544 | 140 | L_{b349} | 1545 | 150 | L_{b349} |
| 1546 | 152 | L_{b349} | 1547 | 157 | L_{b349} | 1548 | 161 | L_{b349} |
| 1549 | 168 | L_{b349} | 1550 | 196 | L_{b349} | 1551 | 201 | L_{b349} |
| 1552 | 207 | L_{b349} | 1553 | 228 | L_{b349} | 1554 | 267 | L_{b349} |
| 1555 | 272 | L_{b349} | 1556 | 278 | L_{b349} | 1557 | 299 | L_{b349} |
| 1558 | 311 | L_{b349} | 1559 | 338 | L_{b349} | 1560 | 343 | L_{b349} |
| 1561 | 349 | L_{b349} | 1562 | 370 | L_{b349} | 1563 | 409 | L_{b349} |
| 1564 | 414 | L_{b349} | 1565 | 420 | L_{b349} | 1566 | 441 | L_{b349} |
| 1567 | 480 | L_{b349} | 1568 | 490 | L_{b349} | 1569 | 511 | L_{b349} |
| 1570 | 522 | L_{b349} | 1571 | 550 | L_{b349} | 1572 | 560 | L_{b349} |
| 1573 | 581 | L_{b349} | 1574 | 593 | L_{b349} | 1575 | 620 | L_{b349} |
| 1576 | 626 | L_{b349} | 1577 | 648 | L_{b349} | 1578 | 659 | L_{b349} |
| 1579 | 746 | L_{b349} | 1580 | 747 | L_{b349} | 1581 | 749 | L_{b349} |
| 1582 | 1 | L_{b360} | 1583 | 7 | L_{b360} | 1584 | 11 | L_{b360} |
| 1585 | 21 | L_{b360} | 1586 | 49 | L_{b360} | 1587 | 63 | L_{b360} |
| 1588 | 105 | L_{b360} | 1589 | 106 | L_{b360} | 1590 | 107 | L_{b360} |
| 1591 | 110 | L_{b360} | 1592 | 130 | L_{b360} | 1593 | 131 | L_{b360} |
| 1594 | 136 | L_{b360} | 1595 | 140 | L_{b360} | 1596 | 150 | L_{b360} |
| 1597 | 152 | L_{b360} | 1598 | 157 | L_{b360} | 1599 | 161 | L_{b360} |
| 1600 | 168 | L_{b360} | 1601 | 196 | L_{b360} | 1602 | 201 | L_{b360} |
| 1603 | 207 | L_{b360} | 1604 | 228 | L_{b360} | 1605 | 267 | L_{b360} |
| 1606 | 272 | L_{b360} | 1607 | 278 | L_{b360} | 1608 | 299 | L_{b360} |
| 1609 | 311 | L_{b360} | 1610 | 338 | L_{b360} | 1611 | 343 | L_{b360} |
| 1612 | 349 | L_{b360} | 1613 | 370 | L_{b360} | 1614 | 409 | L_{b360} |
| 1615 | 414 | L_{b360} | 1616 | 420 | L_{b360} | 1617 | 441 | L_{b360} |
| 1618 | 480 | L_{b360} | 1619 | 490 | L_{b360} | 1620 | 511 | L_{b360} |
| 1621 | 522 | L_{b360} | 1622 | 550 | L_{b360} | 1623 | 560 | L_{b360} |
| 1624 | 581 | L_{b360} | 1625 | 593 | L_{b360} | 1626 | 620 | L_{b360} |
| 1627 | 626 | L_{b360} | 1628 | 648 | L_{b360} | 1629 | 659 | L_{b360} |
| 1630 | 746 | L_{b360} | 1631 | 747 | L_{b360} | 1632 | 749 | L_{b360} |
| 1633 | 1 | L_{b482} | 1634 | 7 | L_{b482} | 1635 | 11 | L_{b482} |
| 1636 | 21 | L_{b482} | 1637 | 49 | L_{b482} | 1638 | 63 | L_{b482} |
| 1639 | 105 | L_{b482} | 1640 | 106 | L_{b482} | 1641 | 107 | L_{b482} |
| 1642 | 110 | L_{b482} | 1643 | 130 | L_{b482} | 1644 | 131 | L_{b482} |
| 1645 | 136 | L_{b482} | 1646 | 140 | L_{b482} | 1647 | 150 | L_{b482} |
| 1648 | 152 | L_{b482} | 1649 | 157 | L_{b482} | 1650 | 161 | L_{b482} |
| 1651 | 168 | L_{b482} | 1652 | 196 | L_{b482} | 1653 | 201 | L_{b482} |
| 1654 | 207 | L_{b482} | 1655 | 228 | L_{b482} | 1656 | 267 | L_{b482} |
| 1657 | 272 | L_{b482} | 1658 | 278 | L_{b482} | 1659 | 299 | L_{b482} |
| 1660 | 311 | L_{b482} | 1661 | 338 | L_{b482} | 1662 | 343 | L_{b482} |
| 1663 | 349 | L_{b482} | 1664 | 370 | L_{b482} | 1665 | 409 | L_{b482} |
| 1666 | 414 | L_{b482} | 1667 | 420 | L_{b482} | 1668 | 441 | L_{b482} |
| 1669 | 480 | L_{b482} | 1670 | 490 | L_{b482} | 1671 | 511 | L_{b482} |
| 1672 | 522 | L_{b482} | 1673 | 550 | L_{b482} | 1674 | 560 | L_{b482} |
| 1675 | 581 | L_{b482} | 1676 | 593 | L_{b482} | 1677 | 620 | L_{b482} |
| 1678 | 626 | L_{b482} | 1679 | 648 | L_{b482} | 1680 | 659 | L_{b482} |
| 1681 | 746 | L_{b482} | 1682 | 747 | L_{b482} | 1683 | 749 | L_{b482} |
| 1684 | 1 | L_{b484} | 1685 | 7 | L_{b484} | 1686 | 11 | L_{b484} |
| 1687 | 21 | L_{b484} | 1688 | 49 | L_{b484} | 1689 | 63 | L_{b484} |
| 1690 | 105 | L_{b484} | 1691 | 106 | L_{b484} | 1692 | 107 | L_{b484} |
| 1693 | 110 | L_{b484} | 1694 | 130 | L_{b484} | 1695 | 131 | L_{b484} |
| 1696 | 136 | L_{b484} | 1697 | 140 | L_{b484} | 1698 | 150 | L_{b484} |
| 1699 | 152 | L_{b484} | 1700 | 157 | L_{b484} | 1701 | 161 | L_{b484} |
| 1702 | 168 | L_{b484} | 1703 | 196 | L_{b484} | 1704 | 201 | L_{b484} |
| 1705 | 207 | L_{b484} | 1706 | 228 | L_{b484} | 1707 | 267 | L_{b484} |
| 1708 | 272 | L_{b484} | 1709 | 278 | L_{b484} | 1710 | 299 | L_{b484} |
| 1711 | 311 | L_{b484} | 1712 | 338 | L_{b484} | 1713 | 343 | L_{b484} |
| 1714 | 349 | L_{b484} | 1715 | 370 | L_{b484} | 1716 | 409 | L_{b484} |
| 1717 | 414 | L_{b484} | 1718 | 420 | L_{b484} | 1719 | 441 | L_{b484} |
| 1720 | 480 | L_{b484} | 1721 | 490 | L_{b484} | 1722 | 511 | L_{b484} |
| 1723 | 522 | L_{b484} | 1724 | 550 | L_{b484} | 1725 | 560 | L_{b484} |
| 1726 | 581 | L_{b484} | 1727 | 593 | L_{b484} | 1728 | 620 | L_{b484} |
| 1729 | 626 | L_{b484} | 1730 | 648 | L_{b484} | 1731 | 659 | L_{b484} |
| 1732 | 746 | L_{b484} | 1733 | 747 | L_{b484} | 1734 | 749 | L_{b484} |
| 1735 | 1 | L_{b485} | 1736 | 7 | L_{b485} | 1737 | 11 | L_{b485} |
| 1738 | 21 | L_{b485} | 1739 | 49 | L_{b485} | 1740 | 63 | L_{b485} |
| 1741 | 105 | L_{b485} | 1742 | 106 | L_{b485} | 1743 | 107 | L_{b485} |
| 1744 | 110 | L_{b485} | 1745 | 130 | L_{b485} | 1746 | 131 | L_{b485} |
| 1747 | 136 | L_{b485} | 1748 | 140 | L_{b485} | 1749 | 150 | L_{b485} |
| 1750 | 152 | L_{b485} | 1751 | 157 | L_{b485} | 1752 | 161 | L_{b485} |
| 1753 | 168 | L_{b485} | 1754 | 196 | L_{b485} | 1755 | 201 | L_{b485} |
| 1756 | 207 | L_{b485} | 1757 | 228 | L_{b485} | 1758 | 267 | L_{b485} |
| 1759 | 272 | L_{b485} | 1760 | 278 | L_{b485} | 1761 | 299 | L_{b485} |
| 1762 | 311 | L_{b485} | 1763 | 338 | L_{b485} | 1764 | 343 | L_{b485} |
| 1765 | 349 | L_{b485} | 1766 | 370 | L_{b485} | 1767 | 409 | L_{b485} |
| 1768 | 414 | L_{b485} | 1769 | 420 | L_{b485} | 1770 | 441 | L_{b485} |
| 1771 | 480 | L_{b485} | 1772 | 490 | L_{b485} | 1773 | 511 | L_{b485} |
| 1774 | 522 | L_{b485} | 1775 | 550 | L_{b485} | 1776 | 560 | L_{b485} |
| 1777 | 581 | L_{b485} | 1778 | 593 | L_{b485} | 1779 | 620 | L_{b485} |
| 1780 | 626 | L_{b485} | 1781 | 648 | L_{b485} | 1782 | 659 | L_{b485} |
| 1783 | 746 | L_{b485} | 1784 | 747 | L_{b485} | 1785 | 749 | L_{b485} |
| 1786 | 1 | L_{b487} | 1787 | 7 | L_{b487} | 1788 | 11 | L_{b487} |
| 1789 | 21 | L_{b487} | 1790 | 49 | L_{b487} | 1791 | 63 | L_{b487} |
| 1792 | 105 | L_{b487} | 1793 | 106 | L_{b487} | 1794 | 107 | L_{b487} |
| 1795 | 110 | L_{b487} | 1796 | 130 | L_{b487} | 1797 | 131 | L_{b487} |
| 1798 | 136 | L_{b487} | 1799 | 140 | L_{b487} | 1800 | 150 | L_{b487} |
| 1801 | 152 | L_{b487} | 1802 | 157 | L_{b487} | 1803 | 161 | L_{b487} |
| 1804 | 168 | L_{b487} | 1805 | 196 | L_{b487} | 1806 | 201 | L_{b487} |
| 1807 | 207 | L_{b487} | 1808 | 228 | L_{b487} | 1809 | 267 | L_{b487} |
| 1810 | 272 | L_{b487} | 1811 | 278 | L_{b487} | 1812 | 299 | L_{b487} |
| 1813 | 311 | L_{b487} | 1814 | 338 | L_{b487} | 1815 | 343 | L_{b487} |
| 1816 | 349 | L_{b487} | 1817 | 370 | L_{b487} | 1818 | 409 | L_{b487} |
| 1819 | 414 | L_{b487} | 1820 | 420 | L_{b487} | 1821 | 441 | L_{b487} |
| 1822 | 480 | L_{b487} | 1823 | 490 | L_{b487} | 1824 | 511 | L_{b487} |
| 1825 | 522 | L_{b487} | 1826 | 550 | L_{b487} | 1827 | 560 | L_{b487} |
| 1828 | 581 | L_{b487} | 1829 | 593 | L_{b487} | 1830 | 620 | L_{b487} |
| 1831 | 626 | L_{b487} | 1832 | 648 | L_{b487} | 1833 | 659 | L_{b487} |
| 1834 | 746 | L_{b487} | 1835 | 747 | L_{b487} | 1836 | 749 | L_{b487} |
| 1837 | 1 | L_{b555} | 1838 | 7 | L_{b555} | 1839 | 11 | L_{b555} |
| 1840 | 21 | L_{b555} | 1841 | 49 | L_{b555} | 1842 | 63 | L_{b555} |
| 1843 | 105 | L_{b555} | 1844 | 106 | L_{b555} | 1845 | 107 | L_{b555} |
| 1846 | 110 | L_{b555} | 1847 | 130 | L_{b555} | 1848 | 131 | L_{b555} |
| 1849 | 136 | L_{b555} | 1850 | 140 | L_{b555} | 1851 | 150 | L_{b555} |
| 1852 | 152 | L_{b555} | 1853 | 157 | L_{b555} | 1854 | 161 | L_{b555} |
| 1855 | 168 | L_{b555} | 1856 | 196 | L_{b555} | 1857 | 201 | L_{b555} |
| 1858 | 207 | L_{b555} | 1859 | 228 | L_{b555} | 1860 | 267 | L_{b555} |
| 1861 | 272 | L_{b555} | 1862 | 278 | L_{b555} | 1863 | 299 | L_{b555} |
| 1864 | 311 | L_{b555} | 1865 | 338 | L_{b555} | 1866 | 343 | L_{b555} |
| 1867 | 349 | L_{b555} | 1868 | 370 | L_{b555} | 1869 | 409 | L_{b555} |
| 1870 | 414 | L_{b555} | 1871 | 420 | L_{b555} | 1872 | 441 | L_{b555} |
| 1873 | 480 | L_{b555} | 1874 | 490 | L_{b555} | 1875 | 511 | L_{b555} |
| 1876 | 522 | L_{b555} | 1877 | 550 | L_{b555} | 1878 | 560 | L_{b555} |
| 1879 | 581 | L_{b555} | 1880 | 593 | L_{b555} | 1881 | 620 | L_{b555} |
| 1882 | 626 | L_{b555} | 1883 | 648 | L_{b555} | 1884 | 659 | L_{b555} |
| 1885 | 746 | L_{b555} | 1886 | 747 | L_{b555} | 1887 | 749 | L_{b555} |
| 1888 | 1 | L_{b728} | 1889 | 7 | L_{b728} | 1890 | 11 | L_{b728} |
| 1891 | 21 | L_{b728} | 1892 | 49 | L_{b728} | 1893 | 63 | L_{b728} |
| 1894 | 105 | L_{b728} | 1895 | 106 | L_{b728} | 1896 | 107 | L_{b728} |
| 1897 | 110 | L_{b728} | 1898 | 130 | L_{b728} | 1899 | 131 | L_{b728} |
| 1900 | 136 | L_{b728} | 1901 | 140 | L_{b728} | 1902 | 150 | L_{b728} |
| 1903 | 152 | L_{b728} | 1904 | 157 | L_{b728} | 1905 | 161 | L_{b728} |
| 1906 | 168 | L_{b728} | 1907 | 196 | L_{b728} | 1908 | 201 | L_{b728} |
| 1909 | 207 | L_{b728} | 1910 | 228 | L_{b728} | 1911 | 267 | L_{b728} |
| 1912 | 272 | L_{b728} | 1913 | 278 | L_{b728} | 1914 | 299 | L_{b728} |
| 1915 | 311 | L_{b728} | 1916 | 338 | L_{b728} | 1917 | 343 | L_{b728} |
| 1918 | 349 | L_{b728} | 1919 | 370 | L_{b728} | 1920 | 409 | L_{b728} |
| 1921 | 414 | L_{b728} | 1922 | 420 | L_{b728} | 1923 | 441 | L_{b728} |
| 1924 | 480 | L_{b728} | 1925 | 490 | L_{b728} | 1926 | 511 | L_{b728} |
| 1927 | 522 | L_{b728} | 1928 | 550 | L_{b728} | 1929 | 560 | L_{b728} |
| 1930 | 581 | L_{b728} | 1931 | 593 | L_{b728} | 1932 | 620 | L_{b728} |
| 1933 | 626 | L_{b728} | 1934 | 648 | L_{b728} | 1935 | 659 | L_{b728} |
| 1936 | 746 | L_{b728} | 1937 | 747 | L_{b728} | 1938 | 749 | L_{b728} |

wherein metal complex 1-7 to metal complex 40-7 have a structure of Ir(Lₐ)₂(L_{b}), and Lₐ and L_{b} correspond to the structures in the following table, respectively:

| Metal | | | Metal | | |
|---|---|---|---|---|---|
| complex No. | Lₐ | L_{b} | complex No. | Lₐ | L_{b} |
| 1-7 | Lₐ₋₁₋₁ | L_{b33} | 2-7 | Lₐ₋₂₋₁ | L_{b33} |
| 3-7 | Lₐ₋₁₋₁₀₅ | L_{b33} | 4-7 | Lₐ₋₂₋₁₀₅ | L_{b33} |
| 5-7 | Lₐ₋₁₋₁₃₀ | L_{b33} | 6-7 | Lₐ₋₂₋₁₃₀ | L_{b33} |
| 7-7 | Lₐ₋₁₋₂₀₁ | L_{b33} | 8-7 | Lₐ₋₂₋₂₀₁ | L_{b33} |
| 9-7 | Lₐ₋₁₋₂₇₂ | L_{b33} | 10-7 | Lₐ₋₂₋₂₇₂ | L_{b33} |
| 11-7 | Lₐ₋₁₋₃₄₃ | L_{b33} | 12-7 | Lₐ₋₂₋₃₄₃ | L_{b33} |
| 13-7 | Lₐ₋₁₋₄₁₄ | L_{b33} | 14-7 | Lₐ₋₂₋₄₁₄ | L_{b33} |
| 15-7 | Lₐ₋₁₋₇₄₆ | L_{b33} | 16-7 | Lₐ₋₂₋₇₄₆ | L_{b33} |
| 17-7 | Lₐ₋₁₋₇₄₇ | L_{b33} | 18-7 | Lₐ₋₂₋₇₄₇ | L_{b33} |
| 19-7 | Lₐ₋₁₋₇₄₉ | L_{b33} | 20-7 | Lₐ₋₂₋₇₄₉ | L_{b33} |
| 21-7 | Lₐ₋₁₋₁ | L_{b74} | 22-7 | Lₐ₋₂₋₁ | L_{b74} |
| 23-7 | Lₐ₋₁₋₁₀₅ | L_{b74} | 24-7 | Lₐ₋₂₋₁₀₅ | L_{b74} |
| 25-7 | Lₐ₋₁₋₁₃₀ | L_{b74} | 26-7 | Lₐ₋₂₋₁₃₀ | L_{b74} |
| 27-7 | Lₐ₋₁₋₂₀₁ | L_{b74} | 28-7 | Lₐ₋₂₋₂₀₁ | L_{b74} |
| 29-7 | Lₐ₋₁₋₂₇₂ | L_{b74} | 30-7 | Lₐ₋₂₋₂₇₂ | L_{b74} |
| 31-7 | Lₐ₋₁₋₃₄₃ | L_{b74} | 32-7 | Lₐ₋₂₋₃₄₃ | L_{b74} |
| 33-7 | Lₐ₋₁₋₄₁₄ | L_{b74} | 34-7 | Lₐ₋₂₋₄₁₄ | L_{b74} |
| 35-7 | Lₐ₋₁₋₇₄₆ | L_{b74} | 36-7 | Lₐ₋₂₋₇₄₆ | L_{b74} |
| 37-7 | Lₐ₋₁₋₇₄₇ | L_{b74} | 38-7 | Lₐ₋₂₋₇₄₇ | L_{b74} |
| 39-7 | Lₐ₋₁₋₇₄₉ | L_{b74} | 40-7 | Lₐ₋₂₋₇₄₉ | L_{b74} |

17. An organic electroluminescent device, comprising:
an anode,
a cathode, and
an organic layer disposed between the anode and the cathode, wherein at least one layer of the organic layer comprises the metal complex of claim 1.

18. The organic electroluminescent device of claim 17, wherein the organic layer comprising the metal complex is an emissive layer.

19. The organic electroluminescent device of claim 18, wherein the emissive layer further comprises a first host compound or further comprises a first host compound and a second host compound;
preferably, the first host compound and/or the second host compound comprise at least one chemical group selected from the group consisting of: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

20. The organic electroluminescent device of claim 19, wherein the metal complex is doped in the first host compound and the second host compound, and the weight of the metal complex accounts for 1% to 30% of the total weight of the emissive layer;
preferably, the weight of the metal complex accounts for 3% to 13% of the total weight of the emissive layer.

21. A compound composition, comprising the metal complex of claim 1.
